(19) United States
(12) Patent Application Publication
(10) Pub. No.: US 2026/0073845 A1
(43) Pub. Date: Mar. 12, 2026

(54) DISPLAY PANEL AND DISPLAY APPARATUS

(71) Applicant: Wuhan Tianma Micro-Electronics Co., Ltd., Wuhan (CN)

(72) Inventors: Wenshuai ZHANG, Wuhan (CN); Zihui YUAN, Wuhan (CN); Qingjun LAI, Wuhan (CN); Lijun LU, Wuhan (CN); Hongbo ZHOU, Wuhan (CN); Yana GAO, Wuhan (CN); Xiangwen MA, Wuhan (CN); Xingyao ZHOU, Wuhan (CN)

(21) Appl. No.: 19/223,600

(22) Filed: May 30, 2025

(30) Foreign Application Priority Data
Sep. 9, 2024 (CN) 202411262755.9

(51) Int. Cl. G09G 3/32

(52) U.S. Cl. CPC G09G 3/32; G09G 2310/0267; G09G 2310/0286; G09G 2310/08; G09G 2320/0233; G09G 2330/021

(57) ABSTRACT

The present disclosure provides a display panel and a display apparatus. The display panel includes a driver circuit including shift registers. The shift register includes a shift control module, configured to receive an input signal, a first clock signal and a second clock signal, and control signals of a first node and a second node; a shift output module, configured to receive the signal of the first node, the signal of the second node, a first level signal and a second level signal, and control an output shift signal; an output control module, configured to receive an output control signal and the shift signal, and control a signal of a third node; a transmission control module, configured to receive the signal of the second node and a signal of the third node, and control a signal of the fourth node; a potential maintaining module; and a drive output module.

### CROSS-REFERENCE TO RELATED APPLICATION

The present disclosure claims the priority of Chinese Patent Application No. 202411262755.9, filed on Sep. 9, 2024, the content of which is incorporated herein by reference in its entirety.

### TECHNICAL FIELD

The present disclosure generally relates to the field of display technology and, more particularly, relates to a display panel and a display apparatus.

### BACKGROUND

A display panel may be disposed with a plurality of pixels arranged in an array, and a driver circuit may be configured to scan each pixel line by line, such that a data signal and the like may be written into each pixel line by line, and each pixel may perform light-emitting display according to received data signal, thereby presenting corresponding display pictures.

A cascaded multi-level shift register may be configured in the driver circuit, and a gate drive signal outputted by the shift register may be controlled by controlling signals of corresponding nodes in the shift register of each level. However, since certain nodes in the shift register are associated with the gate drive signal, the gate drive signal may fluctuate when these nodes change, thereby affecting accuracy of the gate drive signal outputted by the shift register and further affecting the display quality of the display panel.

### SUMMARY

One aspect of the present disclosure provides a display panel. The display panel includes a driver circuit including cascaded N-level shift registers. A shift register of the cascaded N-level shift registers includes a shift control module, configured to at least receive an input signal, a first clock signal and a second clock signal, and control a signal of a first node and a signal of a second node; a shift output module, configured to at least receive the signal of the first node, the signal of the second node, a first level signal and a second level signal, and control an output shift signal, where a shift signal outputted by an x-th-level shift register is an input signal received by a y-th-level shift register; 1≤x≤N; 1≤y≤N; x≠y; and x, y and N are all positive integers; an output control module, configured to at least receive an output control signal and the shift signal, and control a transmission path of the output control signal to a third node under the control of the shift signal; a transmission control module, configured to at least receive the signal of the second node and a signal of the third node, and control a signal of the fourth node; a potential maintaining module, configured to receive a fixed level signal and maintain the signal of the third node; and a drive output module, configured to at least receive the signal of the fourth node, the signal of the first node, the first level signal and the second level signal, and control an output of a gate drive signal, where the fixed level signal is at least different from the second level signal.

Another aspect of the present disclosure provides a display apparatus including a display panel. The display panel includes a driver circuit including cascaded N-level shift registers. A shift register of the cascaded N-level shift registers includes a shift control module, configured to at least receive an input signal, a first clock signal and a second clock signal, and control a signal of a first node and a signal of a second node; a shift output module, configured to at least receive the signal of the first node, the signal of the second node, a first level signal and a second level signal, and control an output shift signal, where a shift signal outputted by an x-th-level shift register is an input signal received by a y-th-level shift register; 1≤x≤N; 1≤y≤N; x≠y; and x, y and N are all positive integers; an output control module, configured to at least receive an output control signal and the shift signal, and control a transmission path of the output control signal to a third node under the control of the shift signal; a transmission control module, configured to at least receive the signal of the second node and a signal of the third node, and control a signal of the fourth node; a potential maintaining module, configured to receive a fixed level signal and maintain the signal of the third node; and a drive output module, configured to at least receive the signal of the fourth node, the signal of the first node, the first level signal and the second level signal, and control an output of a gate drive signal, where the fixed level signal is at least different from the second level signal.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of specification, illustrate embodiments of the present disclosure and together with the description to explain the principles of the present disclosure.

FIG. 1 illustrates a structural schematic of a display panel according to various embodiments of the present disclosure.

FIG. 2 illustrates a structural schematic of a driver circuit according to various embodiments of the present disclosure.

FIG. 3 illustrates a structural schematic of a shift register according to various embodiments of the present disclosure.

FIG. 4 illustrates another structural schematic of a shift register according to various embodiments of the present disclosure.

FIG. 5 illustrates another structural schematic of a driver circuit according to various embodiments of the present disclosure.

FIG. 6 illustrates another structural schematic of a driver circuit according to various embodiments of the present disclosure.

FIG. 7 illustrates another structural schematic of a shift register according to various embodiments of the present disclosure.

FIG. 8 illustrates another structural schematic of a shift register according to various embodiments of the present disclosure.

FIG. 9 illustrates another structural schematic of a shift register according to various embodiments of the present disclosure.

FIG. 10 illustrates another structural schematic of a driver circuit according to various embodiments of the present disclosure.

FIG. 11 illustrates another structural schematic of a driver circuit according to various embodiments of the present disclosure.

FIG. 12 illustrates another structural schematic of a driver circuit according to various embodiments of the present disclosure.

FIG. 13 illustrates a driving time sequence diagram of a display panel according to various embodiments of the present disclosure.

FIG. 14 illustrates another driving time sequence diagram of a display panel according to various embodiments of the present disclosure.

FIG. 15 illustrates a structural schematic of a pixel according to various embodiments of the present disclosure.

FIG. 16 illustrates another driving time sequence diagram of a display panel according to various embodiments of the present disclosure.

FIG. 17 illustrates another driving time sequence diagram of a display panel according to various embodiments of the present disclosure.

FIG. 18 illustrates another driving time sequence diagram of a display panel according to various embodiments of the present disclosure.

FIG. 19 illustrates another driving time sequence diagram of a display panel according to various embodiments of the present disclosure.

FIG. 20 illustrates another structural schematic of a shift register according to various embodiments of the present disclosure.

FIG. 21 illustrates another structural schematic of a shift register according to various embodiments of the present disclosure.

FIG. 22 illustrates another structural schematic of a shift register according to various embodiments of the present disclosure.

FIG. 23 illustrates another structural schematic of a shift register according to various embodiments of the present disclosure.

FIG. 24 illustrates another structural schematic of a shift register according to various embodiments of the present disclosure.

FIG. 25 illustrates another structural schematic of a shift register according to various embodiments of the present disclosure.

FIG. 26 illustrates another structural schematic of a shift register according to various embodiments of the present disclosure.

FIG. 27 illustrates another structural schematic of a shift register according to various embodiments of the present disclosure.

FIG. 28 illustrates another structural schematic of a shift register according to various embodiments of the present disclosure.

FIG. 29 illustrates a driving time sequence diagram of a shift register according to various embodiments of the present disclosure.

FIG. 30 illustrates another structural schematic of a shift register according to various embodiments of the present disclosure.

FIG. 31 illustrates another structural schematic of a shift register according to various embodiments of the present disclosure.

FIG. 32 illustrates another driving time sequence diagram of a shift register according to various embodiments of the present disclosure.

FIG. 33 illustrates another structural schematic of a shift register according to various embodiments of the present disclosure.

FIG. 34 illustrates another structural schematic of a driver circuit according to various embodiments of the present disclosure.

FIG. 35 illustrates another structural schematic of a driver circuit according to various embodiments of the present disclosure.

FIG. 36 illustrates another structural schematic of a driver circuit according to various embodiments of the present disclosure.

FIG. 37 illustrates another structural schematic of a driver circuit according to various embodiments of the present disclosure.

FIG. 38 illustrates another structural schematic of a driver circuit according to various embodiments of the present disclosure.

FIG. 39 illustrates another structural schematic of a shift register according to various embodiments of the present disclosure.

FIG. 40 illustrates another structural schematic of a shift register according to various embodiments of the present disclosure.

FIG. 41 illustrates another structural schematic of a shift register according to various embodiments of the present disclosure.

FIG. 42 illustrates another structural schematic of a shift register according to various embodiments of the present disclosure.

FIG. 43 illustrates another structural schematic of a shift register according to various embodiments of the present disclosure.

FIG. 44 illustrates another structural schematic of a shift register according to various embodiments of the present disclosure.

FIG. 45 illustrates a partial cross-sectional structural schematic of a display panel according to various embodiments of the present disclosure.

FIG. 46 illustrates another partial cross-sectional structural schematic of a display panel according to various embodiments of the present disclosure.

FIG. 47 illustrates another partial cross-sectional structural schematic of a display panel according to various embodiments of the present disclosure.

FIG. 48 illustrates another structural schematic of a shift register according to various embodiments of the present disclosure.

FIG. 49 illustrates another structural schematic of a shift register according to various embodiments of the present disclosure.

FIG. 50 illustrates another structural schematic of a shift register according to various embodiments of the present disclosure.

FIGS. 51-55 illustrate top-view structural schematics of each film layer of a shift register according to various embodiments of the present disclosure.

FIG. 56 illustrates another structural schematic of a shift register according to various embodiments of the present disclosure.

FIG. 57 illustrates another structural schematic of a shift register according to various embodiments of the present disclosure.

FIG. 58 illustrates another structural schematic of a shift register according to various embodiments of the present disclosure.

FIG. 59 illustrates a top-view structural schematic of a shift register according to various embodiments of the present disclosure.

FIG. 60 illustrates a cross-sectional structural schematic along an A-A section in FIG. 59.

FIG. 61 illustrates another structural schematic of a shift register according to various embodiments of the present disclosure.

FIG. 62 illustrates a partial film layer structural schematic of a display panel according to various embodiments of the present disclosure.

FIG. 63 illustrates a partial cross-sectional structural schematic of a display panel according to various embodiments of the present disclosure.

FIG. 64 illustrates a structural schematic of a display apparatus according to various embodiments of the present disclosure.

### DETAILED DESCRIPTION

In order to make the objective, technical solution and advantages of the present disclosure clearer, the technical solution of the present disclosure is fully described below in conjunction with the drawings in embodiments of the present disclosure through specific implementation manners. Obviously, described embodiments are a part of embodiments of the present disclosure, not all of embodiments. Various modifications and changes may be made in the present disclosure without departing from the spirit or scope of the present disclosure, which may be obvious to those skilled in the art. Therefore, the present disclosure may be intended to cover modifications and changes of the present disclosure that fall within the protection scope of corresponding claims (technical solution to be protected) and their equivalents.

Moreover, the terms “first”, “second” and similar terms used in embodiments of the present disclosure may not indicate any order, quantity or importance, but may be only used to distinguish different components. Similarly, terms such as “one”, “an” or “the” may not indicate a quantity limitation, but indicate the existence of at least one. Terms such as “include”, “comprise” and similar terms may indicate that the elements or objects appearing before the terms include the elements or objects and their equivalents listed after the terms, without excluding other elements or objects. Terms such as “connect”, “connection” and similar terms may be not limited to physical or mechanical connections but may include direct or indirect electrical connections. “Up”, “down”, “left”, “right” and the like may be only used to indicate relative positional relationships. When absolute position of described object changes, relative positional relationship may also change accordingly. In addition, the description of same, equal and the like in embodiments of the present disclosure may not indicate that two objects are completely equal in size and shape and may indicate that two objects are allowed to be roughly same or roughly equal within a certain error range.

It should be noted that the implementation manners provided in embodiments of the present disclosure may be combined with each other without contradiction.

As described in the background, the shift register of the driver circuit may include multiple nodes. By controlling the signal of each node, the gate drive signal outputted by the drive output module in the shift register may be controlled. Especially for the shift register that may satisfy diversified display requirement of the display panel, the gate drive signal outputted by the shift register may be controlled to adapt to current display requirement through the output control signal. For example, when the shift signal is at a valid level and the output control signal is at a valid level, the shift register may be controlled to output the valid level of the gate drive signal; and when the shift signal is at a valid level and the output control signal is at an invalid level, the shift register may be controlled to output the invalid level of the gate drive signal.

When the pixel divisions in the display panel perform signal refresh during the display time of one frame, the gate drive signal outputted by the shift register, which provides the gate drive signal to the pixel that needs to be refreshed, should include the valid level. When such shift register outputs the valid level of the shift signal, the output control signal should maintain the valid level. Furthermore, the gate drive signal outputted by the shift register, which provides the gate drive signal to the pixel that does not need to be refreshed, may maintain the invalid level. When such shift register outputs the valid level of the shift signal, the output control signal should be maintained at the invalid level. In such way, in the display time of one frame, the output control signal may jump between the valid level and the invalid level. However, the jump time of the output control signal and the valid level of the gate drive signal outputted by certain shift registers in the driver circuit may fluctuate due to the jump of the output control signal, which may affect the accuracy of the pixel signal refresh, thereby affecting the display brightness of the pixel and further affecting the display quality of the display panel.

In order to solve above-mentioned technical problems, embodiments of the present disclosure provide a display panel. The display panel may include a driver circuit; and the driver circuit may include cascaded N-level shift registers. The shift register may include a shift control module, configured to at least receive an input signal, a first clock signal and a second clock signal, and control a signal of a first node and a signal of a second node; a shift output module, configured to at least receive the signal of the first node, the signal of the second node, a first level signal and a second level signal, and control an output shift signal, where a shift signal outputted by an x-th-level shift register is an input signal received by a y-th-level shift register; 1≤x≤N; 1≤y≤N; x≠y; and x, y and N are all positive integers; an output control module, configured to at least receive an output control signal and the shift signal, and control a transmission path of the output control signal to a third node under the control of the shift signal; a transmission control module, configured to at least receive the signal of the second node and a signal of the third node, and control a signal of the fourth node; a potential maintaining module, configured to receive a fixed level signal and maintain the signal of the third node; and a drive output module, configured to at least receive a signal of the fourth node, the signal of the first node, the first level signal and the second level signal, and control an output of a gate drive signal, where the fixed level signal is at least different from the second level signal.

For above-mentioned technical solution adopted, the cascaded N-level shift registers may be configured in the driver circuit, the shift control module of the shift register at each level may control the shift output module to output the shift signal as the input signal of other level shift registers, and the shift signal may be configured to control the output control module to transmit the output control signal to the third node, such that the transmission control module may control the drive output module to output the gate drive signal according to the signal of the third node. In such way, in a same shift register, the shift output module for signal level transmission and the drive output module for outputting the gate drive signal may be two different modules to make the signal level transmission and the output of the gate drive signal to be independent of each other. Therefore, while ensuring the signal level transmission between the shift registers, the gate drive signals outputted by the shift registers at all levels may be flexibly controlled; and the display panel may satisfy diversified display requirement and broaden application scenarios of the display panel. Meanwhile, the shift register may be also configured with the potential maintaining module to receive the fixed level signal and maintain the signal of the third node. In addition, the fixed level signal may be at least different from the second level signal, which may prevent the second level signal from fluctuating due to the signal change of the third node and affecting the gate drive signal outputted by the drive output module, thereby being beneficial for improving the accuracy of the gate drive signal outputted by the drive output module and further improving the display quality of the display panel.

The above is the core idea of the present disclosure. Based on embodiments of the present disclosure, all other embodiments obtained by those skilled in the art without creative work should be within the protection scope of the present disclosure. The technical solution in embodiments of the present disclosure is clearly and completely described with conjunction of the drawings in embodiments of the present disclosure hereinafter.

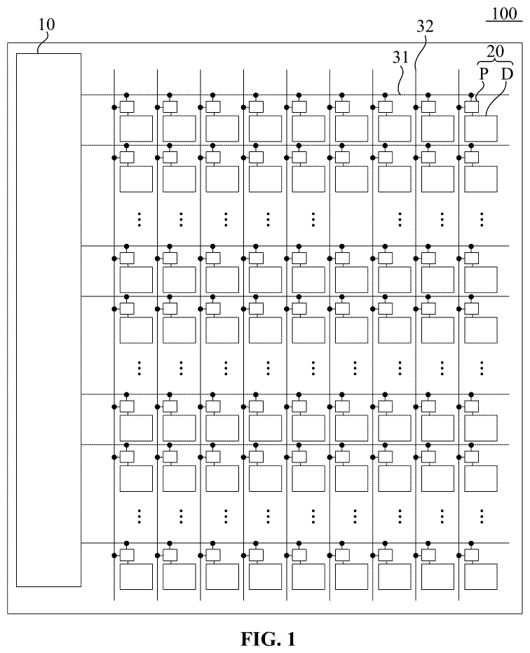

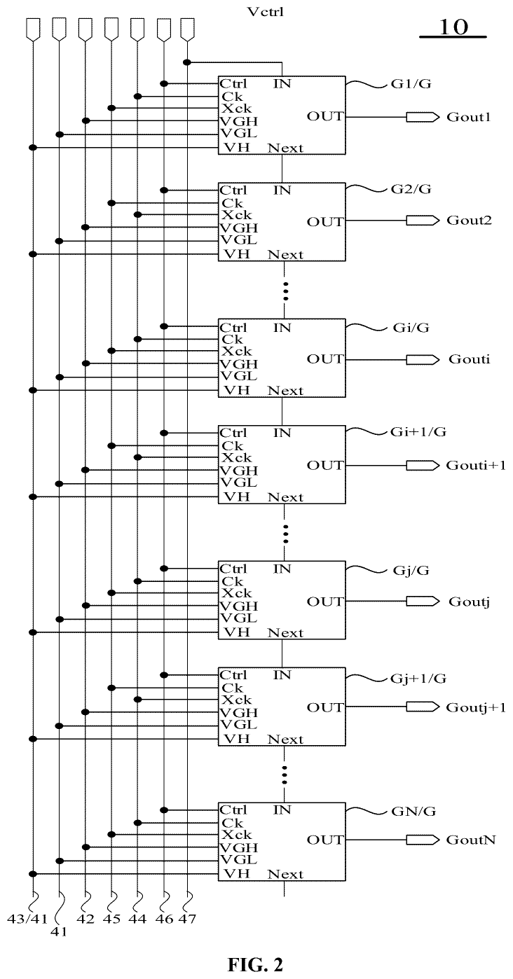

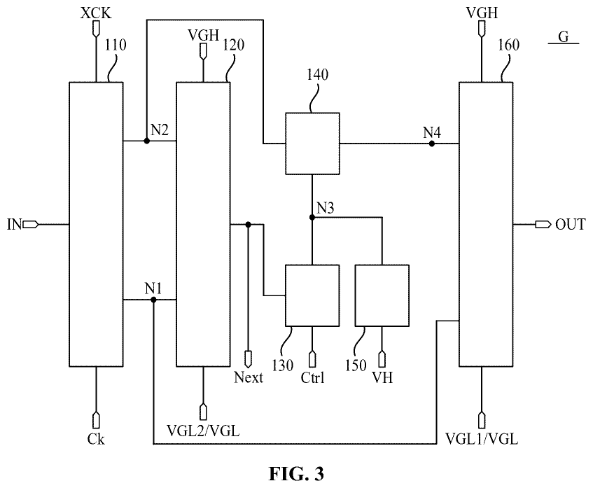

FIG. 1 illustrates a structural schematic of a display panel according to various embodiments of the present disclosure; FIG. 2 illustrates a structural schematic of a driver circuit according to various embodiments of the present disclosure; and FIG. 3 illustrates a structural schematic of a shift register according to various embodiments of the present disclosure. Referring to FIGS. 1-3, the display panel 100 may include a driver circuit 10; and the driver circuit 10 may include cascaded N-level shift registers G. The shift register G may include a shift control module 110 configured to at least receive the input signal Vin, the first clock signal CK and the second clock signal XCK, and control the signal of the first node N1 and the signal of the second node N2; a shift output module 120 configured to at least receive the signal of the first node N1, the signal of the second node N2, the first level signal Vg1 and the second level signal Vgh, and control the output of the shift signal Vnext; an output control module 130 configured to at least receive the output control signal Vctrl and the shift signal Vnext, and under the control of the shift signal Vnext, control the transmission path of the output control signal Vctrl to the third node N3; a transmission control module 140 configured to at least receive the signal of the second node N2 and the signal of the third node N3, and control the signal of the fourth node N4; a potential maintaining module 150 configured to receive the fixed level signal Vh and maintain the signal of the third node N3; and a drive output module 160 configured to at least receive the signal of the fourth node N4, the signal of the first node N1, the first level signal Vg1 and the second level signal Vgh, and control output of the gate drive signal Gout. The fixed level signal Vh may be at least different from the second level signal Vgh. The shift signal Vnext outputted by the x-th-level shift register Gx may be the input signal received by the y-th-level shift register Gy, 1≤x≤N, 1≤y≤N, x≠y, and x, y and N are all positive integers.

In addition, the shift register G may also at least include the signal input terminal IN, the first clock terminal Ck, the second clock terminal Xck, the first level terminal VGL, the second level terminal VGH, the fixed signal terminal VH, the output control terminal Ctrl, the shift signal terminal Next and the drive signal terminal OUT. The signal input terminal IN may be configured to receive the input signal, the first clock terminal Ck may be configured to receive the first clock signal CK, the second clock terminal Xck may be configured to receive the second clock signal XCK, the first level terminal VGL may be configured to receive the first level signal Vg1, the second level terminal VGH may be configured to receive the second level signal Vgh, the fixed signal terminal VH may be configured to receive the fixed level signal Vh, the output control terminal Ctrl may be configured to receive the output control signal Vctrl, the shift signal terminal Next may be configured to output the shift signal Vnext, and the drive signal terminal OUT may be configured to output the gate drive signal Gout.

The shift control module 110 may be at least electrically connected to the signal input terminal IN, the first clock terminal Ck, the second clock terminal Xck, the first node N1 and the second node N2 to receive the input signal Vin of the signal input terminal IN, the first clock signal CK of the first clock terminal Ck, and the second clock signal of the second clock terminal Xck; and may control the signal of the first node N1 and the signal of the second node N2. For example, when the signal of the first node N1 is controlled to be at the valid level, the signal of the second node N2 may be controlled to be a non-enable signal; or when the signal of the second node N2 is controlled to be at the valid level, the signal of the first node N1 may be controlled to be at an invalid level.

The shift output module 120 may be at least electrically connected to the first node N1, the second node N2, the first level terminal VGL, the second level terminal VGH and the shift signal output terminal Next, such that the shift output module 120 may receive the signal of the first node N1, the signal of the second node N2, the first level signal Vg1 of the first level terminal VGL, and the second level signal Vgh of the second level terminal VGH; and may control the shift signal Vnext outputted by the shift signal terminal Next. For example, when the signal of the first node N1 is at the valid level, the shift output module 120 may be controlled to transmit the first level signal Vg1 to the shift signal terminal Next, such that the shift signal Vnext of the shift signal terminal Next may be consistent with the first level signal Vg1. When the signal of the second node N2 is at the valid level, the shift output module 120 may be controlled to transmit the second level signal Vgh to the shift signal terminal Next, such that the shift signal Vnext of the shift signal terminal Next may be consistent with the second level signal Vgh. The first level signal Vg1 and the second level signal Vgh may be two fixed signals with different polarities, such that one of the first level signal Vg1 and the second level signal Vgh may be the valid level of the shift signal Vnext, and another one of the first level signal Vg1 and the second level signal Vgh may be the invalid level of the shift signal Vnext.

It may be understood that different polarities of the first level signal Vg1 and the second level signal Vgh may be that one of the first level signal Vg1 and the second level signal Vgh may be a high level signal, and another one of the first level signal Vg1 and the second level signal Vgh may be a low level signal. For example, the first level signal Vg1 may be the low level signal, and the second level signal Vgh may be the high level signal; or the first level signal Vg1 may be the high level signal, and the second level signal Vgh may be the high level signal, which may be configured based on actual needs and may not be limited in embodiments of the present disclosure.

The output control module 130 may be at least electrically connected to the output control terminal Ctrl, the shift signal terminal Next and the third node N3, such that the transmission path of the output control signal Vctrl of the output control terminal Ctrl to the third node N3 may be controlled according to the shift signal Vnext of the shift signal terminal Next. For example, the shift signal Vnext at the shift signal terminal Next may control the output control module 130 to be turned on or off. In addition, when the shift signal Vnext controls the output control module 130 to be turned on for conduction, the output control module 130 may transmit the output control signal Vctrl to the third node N3, such that the signal of the third node N3 may be consistent with the output control signal Vctrl; and when the shift signal Vnext controls the output control module 130 to be turned off for disconnection, the output control signal Vctrl may be stopped from being transmitted to the third node N3, such that the signal of the third node N3 may remain unchanged.

The transmission control module 140 may be at least electrically connected to the second node N2, the third node N3 and the fourth node N4, such that the signal of the fourth node N4 may be controlled according to the signals of the second node N2 and the third node N3. For example, the signal of the third node N3 may control the transmission control module 140 to be turned on or off. Furthermore, when the signal of the third node N3 controls the transmission control module 140 to be turned on, the signal of the second node N2 may be transmitted to the fourth node N4, such that the signal of the fourth node N4 may be consistent with the signal of the second node N2; and when the signal of the third node N3 controls the transmission control module 140 to be turned off, the signal of the second node N2 cannot be transmitted to the fourth node N4, such that the signal of the fourth node N4 may remain the signal written in previous stage, that is, the signal of the fourth node N4 may remain unchanged.

The drive output module 160 may be at least electrically connected to the fourth node N4, the first node N1, the first level terminal VGL, the second level terminal VGH and the drive signal terminal OUT, such that the gate drive signal Gout outputted by the drive signal terminal OUT may be controlled according to the signal of the fourth node N4, the signal of the first node N1, the first level signal Vg1 of the first level terminal VGL, and the second level signal Vgh of the second level terminal VGH. For example, when the signal of the first node N1 is at the valid level, the drive output module 160 may be controlled to transmit the first level signal Vg1 to the drive signal terminal OUT, such that the gate drive signal Gout of the drive signal terminal OUT may be consistent with the first level signal Vg1; and when the signal of the fourth node N4 is at the valid level, the drive output module 160 may be controlled to transmit the second level signal Vgh to the drive signal terminal OUT, such that the gate drive signal Gout of the drive signal terminal OUT may be consistent with the second level signal Vgh. One of the first level signal Vg1 and the second level signal Vgh may be the valid level of the gate drive signal Gout, and another one of the first level signal Vg1 and the second level signal Vgh may be the invalid level of the gate drive signal Gout.

The potential maintaining module 140 may be electrically connected to the fixed signal terminal VH and the third node N3, respectively, such that the potential maintaining module 140 may maintain the signal of the third node N3 under the action of the fixed level signal Vh of the fixed signal terminal VH. The fixed level signal Vh may be at least different from the second level signal Vgh. That is, the fixed level signal Vh and the second level signal Vgh may be provided by different signal terminals. In other terms, the fixed signal terminal VH and the second level terminal VGH may be different signal terminals. At this point, the voltage of the fixed level signal Vh may be same as or different from the voltage of the second level signal Vgh.

It may be understood that, the potential maintaining module 140 is electrically connected between the fixed signal terminal VH and the third node N3, therefore when the third node N3 and the fixed level signal Vh remain unchanged, the potential maintaining module 140 may ensure that the voltage difference between the first node N3 and the fixed level signal Vh is fixed based on charge conservation principle; that is, the signal of the third node N3 and the fixed level signal Vh of the fixed signal terminal VH may remain unchanged. However, when the shift signal Vnext controls the output control module 130 to be in a turn-on state, the signal of the third node N3 may change with the change of the output control signal Vctrl. That is, during the time when the output control module is turned on for conduction, if the output control signal Vctrl jumps, the signal of the third node N3 may jump accordingly; or when the output control signal Vctrl transmitted by the output control module 130 during current time period is different from the output control signal Vctrl transmitted during last conduction time period of the output control module 130, the signal of the third node N3 may jump. When the signal of the third node N3 changes, the signal of the fixed signal terminal VH may fluctuate instantaneously due to the charge conservation principle of the potential maintaining module 140.

Referring to FIGS. 1-4, when the shift output module 120 controls the transmission of the first level signal Vg1 to the shift signal terminal Next according to the signal of the first node N1, the first level signal Vg1 may be configured as an invalid level of the shift signal Vnext; and when the shift output module 120 controls the transmission of the second level signal Vgh to the shift signal terminal of the NEXT according to the signal of the second node N2, the second level signal Vgh may be configured as a valid level of the shift signal Vnext. At this point, the fixed level signal may be at least different from the second level signal Vgh, therefore the valid level of the shift signal Vnext outputted by the shift output module 120 may at least not be affected when the signal of the third node N3 changes and the signal of the fixed signal terminal fluctuates instantaneously, thereby ensuring the valid level of the shift signal Vnext. In such way, when the shift signal Vnextx outputted by the x-level shift register GX is configured as the input signal Viny of the y-level shift register GY, since the x-level shift register GX may stabilize the valid level of the output of the shift signal Vnextx, the shift control module of the y-level shift register GY may accurately control the signals of the first node N1 and the second node N2 when the input signal Viny of the y-level shift control module 110 is the valid level, which may ensure that the stability and accuracy of the shift signal Vnext outputted by the y-level shift register and further ensure that the shift signals of the shift registers G at all levels in the drive circuit 10 may be transmitted level by level sequentially.

Similarly, when the drive output module 160 controls the transmission of the first level signal Vg1 to the drive signal terminal OUT according to the signal of the first node N1, the first level signal Vg1 may be configured as the invalid level of the gate drive signal Gout; and when the drive output module 160 controls the transmission of the second level signal Vgh to the drive signal terminal OUT according to the signal of the fourth node N4, the second level signal Vgh may be configured as the valid level of the gate drive signal Gout. At this point, the fixed level signal Vh may be at least different from the second level signal Vgh, the valid level of the gate drive signal Gout outputted by the drive output module 160 may at least not be affected when the signal of the third node N3 changes and the signal of the fixed signal terminal VH fluctuates instantaneously, thereby ensuring the output stability of the valid level of the gate drive signal Gout. In such way, when the gate drive signal Gout is configured to control the display panel to refresh the signal, the shift register G at each level may stably output the valid level of the gate drive signal Gout, thereby at least being ensuring that the display panel may refresh the signal accurately when the shift register is at the valid level, and further being beneficial for improving the accuracy of the signal refresh in the display panel and improving the display quality of the display panel.

Optional, on the premise that the fixed level signal Vh is at least different from the second level signal Vgh, the fixed level signal Vh may also be different from the first level signal Vg1, such that the fixed level signal Vh and the first level signal Vg1 may be provided by different signal terminals respectively; that is, the fixed signal terminal VH and the first level terminal VGL may be different signal terminals respectively. At this point, the voltage of the fixed level signal Vh may be same as or different from the voltage of the first level signal Vg1. In such way, the fixed level signal Vh may be different from the first level signal Vg1 and the second level signal Vgh. Therefore, the valid level and invalid level of the gate drive signal Gout outputted by the drive output module 160 may not be affected when the signal of the fixed signal terminal VH fluctuates instantaneously, thereby ensuring the output stability of the gate drive signal Gout. Furthermore, when the gate drive signal Gout controls the display panel to refresh the signal, the shift register G at each level may stably output the gate drive signal Gout, thereby ensuring that the display panel may accurately refresh the signal and further being beneficial for improving the accuracy of the signal refresh in the display panel and improving the display quality of the display panel.

In another optional embodiment, the fixed level signal Vh may also be same as the first level signal Vg1. At this point, the first level signal Vg1 may be multiplexed as the fixed level signal Vh to reduce the number of signals provided by the shift register G, which may be beneficial for simplifying the driving manner of the shift register G and reducing the driving cost of the shift register G.

It may be understood that when the shift output module 120 outputs the first level signal Vg1 as the invalid level of the shift signal Vnext and when the drive output module 160 outputs the first level signal Vg1 as the invalid level of the gate drive signal Gout, the invalid level time period of the shift signal Vnext and the gate drive signal Gout may be relatively long during the display time of one frame, and the signal may not be controlled to refresh during such time period. Therefore, fluctuation of the first level signal Vg1 may have relatively small influence on the accuracy of the signal refresh in the display panel. Meanwhile, since the first level signal Vg1 is a fixed signal, multiplexing the first level signal Vg1 as the fixed level signal may satisfy the requirement of the signal of display panel 100 under the premise of reducing the driving cost.

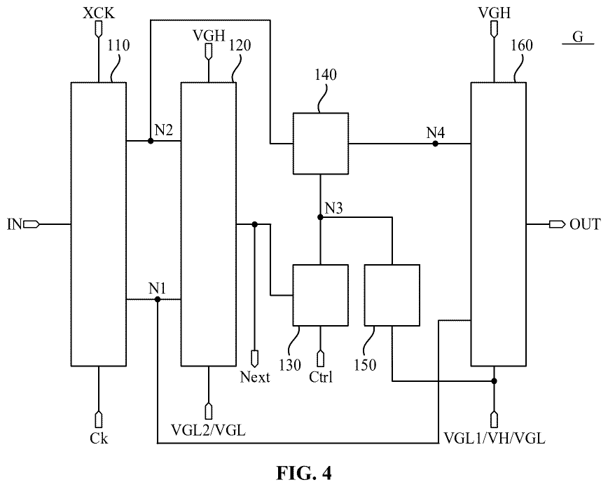

FIG. 4 illustrates another structural schematic of a shift register according to various embodiments of the present disclosure. Referring to FIGS. 2-4, when the fixed level signal Vh is same as the first level signal Vg1, the fixed signal terminal for receiving the fixed level signal Vh and the first level terminal VGL for receiving the first level signal Vg1 may be different signal terminals or same signal terminal, which may not be limited according to embodiments of the present disclosure.

Optionally, referring to FIGS. 1-3, the display panel 100 may further include at least one first signal transmission line 41. The first signal transmission line 41 may be configured to transmit the first level signal Vg1. In the same shift register G, when the fixed signal terminal VH and the first level terminal VGL are different signal terminals, the drive output module 160 and the potential maintaining module 150 may be electrically connected to different first signal transmission lines 41, respectively. In such way, the first signal transmission line 41 electrically connected to the drive output module 160 may transmit the first level signal Vg1 to the first level terminal VGL to control the drive output module 160 to output corresponding gate drive signal Gout as needed; and the first signal transmission line 41 electrically connected to the potential maintaining module 150 may transmit the fixed level signal Vh, same as the first level signal Vg1, to the fixed signal terminal VH, thereby controlling the potential maintaining module 150 to maintain the signal of the third node N3.

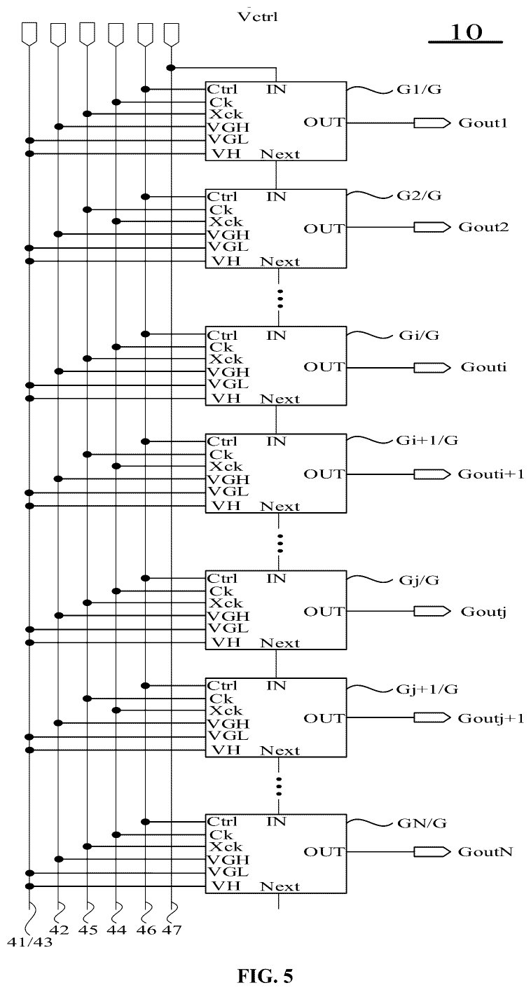

In another optional embodiment, FIG. 5 illustrates another structural schematic of a driver circuit according to various embodiments of the present disclosure. Referring to FIGS. 1, 3 and 5, when the display panel 100 includes at least one first signal transmission line 41 and the first signal transmission line 41 is configured to transmit the first level signal Vg1, both the drive output module 160 and the potential maintaining module 150 may be electrically connected to same first signal transmission line 41. In such way, the drive output module 160 and the potential maintaining module 150 of same shift register G may share one first signal transmission line 41, which may be beneficial for reducing the number of first signal transmission lines 41 electrically connected to same shift register G, thereby simplifying the structure of the display panel 100. Furthermore, when the first signal transmission line 41 is disposed in the non-display region of the display panel 100, it is beneficial for reducing the dimension of the non-display region of the display panel 100 and further beneficial for the narrow frame of the display panel 100.

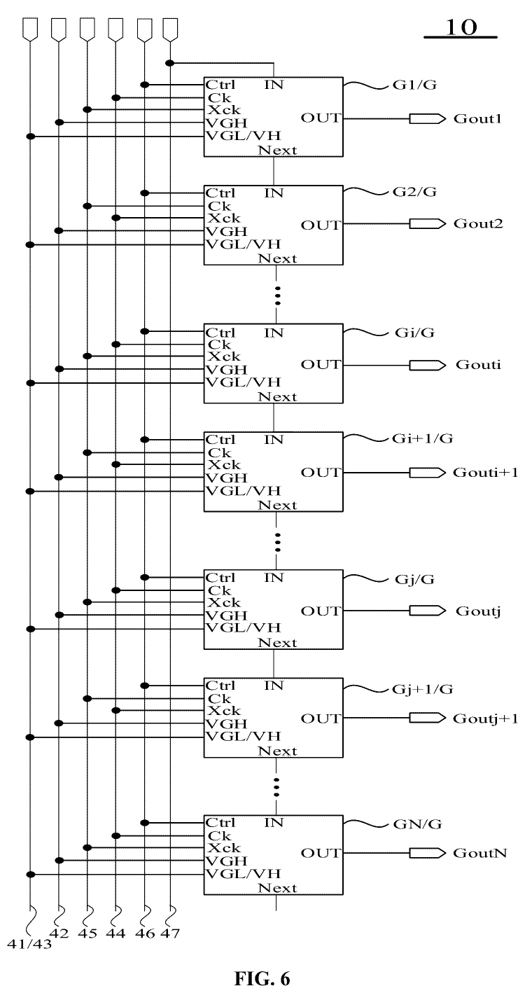

It should be noted that when the drive output module 160 and the potential maintaining module 150 of same shift register G share one first signal transmission line 41, the fixed signal terminal VH and the first level terminal VGL of same shift register G may be different signal terminals respectively. At this point, the potential maintaining module 150 and the drive output module 160 of same shift register G may need to be electrically connected to the first signal transmission line 41 through different connection structures respectively (as shown in FIG. 5). In another optional embodiment, as shown in FIG. 6, the first level terminal VGL and the fixed signal terminal VH in the same shift register G may also be same (signal terminal). At this point, the potential maintaining module 150 and the drive output module 160 of same shift register G may need to be electrically connected to the first signal transmission line 41 through same connection structure. In such way, the number of connection structures disposed in the display panel 100 may be reduced, which may be beneficial for simplifying the structure of the display panel 100, thereby being beneficial for reducing the formation cost of the display panel.

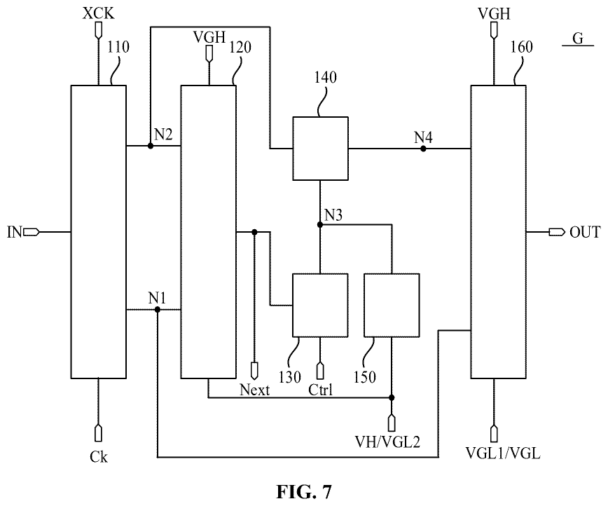

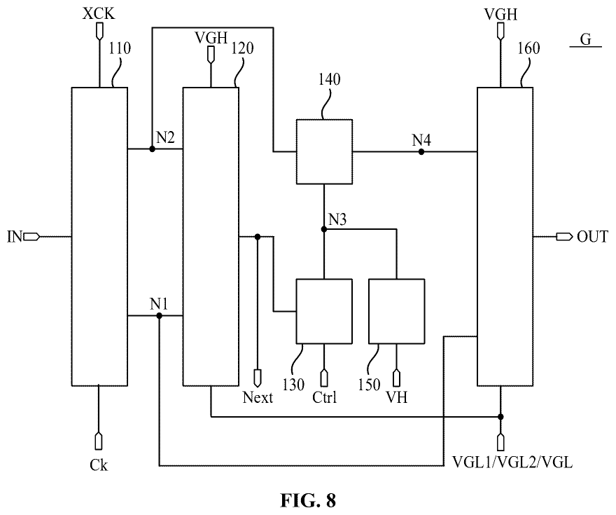

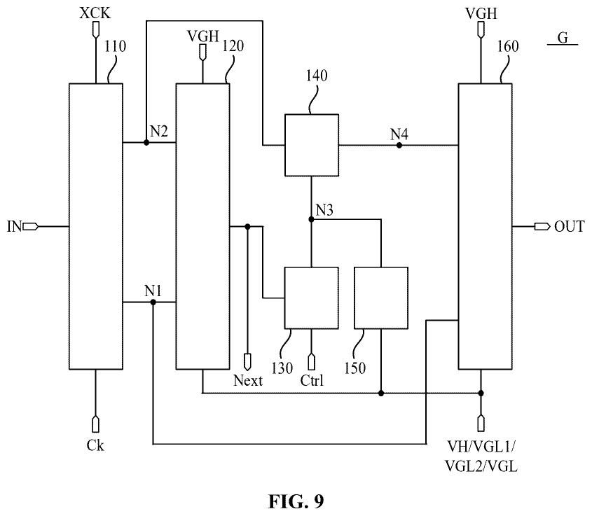

Optionally, FIG. 7 illustrates another structural schematic of a shift register according to various embodiments of the present disclosure; FIG. 8 illustrates another structural schematic of a shift register according to various embodiments of the present disclosure; and FIG. 9 illustrates another structural schematic of a shift register according to various embodiments of the present disclosure. Referring to FIGS. 2, 5 and 9, in the same shift register G, the shift output module 120 may be electrically connected to the first signal transmission line 41 through the potential maintaining module 150 and/or the drive output module 160.

Both the shift output module 110 and the drive output module 160 may receive the first level signal Vg1, and the first level signal Vg1 received by the shift output module 110 and the drive output module 160 may be same or different. Therefore, when the fixed level signal Vh is same as the first level signal Vg1, the fixed signal terminal VH for receiving the fixed level signal Vh may be same (signal terminal) as the first level terminal VGL2 for providing the first level signal Vg1 to the shift output module 120. At this point, the shift output module 120 may be electrically connected to the fixed signal terminal VH through the potential maintaining module 150, and then electrically connected to the first signal transmission line 41 through the fixed signal terminal VH; and the drive output module 160 may be electrically connected to the first signal transmission line 41 through the first level terminal VGL1 (as shown in FIGS. 5 and 7). Or the first level terminal VGL2 for providing the first level signal Vg1 to the shift output module 120 may be same (signal terminal) as the first level terminal VGL1 for providing the first level signal Vg1 to the drive output module 160. At this point, the shift output module 120 may be electrically connected to the first level terminal VGL1 through the drive output module 160, and then electrically connected to the first signal transmission line 41 through the first level terminal VGL1; and the potential maintaining module 15 may be directly and electrically connected to the first signal transmission line 41 through the fixed signal terminal VH (as shown in FIGS. 5 and 8). Or the fixed signal terminal VH, the first level terminal VGL2 providing the first level signal Vg1 to the shift output module 120, and the first level terminal VGL1 providing the first level signal Vg1 to the drive output module 160 may be all same (signal terminal). At this point, the shift output module 120 may be electrically connected to the first level terminal VGL1 through the potential maintaining module 150 and the drive output module 160 sequentially, and then electrically connected to the first signal transmission line 41 through the first level terminal VGL1.

In such way, when the shift output module 120 is electrically connected to the first signal transmission line 41 through the drive output module 160 and/or the potential maintaining module 150, the number of connection structures electrically connected to the first signal transmission line 41 may be reduced, which may be beneficial for simplifying the structure of the shift register G. Therefore, the structure of the shift register G may be more compact, and the dimension of the shift register G may be reduced, thereby reducing overall formation cost of the display panel and being beneficial for the narrow frame of the display panel.

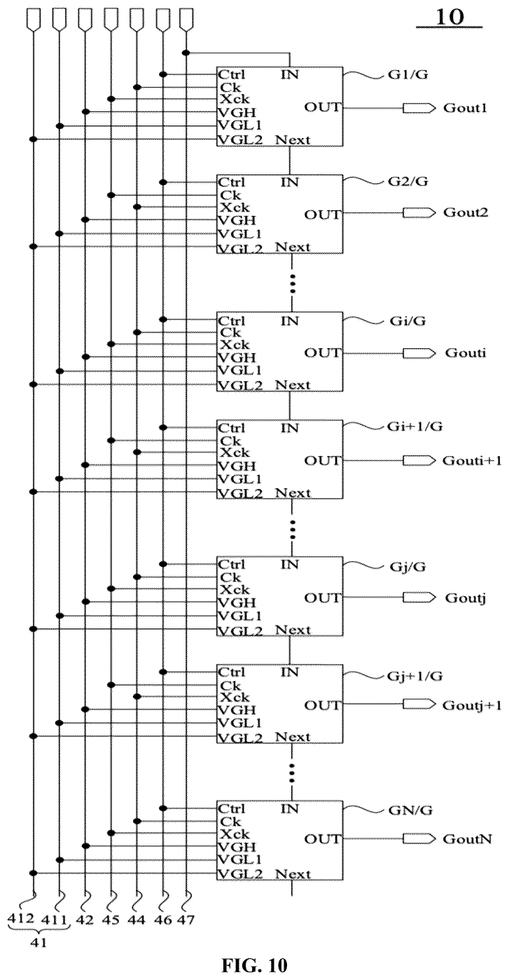

In another optional embodiment, FIG. 10 illustrates another structural schematic of a driver circuit according to various embodiments of the present disclosure. Referring to FIGS. 4 and 10, in the same shift register G, the drive output module 160 and the shift output module 120 may be electrically connected to different first signal transmission lines 41 (411, 412) respectively.

The drive output module 160 may be electrically connected to the first signal transmission line 411 through the first level terminal VGL1, and the shift output module 120 may be electrically connected to the first signal transmission line 412 through the first level terminal VGL2, such that the first signal transmission line 411 may provide the first level signal Vg1 to the drive output module 160, and the first signal transmission line 412 may provide the first level signal Vg1 to the shift output module 120. At this point, the first level signal Vg1 transmitted by the first signal transmission line 411 may be same as or different from the first level signal Vg1 transmitted by the first signal transmission line 411, which may be flexibly designed according to actual needs, thereby satisfying different display requirement of the display panel 100 and broadening application scenarios of the display panel 100. Meanwhile, when different first signal transmission lines 41 are configured to provide the first level signal Vg1 to the shift output module 120 and the drive output module 160 respectively, each first signal transmission line 41 may have relatively small load, such that each first signal transmission line 41 may have relatively small voltage drop, which may be beneficial for accuracy of the first level signal Vg1 transmitted by each first signal transmission line 41.

Optionally, referring to FIGS. 2-10, the drive output module 160 of the shift register G at each level may be electrically connected to same first signal transmission line 41; and the line width of the first signal transmission line 41 electrically connected to the drive output module 160 may be greater than or equal to 12 μm.

In the driver circuit 10, the drive output module 160 of the shift register G at each level may be electrically connected to same first signal transmission line 41, such that there is no need to separately dispose the first signal transmission line 41 for transmitting the first level signal Vg1 for the shift register G at each level, thereby being beneficial for simplifying the structure of the driver circuit 10, reducing the occupied dimension of the driver circuit 10, and further beneficial for the narrow frame of the display panel 100.

In addition, it may be understood that the drive output module 160 may output corresponding gate drive signal Gout according to the first level signal Vg1 transmitted by the first signal transmission line 41 electrically connected to the drive output module 160, and the gate drive signal Gout may be configured to control the display panel to refresh the signal, such that when the first level signal Vg1 transmitted by the first signal transmission line 41 has relatively large voltage drop, the gate drive signal Gout outputted by the drive output module 160 may be inaccurate, thereby not being able to accurately control the display panel to refresh the signal. At this point, the first signal transmission line 41 electrically connected to the drive output module 160 of the shift register G at each level may be configured to have relatively large line width; for example, the line width size may be greater than 12 μm. In such way, the first signal transmission line 41 may have relatively large cross-sectional region, thereby reducing the resistance of the first signal transmission line 41, reducing the voltage drop of the first level signal Vg1 transmitted by the first signal transmission line 41, and accurately providing the first level signal Vg1 to the shift register G at each level. Furthermore, the shift register G at each level may accurately output the gate drive signal Gout, and the display panel may accurately refresh the signal, thereby improving the display quality of the display panel. The line width of the signal line may be understood as the dimension of the signal line along the direction perpendicular to the extension direction of the signal line or may also be understood as the dimension of the relatively short side of the signal line.

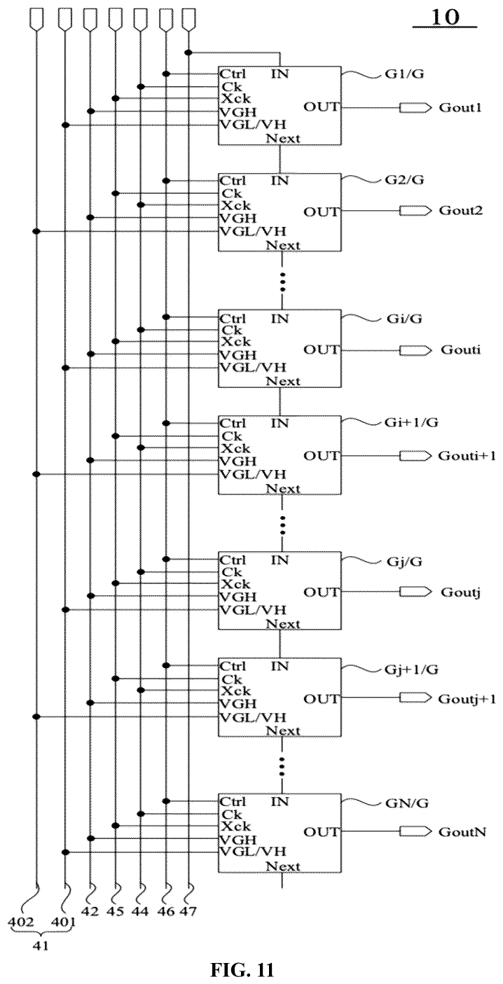

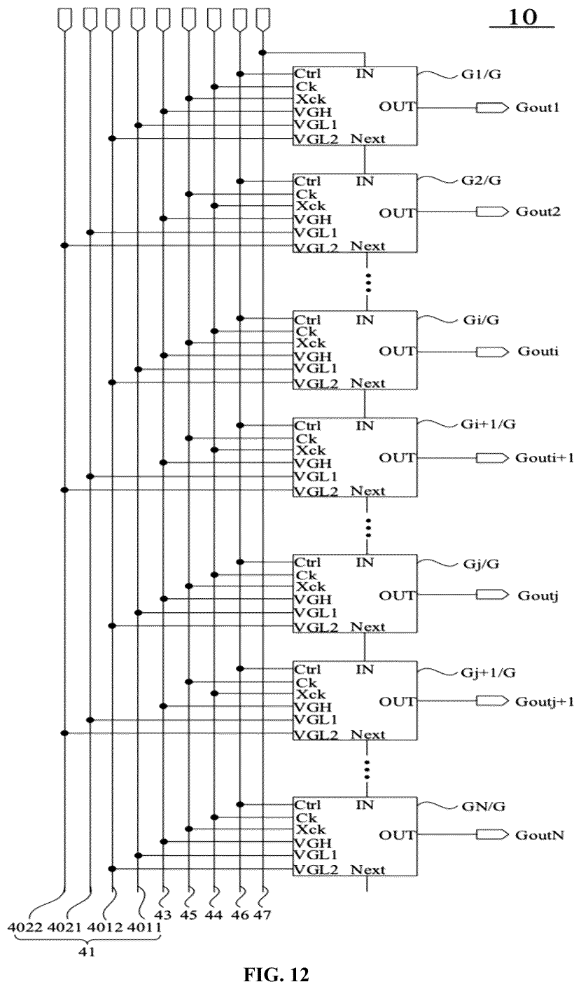

In another optional embodiment, FIG. 11 illustrates another structural schematic of a driver circuit according to various embodiments of the present disclosure; and FIG. 12 illustrates another structural schematic of a driver circuit according to various embodiments of the present disclosure. Referring to FIGS. 11-12, the drive output modules 160 of the shift registers G of any two adjacent levels may be electrically connected to different first signal transmission lines 41, respectively.

In one embodiment, referring to FIG. 11, the odd-numbered shift registers G may be electrically connected to the first signal transmission line 401, and the even-numbered shift registers G may be electrically connected to the first signal transmission line 402, such that the shift registers G of any two adjacent levels may be electrically connected to different first signal transmission lines 41, respectively. At this point, each first signal transmission line 41 may be electrically connected to fewer shift registers G, thereby reducing the load on each first signal transmission line 41 and being beneficial for reducing the voltage drop of the first level signal Vg1 transmitted by the first signal transmission line 41 and accurately providing the first level signal Vg1 to the shift register G at each level. Furthermore, the shift register G at each level may accurately output the gate drive signal Gout, and the display panel may accurately refresh the signal, thereby improving the display quality of the display panel.

In another embodiment, referring to FIG. 12, when the shift output module 120 and the drive output module 160 of same shift register G are electrically connected to different first signal transmission lines respectively, under the premise that the drive output modules 160 of the shift registers G of any two adjacent levels are electrically connected to different first signal transmission lines 41 respectively, the shift output modules 120 of the shift registers of any two adjacent levels may also be electrically connected to different first signal transmission lines 41 respectively. For example, the drive output module 160 of the odd-numbered shift register may be electrically connected to the first signal transmission line 4011, and the shift output module 120 of the odd-numbered shift register may be electrically connected to the first signal transmission line 4012; and the drive output module 160 of the even-numbered shift register may be electrically connected to the first signal transmission line 4021, and the shift output module 120 of the even-numbered shift register may be electrically connected to the first signal transmission line 4022. In such way, each first signal transmission line 41 may have relatively small load, which may make the shift register G at each level accurately output the gate drive signal Gout, thereby being beneficial for improving the display quality of the display panel.

It should be noted that as shown in FIGS. 11 and 12, the fixed level signal Vh may be same as the first level signal, and the fixed level terminal VH may be same (signal terminal) as the first level terminal VGL1 and/or the second level terminal VGL2, which may be taken as an example for illustration. In embodiments of the present disclosure, when the fixed level terminal VH is different from the first level terminal VGL1 and the second level terminal VGL2, a corresponding signal transmission line may also be configured separately for transmitting the fixed level signal Vh. The line width of such signal transmission line and the connection manner between the signal transmission line and the shift registers G at each level may be designed according to actual needs, which may not be limited in embodiments of the present disclosure. For the convenience of description, without special limitations, the fixed level signal Vh may be same as the first level signal Vg1, and the shift output module 120 in the same shift register G may be sequentially connected to the first signal transmission line 41 through the point maintaining module 150 and the drive output module 160, which may be taken as an example to exemplarily illustrate the technical solution of embodiments of the present disclosure.

Referring to FIG. 11, since the shift signal Vnextx outputted by the x-th-level shift register Gx is the input signal Viny received by the y-th-level shift register Gy, the x-th-level shift register Gx may be electrically connected to the y-th-level shift register Gy. For example, the shift signal output terminal Next for outputting the shift signal Vnextx in the x-th-level shift register Gx may be electrically connected to the signal input terminal IN for receiving the input signal Viny in the y-th-level shift register Gy. Exemplarily, when x=i, y may be equal to i+1. At this point, the shift signal output terminal Next of the i-th-level shift register Gi may be electrically connected to the signal input terminal IN of the (i+1)-th-level shift register Gi+1, such that the (i+1)-th-level shift register Gi+1 may output the shift signal Vnexti+1 under the control of the shift signal Vnexti outputted by the i-th-level shift register Gi, which may ensure that the valid level starting time point of the shift signal Vnext outputted by the shift register G at each level may be shifted sequentially, where i is a positive integer.

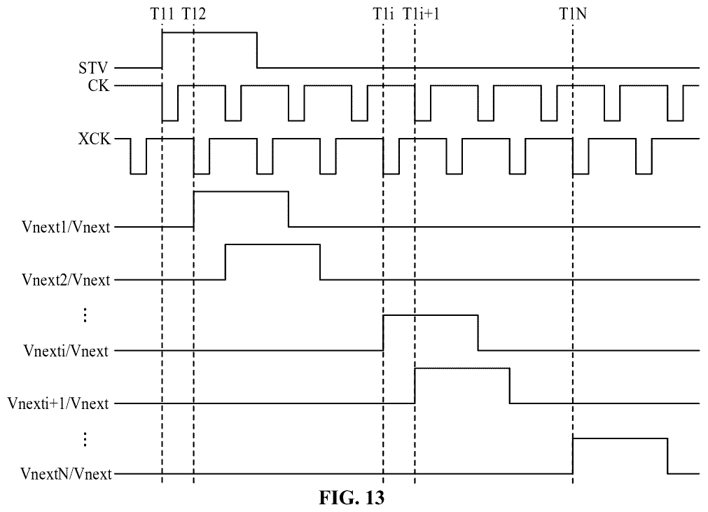

Exemplarily, FIG. 13 illustrates a driving time sequence diagram of a display panel according to various embodiments of the present disclosure. Referring to FIGS. 1, 9, 11 and 13, the shift control module 110 of the first-level shift register G1 may use the start control signal STV received by corresponding signal input terminal IN as its input signal Vin1, such that the shift control module 110 of the first-level shift register G1 may control the signals of the first node N1 and the second node N2 according to the start control signal STV; and furthermore, the shift output module 120 of the first-level shift register G1 may start to output the valid level of the shift signal Vnext1 at the time point T11 according to the signal of the first node N1 and the signal of the second node N2. The shift signal Vnext1 outputted by the first-level shift register G1 may be configured as the input signal Vin2 of the second-level shift register G2, such that the shift control module 110 of the second-level shift register G2 may control the signal of corresponding first node N1 and the signal of corresponding second node N2 according to the shift signal Vnext1 outputted by the first-level shift register G1; and furthermore, the shift output module 120 of the second-level shift register G2 may start to output the valid level of the shift signal Vnext2 at the time point T12 according to the signal of corresponding first node N1 and the signal of corresponding second node N2. Same or similar arrangement may be applied to all shift registers, e.g., the third, fourth till the i-th-level shift register. The i-th-level shift register Gi may output the valid level of the shift signal Vnexti at the time point T1i according to the input signal Vini received. The (i+1)-th-level shift register Gi+1 may start to output the valid level of the shift signal Vnexti+1 at the time point T1i+1 according to the input signal Vini+1 received; . . . ; and the N-th-level shift register GN may start to output the valid level of the shift signal VnextN at the time point TIN according to the input signal VinN received. T12 is after T11; T1i+1 is after T11, T12, . . . , T1i; and TIN is after 11, T12, . . . , T1i, T1i+1, . . . . T1N−1, such that the valid level starting time point of the shift signal Vnext outputted by the shift register G at each level may be shifted sequentially.

It should be noted that the valid level time of the shift signal Vnext outputted by the shift register G at each level may be same or different, which may be designed according to actual needs. The valid level time of the shift signal Vnext outputted by the shift register G at each level may be same, which is taken as an example for illustration. In such way, when the valid level starting time point of the shift signal Vnext outputted by the shift register G at each level is shifted sequentially, the valid level ending time point of the shift signal Vnext outputted by the shift register G at each level may also shift sequentially.

The above only exemplarily describes the scenario of the cascaded shift registers at various levels when x is less than y, x=i, and y=i+1. In embodiments of the present disclosure, the values of x and y may be designed according to actual needs. Under the premise that x is not equal to y, the values of x and y may not be limited in embodiments of the present disclosure.

Referring to FIGS. 1, 9, 11 and 13, the shift signal Vnextx outputted by the x-th-level shift register Gx may be configured as the input signal Viny of the y-th-level shift register Gy; and in the same shift register G, the shift signal Vnext and the gate drive signal Gout may be provided by the shift output module 120 and the drive output module 160 respectively, such that the shift signal Vnext may not be affected by the gate drive signal Gout. Therefore, while ensuring that the valid level starting time point of the shift signal Vnext outputted by the shift register G at each level is shifted sequentially, the gate drive signal Gout outputted by the shift register G at each level may be flexibly controlled by controlling the output control signal Vctrl received by the shift register G at each level and controlling the output control module 130 and the signal transmission module 140 of the shift register G at each level. Furthermore, the gate drive signal Gout outputted by the shift register G at each level may satisfy diversified display requirement of the display panel 100.

It should be noted that, since the gate drive signal Gout is flexibly controlled, the valid level time length of the gate drive signal Gout outputted by same shift register G may be same as or different from the valid level time length of the shift signal Vnext; and the valid level starting/ending time point of the gate drive signal Gout outputted by same shift register G may be same as or different from the valid level starting/ending time point of the shift signal Vnext. On the premise that the shift register G at each level may perform signal level transmission and satisfy different display requirement of the display panel 100, the valid level time of the shift signal Vnext and the gate drive signal Gout outputted by same shift register G may not be limited in embodiments of the present disclosure.

It may be understood that the valid level and the invalid level of the shift signal Vnext may be two relative concepts. That is, the valid level of the shift signal Vnext may be the high level, and the invalid level may be the low level; or the valid level of the shift signal Vnext may be the low level, and the invalid level may be the high level, which may not be limited in embodiments of the present disclosure. In a driving cycle, the shift signal Vnext may include the high level and the low level. In one embodiment, in the high level and the low level, the level with a relatively short time period may be configured as the valid level of the shift signal Vnext, and the level with a relatively long time period may be configured as the invalid level of the shift signal Vnext. Therefore, the valid level and invalid level of the shift signal Vnext may be not associated with specific control structures of the output control module 130 and/or the shift control module 110 of the shift register G at another level. Based on same principle, in a driving cycle, the valid level of the gate drive signal Gout may be the level with a relatively short time period in the high level and the low level; and the invalid level of the gate drive signal Gout may be the level with a relatively long time period in the high level and the low level. However, in embodiments of the present disclosure, the configuration of the valid level and the invalid level of other signals except the shift signal Vnext and the gate drive signal Gout may be determined according to the conduction and disconnection conditions of actual control module structures, which may not be limited in embodiments of the present disclosure. For ease of description, the valid level of the shift signal Vnext and the gate drive signal Gout may be the high level, and the invalid level of the shift signal Vnext and the gate drive signal Gout may be the low level, which is taken as an example to exemplarily illustrate the technical solution of embodiments of the present disclosure.

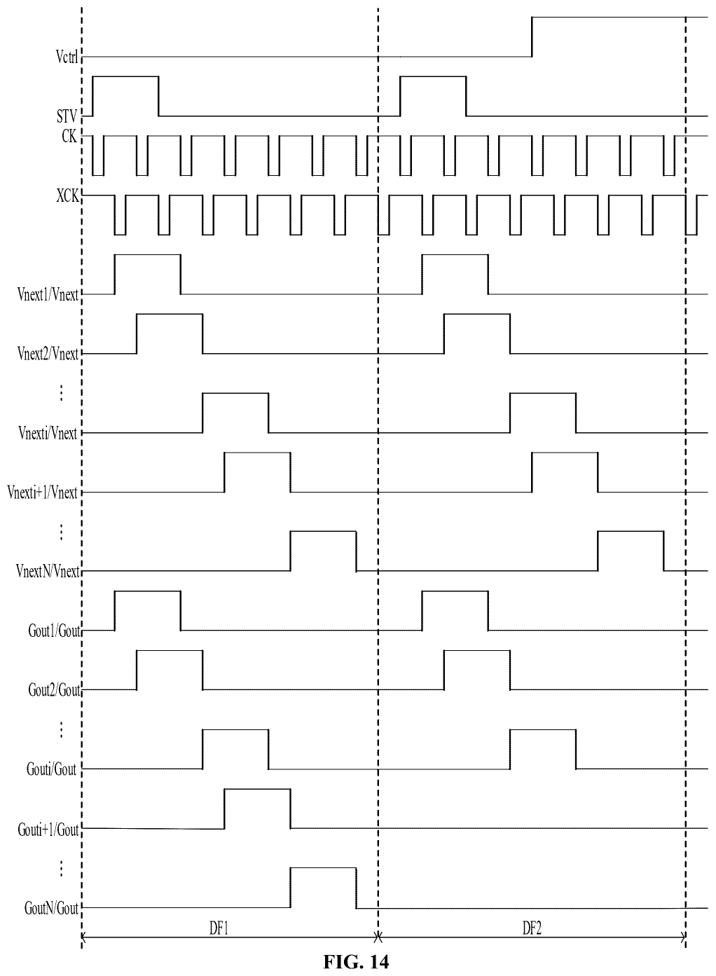

In an optional embodiment, FIG. 14 illustrates another driving time sequence diagram of a display panel according to various embodiments of the present disclosure. Referring to FIGS. 1, 9, 11 and 14, in the same shift register G, the gate drive signal Gout may be the invalid level during the time period when the shift signal Vnext is the valid level.

For example, the shift signal Vnextx outputted by the x-th-level shift register Gx may be configured as the input signal Viny of the y-th-level shift register Gy. Therefore, in order to enable the y-th-level shift register Gy to work normally, the x-th-level shift register Gx may need to provide the y-th-level shift register Gy with the shift signal Vnextx, including an enable level, to satisfy the signal level transmission requirement. Meanwhile, the gate drive signal Gout outputted by the shift register G at each level may be configured to control the signal refresh of the display panel 100. Therefore, when the display panel 100 needs to perform signal refresh, the gate drive signal Gout outputted by the shift register G may include the valid level; and when the display panel 100 does not need to perform signal refresh, the gate drive signal Gout outputted by the shift register G should include the valid level. In such way, the gate drive signal Gout may be the invalid level during the time period when the shift signal Vnext is at the valid level in the same shift register G, thereby satisfying the signal refresh requirement of the display panel 100.

In another optional embodiment, referring to FIGS. 1, 9, 11 and 14, in the same shift register G, the valid level time of the gate drive signal Gout may be overlapped with the valid level time of the shift signal Vnext. In such way, the display panel 100 may perform signal refresh while the shift register G performs signal level transmission. That is, the signal refresh of the display panel 100 may be synchronized with the signal level transmission of the shift register G to prevent the display time period of one frame of the display panel 100 from being affected by asynchrony between the signal level transmission and the signal refresh, thereby being beneficial for shortening the display time of one frame of the display panel 100 and increasing the refresh frequency of the display panel 100 while satisfying diversified display requirement of the display panel 100.

It may be understood that when the display panel 100 realizes diversified display, the display panel 100 may include multiple display modes, and the display panel may have different display brightness and/or refresh frequency in different display modes. At this point, the valid levels of the gate drive signals Gout outputted by the shift registers G at all levels may be controlled to have different time periods and/or cycles in different display modes. Or the number of display sub-regions included in the display panel may be different in different display modes, and the picture refresh frequencies and/or display brightnesses of all display sub-regions in the same mode may be different. At this point, in the same display mode, the gate drive signals outputted by all shift registers G electrically connected to all display sub-region may be controlled to have different valid level time periods and/or cycles. In such way, the valid level time periods and/or cycles of the gate drive signals Gout outputted by the shift registers G at all levels may be flexibly configured, thereby satisfying the display requirement of the display panel in different display modes.

In an optional embodiment, referring to FIG. 1, the display panel 100 may include a plurality of pixels 20 arranged in an array; and the pixel 20 may include a pixel circuit P and a light-emitting element D. The pixel circuit P may provide a driving current to the light-emitting element D according to written data signal, thereby driving the light-emitting element D to emit light. At this point, when the gate drive signal Gout outputted by the shift register G is configured to control the data signal writing of the pixel circuit P, by controlling the period of the valid level of the gate drive signal Gout outputted by the shift register G, the signal refresh frequency of the pixel circuit P may be controlled, thereby implementing the control of the picture refresh frequency of each display sub-region in the display panel. When the gate drive signal Gout outputted by the shift register G is configured to control the time length of the pixel circuit P of providing the driving current to the light-emitting element D, overall light-emitting brightness of the light-emitting element D may be controlled by controlling the time length of the valid level of the gate drive signal Gout outputted by the shift register G, thereby controlling the screen display brightness of each display sub-region in the display panel 100.

It should be noted that the structure of the pixel circuit P of each pixel 20 in the display panel 100 may be designed according to actual needs, which may not be limited in embodiments of the present disclosure. In an optional embodiment, as shown in FIG. 15, the pixel circuit P may at least include a compensation module 230, a data writing module 220 and a driving module 210. The driving module 210 may include a driving transistor T1; the data writing module 220 may be configured to control the data signal Vdata to be written to the driving module 210; the compensation module 230 may be configured to compensate the threshold voltage of the driving transistor T1 to the driving module 210; and the driving module 210 may be configured to selectively provide the driving current to the light-emitting element D to control the display light-emitting brightness of the light-emitting element D.

Furthermore, the pixel circuit P may further include a pixel reset module 240, which may be at least configured to provide a reset signal Vref to the gate electrode of the driving transistor T1 to reset the gate electrode of the driving transistor T1; an initialization module 250, which may be configured to provide an initialization signal Vini to the light-emitting element D to initialize the light-emitting element D; a light-emitting control module 260, which may be configured to control the time of providing the driving current to the light-emitting element D. Optionally, the light-emitting control module 260 may include the first light-emitting control module 261 and the second light-emitting control module 262. The first light-emitting control module 261 may be connected between the first power signal terminal and one electrode of the driving transistor T1, the second light-emitting control module 262 may be connected between another electrode of the driving transistor T1 and one electrode of the light-emitting element D, and another electrode of the light-emitting element D may be electrically connected to the second power signal terminal.

The control terminal of the data writing module 220 may receive the first scanning signal S1 which may control the turn on and off of the data writing module 220; the control terminal of the compensation module 230 may receive the second scanning signal S2 which may control the turn on and off of the compensation module 230; the control terminal of the pixel reset module 240 may receive the third scanning signal S3 which may control the turn on and off of the pixel reset module 240; the control terminal of the initialization module 250 may receive the fourth scanning signal S4 which may control the turn on and off of the initialization module 250; and the control terminal of the light-emitting control module 260 may receive a light-emitting control signal EM which may control the turn on and off of the light-emitting control module 260.

In an exemplary embodiment, the data writing module 220 may include a data writing transistor T2, and the first scanning signal S1 may control the turn on and off of the data writing transistor T2; the compensation module 230 may include a compensation transistor T3, and the second scanning signal S2 may control the turn on and off of the compensation transistor T3; the pixel reset module 240 may include a reset transistor T4, and the third scanning signal S3 may control the turn on and off of the reset transistor T4; the initialization module 250 may include an initialization transistor T5, and the fourth scanning signal S4 may control the turn on and off of the initialization transistor T5; and the first light-emitting control module 261 may include a first light-emitting control transistor T6, the second light-emitting control module 262 may include a second light-emitting control transistor T7, and the light-emitting control signal EM may control the turn on and off of the first light-emitting control transistor T6 and the second light-emitting control transistor T7.

Optionally, the pixel circuit P may further include a storage capacitor Cst. The first electrode of the storage capacitor Cst may be connected to the first power signal terminal, and the second electrode may be connected to the gate electrode of the driving transistor T1 for storing the gate signal of the driving transistor T1, such that in the light-emitting stage, the driving transistor T1 may continuously provide the driving current to ensure that the light-emitting element D may accurately emit light.

It may be understood that the first power signal terminal may provide the first power signal PVDD, and the second power signal terminal may provide the second power signal PVEE. A potential difference may be between the first power signal PVDD and the second power signal PVEE, such that the driving current may be generated between the first power signal PVDD and the second power signal PVEE, thereby driving the light-emitting element D to emit light for display.

It may also be understood that in the pixel circuit P, the types of the driving transistor T1, the data writing transistor T2, the compensation transistor T3, the reset transistor T4, the initialization transistor T5, the first light-emitting control transistor T6 and the second light-emitting control transistor T7 may be designed according to actual needs, which may not be limited in embodiments of the present disclosure. In an exemplary embodiment, the reset transistor T4 and the compensation transistor T3 may be NMOS (N-type metal oxide semiconductor) transistors; and the driving transistor T1, the data writing transistor T2, the initialization transistor T5, the first light-emitting control transistor T6 and the second light-emitting control transistor T7 may all be PMOS (P-type metal oxide semiconductor) transistors. In other optional embodiments, the driving transistor T1, the data writing transistor T2, the compensation transistor T3, the reset transistor T4, the initialization transistor T5, the first light-emitting control transistor T6 and the second light-emitting control transistor T7 may all be PMOS transistors. For NMOS transistors, the gate may be turned on for conduction when the signal received is at the high level and turned off for disconnection when the signal received is at the low level. For PMOS transistors, the gate may be turned on for conduction when the signal received is at the low level and turned off for disconnection when the signal received is at the high level. In such way, when the type of each transistor is changed, the signal received by the gate electrode of each transistor may be adjusted accordingly to achieve same working time sequence.

It should be noted that FIG. 15 exemplarily illustrates the structure of the pixel circuit, but the structure of the pixel circuit in embodiments of the present disclosure may be not limited thereto. On such basis, pixel circuits with increasing or decreasing corresponding transistors and other structures may be applicable to embodiments of the present disclosure, which may not be limited in embodiments of the present disclosure. For the convenience of description, without special limitation, the pixel circuit shown in FIG. 1 may be taken as an example to exemplarily describe the technical solution of embodiments of the present disclosure.

Referring to FIGS. 11 and 15, in one embodiment, the gate drive signal Gout outputted by the shift register G may control at least one of the data writing module 220, the compensation module 230, the pixel reset module 240, the initialization module 250 and the light-emitting control module 260 to be turned on or off. That is, the gate drive signal Gout outputted by the shift register G may be at least one of the first scanning signal S1, the second scanning signal S2, the third scanning signal S3, the fourth scanning signal S4 and the light-emitting control signal EM, which may not be limited in embodiments of the present disclosure under the premise of capable of implementing the core concept (solution) of embodiments of the present disclosure.

The compensation module 230 and the initialization module 240 may be both directly electrically connected to the gate electrode of the driving transistor T1. Therefore, if the gate drive signal Gout outputted by the shift register G controls the compensation module 230 or the initialization module 250 to be turned on or off, the data signal written to the driving transistor T1 in previous pixel cycle (period) may be cleared when the gate drive signal G outputted by the shift register G is at the valid level, such that the data signal of current pixel cycle may be accurately written, thereby realizing the signal refresh of the pixel circuit P; and if the gate drive signal Gout outputted by the shift register G controls the conduction time length of the light-emitting control module 260, the time length for providing the driving current to the light-emitting element D may be controlled, thereby controlling overall display light-emitting brightness of the light-emitting element D.

In such way, in different modes, when the display region of the display panel includes different display sub-regions, if the display brightnesses of all display sub-regions are different in the same display mode, the shift registers electrically connected to the pixel circuits of different display sub-regions may be controlled to output gate drive signals with different valid level time lengths in the same display mode; and if the refresh frequencies of all display sub-regions are different in the same display mode, the shift registers electrically connected to the pixel circuits of different display sub-regions may be controlled to output valid levels of different frequencies in the same display mode.

For the convenience of description, without special limitations, the number of display sub-regions included in the display panel may be different in different display modes, and the refresh frequencies of all display sub-regions may be different in the same display mode, which may be taken as an example to exemplarily describe the technical solution of embodiments of the present disclosure.

Optionally, referring to FIGS. 1, 9, 11 and 14, the working mode of the display panel 100 may include the first mode; in the first mode, at least a part of the shift registers G may be first shift registers, and the output control signal Vctrl may include the valid level and the invalid level; and for at least partial time of the first mode, in the first shift registers, the frequency of the shift signal Vnext may be greater than the frequency of the gate drive signal Gout.

In the same shift register, when the shift output module 120 outputs the shift signal Vnext to control the output control module 130 to be turned on, the output control module 130 may transmit the output control signal Vctrl to the third node N3, such that the signal of the third node N3 may be consistent with the output control signal Vctrl. At this point, if the output control signal Vctrl is at the valid level, the signal of the third node N3 may also be at the valid level; and if the output control signal Vctrl is at the invalid level, the signal of the third node N3 may also be at the invalid level. When the signal of the third node N3 is at the valid level, the transmission control module 140 may be controlled to transmit the signal of the second node N2 to the fourth node N4, such that the signal of the fourth node N4 may be consistent with the signal of the second node N2. At this point, the shift signal Vnext outputted by the shift output module 120 may be controlled to be consistent with the gate drive signal Gout outputted by the drive output module 160; that is, when the shift signal Vnext is at the valid level, the gate drive signal Gout may also be at the valid level. Furthermore, when the signal of the third node N3 is at the invalid level, the transmission control module 140 cannot be controlled to transmit the signal of the second node N2 to the fourth node N4, such that the gate drive signal Gout cannot be synchronized with the shift signal Vnext, and the valid level may be maintained.

In one embodiment, by configuring that the output control signal Vctrl includes the valid level and the invalid level, when the shift output module 120 of the first shift register is controlled to output the valid level of the shift signal Vnext in a partial time period (for example, the frame picture display time DF1), the signal of the third node N3 may be at the valid level, such that the first shift register may output the valid level of the gate drive signal Gout in such time period, and the pixel 20 electrically connected to the first shift register may perform signal refresh. In another part of the time period (for example, the frame picture display time DF2), when the shift output module 120 of the first shift register is controlled to output the valid level of the shift signal Vnext, the signal of the third node N3 may be at the invalid level, such that the first shift register cannot output the valid level of the gate drive signal Gout. That is, in such time period, the gate drive signal Gout outputted by the first shift register may continue to maintain the invalid level, such that the pixel 20 electrically connected to the first shift register cannot perform signal refresh. In such way, the valid level interval time of the shift signal Vnext outputted by the first shift register may be less than the valid level interval time of the gate drive signal Gout outputted by the first shift register; that is, the frequency of the shift signal Vnext outputted by the first shift register may be greater than the frequency of the gate drive signal Gout outputted by the first shift register, such that the signal level transmission of the shift register G at each level may be ensured in each time period (the display time DF1 and DF2 of each frame). Meanwhile, according to the signal refresh requirement of the pixel 20 electrically connected to the first shift register in the display panel 100, the gate drive signal Gout outputted by the first shift register may be controlled to have relatively long valid level interval time, the signal refresh cycle of the pixel 20 may be extended, and the number of signal refreshes of the pixel 20 per unit time may be reduced, which may be beneficial for reducing the power consumption caused by the signal refresh of the pixel 20 and further beneficial for low power consumption of the display panel 100.

It may be understood that at least a part of the shift registers G may be the first shift registers; that is, a part of the shift registers G may be the first shift registers, or all of the shift registers G may be the first shift registers, which may be designed according to actual needs and may not be limited in embodiments of the present disclosure.

In an optional embodiment, when all shift registers G are the first shift registers, in the first mode, there may be valid level interval time of the gate drive signals Gout corresponding to the shift registers G at all levels; and in the same time period, the valid level interval time of the gate drive signals Gout of the shift registers G at all levels may be same or different, which may be designed according to actual need and may not be limited in embodiments of the present disclosure.

In another optional embodiment, when a part of the shift registers G is the first shift registers in the first mode, another part of the shift registers G may include the second shift registers; and in the second shift register, the frequency of the shift signal Vnext may be equal to the frequency of the gate drive signal Gout.

It may be understood that in the second shift register, the frequency of the shift signal Vnext may be equal to the frequency of the gate drive signal Gout; that is, the valid level interval time of the shift signal Vnext of the second shift register may be same as the interval time of the gate drive signal Gout. For example, when the second shift register outputs the valid level of the shift signal Vnext, the second shift register may simultaneously output the valid level of the gate drive signal Gout, such that the signal refresh cycle of the pixel 20 electrically connected to the second shift register may be consistent with the cycle of the signal level transmission of the shift register at each level. In such way, the signal refresh frequency of the pixel 20 electrically connected to the second shift register may be greater than the signal refresh frequency of the pixel 20 electrically connected to the first shift register. Therefore, the pixels 20 in the display panel 100 may be refreshed in different regions in the display time (DF1) of one frame. For example, the pixels 20 in the display sub-region with higher display quality requirement may be controlled to have a higher signal refresh frequency; and the pixels 20 in the display sub-region with lower display quality requirement may be controlled to have a lower signal refresh frequency, thereby satisfying high-quality display requirement of the display panel 100 while making the display panel 100 have lower power consumption.

In one embodiment, referring to FIGS. 1, 9, 11 and 14, in the first mode, the display panel 100 may include two display sub-regions. The display sub-regions, where the pixels 20 electrically connected to the shift registers G (G1, G2, . . . , Gi) from the first-level shift register G1 to the i-level shift register Gi are located, may be the display sub-region with a high refresh rate; and the display sub-regions, where the pixels 20 electrically connected to the shift registers G (Gi+1, . . . , GN) from the (i+1)-level shift register Gi+1 to the N-level shift register GN are located, may be the display sub-region with a low refresh rate, which may be taken as an example for illustration. At this point, the shift registers G (G1, G2, . . . , Gi) at all levels from the first-level shift register G1 to the i-th-level shift register Gi may all be second shift registers, and the shift registers from the (i+1)-th-level shift register G1 to the N-th-level shift register GN may all be first shift registers.

When the display mode of the display panel 100 is the first mode, the display panel may include a plurality of display cycles, each display cycle may include the display time of multiple frames; for example, each display cycle may include the display time of two frames. During the display time DF1 of the first frame, the output control signal Vctrl may be controlled to maintain at the valid level, such that the signals transmitted to the third nodes N3 of the shift register G at all levels (G1, G2, . . . , Gi, Gi+1, . . . , GN) may be all valid levels. During the display time DF1 of the first frame, the shift registers G at all levels (G1, G2, . . . , Gi, Gi+1, . . . , GN) may sequentially output the valid levels of the shift signals Vnext (Vnext1, Vnext2, . . . , Vnexti, Vnexti+1, . . . , VnextN), and also sequentially output the valid levels of the gate drive signals Gout (Gout1, Gout2, . . . , Gouti, Gouti+1, . . . , GoutN), such that the pixels 20 electrically connected to the shift registers from the first-level shift register G1 to the i-th-level shift register Gi and the pixels 20 electrically connected to the shift registers from the (i+1)-th-level shift register G1 to the N-th-level shift register GN may simultaneously perform signal refresh. During the display time DF2 of the second frame, when the output control signal Vctrl is transmitted to the third nodes N3 of all shift registers G (G1, G2, . . . , Gi) from the first-level shift register G1 to the i-level shift register Gi, the output control signal Vctrl may be controlled to be at the valid level. Therefore, while all-level shift registers G (G1, G2, . . . , Gi) from the first-level shift register G1 to the i-level shift register Gi sequentially output the valid levels of the shift signals Vnext (Vnext1, Vnext2, . . . , Vnexti), all-level shift registers G (G1, G2, . . . , Gi) from the first-level shift register G1 to the i-level shift register Gi may also sequentially output the valid levels of the gate drive signals Gout (Gout1, Gout2, . . . , Gouti), such that the pixels 20 electrically connected to the shift registers G (G1, G2, . . . , Gi) from the first-level shift register G1 to the i-level shift register Gi may perform signal refresh.

During the display time DF2 of the second frame, when the output control signal Vctrl is transmitted to the third nodes N3 of all-level shift registers G from the first-level shift register G1 to the i-th-level shift register Gi, the output control signal Vctrl may be controlled to be at the valid level. Therefore, while all shift registers G (G1, G2, . . . , Gi) from the first-level shift register G1 to the i-th-level shift register Gi sequentially output the valid levels of the shift signals Vnext (Vnext1, Vnext2, . . . , Vnexti), all-level shift registers G (G1, G2, . . . , Gi) from the first-level shift register G1 to the i-th-level shift register Gi may also sequentially output the gate drive signal Gout (Gout1, Gout2, . . . , Gouti), such that the pixels 20 electrically connected to the shift registers G (G1, G2, . . . , Gi) from the first-level shift register G1 to the i-level shift register Gi may perform signal refresh. When the third nodes N3 of all-level shift registers G (Gi+1, . . . , GN) from the (i+1)-level shift register Gi+1 to the N-level shift register GN transmit the output control signal Vctrl, the output control signal Vctrl may be controlled to be at the invalid level. Therefore, when all-level shift registers G (Gi+1, . . . , GN) from the (i+1)-level shift register Gi+1 to the Nth-level shift register GN sequentially output the valid level of the shift signal Vnext (Vnexti+1, . . . , VnextN), all-level shift registers G (Gi+1, . . . , GN) from the (i+1)-level shift register Gi+1 to the Nth-level shift register GN cannot output the valid level of the gate drive signal Gout (Gouti+1, . . . , GoutN), such that the pixels 20 electrically connected to all-level shift registers G (Gi+1, . . . , GN) from the (i+1)-level shift register Gi+1 to the Nth-level shift register GN cannot perform signal refresh.

In such way, in one display cycle of the display panel, the frequencies of the shift signals Vnext (Vnext1, Vnext2, . . . , Vnexti) for controlling the second shift registers G (G1, G2, . . . , Gi) may be equal to the frequencies of corresponding gate drive signals Gout (Gout1, Gout2, . . . , Gouti); and the frequencies of the shift signals Vnext (Vnexti+1, . . . , VnextN) for controlling the first shift registers G (Gi+1, . . . , GN) may be greater than the frequencies of corresponding gate drive signals Gout (Gouti+1, . . . , GoutN), which may control the signal refresh time of the pixels 20 in each display sub-region of the display panel 100 as needed, thereby satisfying diversified display requirement of the display panel 100.

It may be understood that the shift signal Vnext outputted by the shift output module 120 in the same shift register G may control the output control module 130 to be turned on or off. In such way, when the shift signal Vnext controls the output control module 130 to be turned on for conduction, the output control signal Vctrl may be transmitted to the third node N3, and the signal of the third node N3 may control the transmission control module 140 to be turned on or off; and when the signal of the third node N3 control the transmission control module 140 to be turned on for conduction, the signal of the fourth node N4 may be remained to be consistent with the signal of the second node N2. Accordingly, the gate drive signal Gout outputted by the drive output module 160 may be controlled to be consistent with the shift signal Vnext, such that the gate drive signal Gout may also be at the valid level when the shift signal Vnext is at the valid level. Furthermore, when the signal of the third node N3 controls the transmission control module 140 to be turned off for disconnection, the signal of the fourth node N4 cannot be consistent with the signal of the second node N2, such that the gate drive signal Gout cannot be changed to the valid level when the shift signal Vnext is changed to the valid level. In such way, the valid level time of the signal of the third node N3 may be related to the valid level time of the gate drive signal Gout outputted by the drive output module 160. Therefore, when the shift output module 120 outputs the valid level of the shift signal Vnext, if the signal of the third node N3 changes between the invalid level and the valid level, the valid level time of the gate drive signal Gout outputted by the drive output module 160 may be affected, which may result in inaccurate gate drive signal outputted by the drive output module 160.

To solve above technical problems, in the same shift register G, before corresponding shift signal Vnext is changed to the valid level, the output control module 130 may be controlled to be in a turn-on state to transmit the output control signal Vctrl to the third node N3; and when the shift signal Vnext is changed to the valid level, the output control module 130 may be controlled to be in a turn-off state, such that the output control signal Vctrl cannot be transmitted to the third node N3. Therefore, the signal of the third node N3 may not change with the output control signal Vctrl to ensure that the signal of the third node N3 may be a stable signal when the shift signal Vnext is at the valid level, thereby ensuring that the drive output module 160 may stably and accurately output the gate drive signal Gout.

In an optional embodiment, in order to make the frequency of the gate drive signal GOUT outputted from the first shift register to be less than the frequency of the shift signal VNEXT, the output control signal Vctrl may be controlled to be the invalid level before the shift signal Vnext is changed to the valid level. That is, the invalid level time of the shift signal Vnext may be overlapped with the invalid level time of the output control signal VCTRL, such that the invalid level of the output control signal VCTRL may be transmitted to the third node N3, the signal of the third node N3 may control the fourth node N4 to maintain the invalid level, and the gate drive signal GOUT may be at the invalid level when the shift signal Vnext is the valid level.

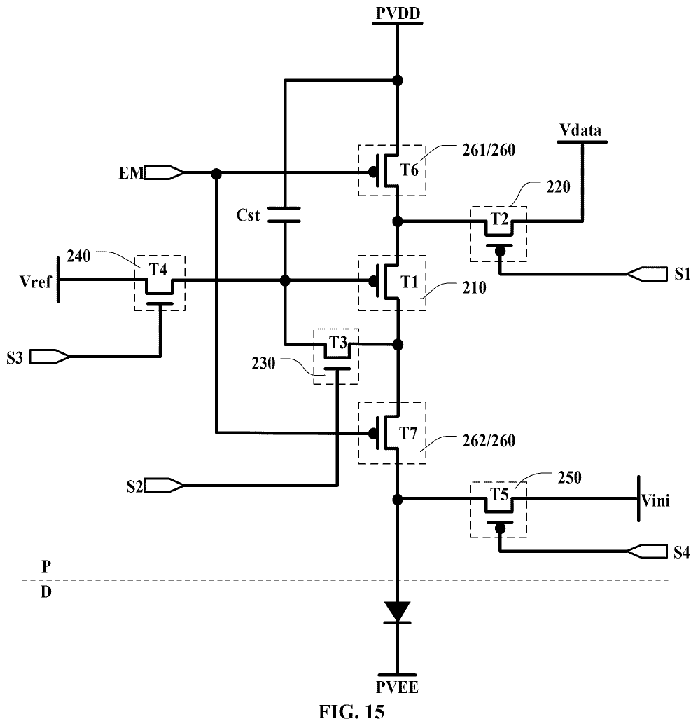

In an optional embodiment, FIG. 16 illustrates another driving time sequence diagram of a display panel according to various embodiments of the present disclosure. Referring to FIGS. 1, 9, 11 and 16, in the first shift register G, the time point that the output control signal VCTRL changes from the valid level to the invalid level is the first time point Tc1; and the valid level starting time point of the shift signal Vnext is the second time point Ti+1. The first time point Tc1 may be before the second time point Ti+1.

The frequency of the gate drive signal GOUT of the first shift register G is less than the frequency of corresponding shift signal VNEXT. Therefore, in partial time period of the first mode, the gate drive signal GOUT may still maintain the invalid level when the first shift register G outputs the valid level of the shift signal VNEXT. That is, the signal of the third node N3 of the first shift register G within such time period should continue to be at the invalid level. By controlling the first time point Tc1 to be before the second time Ti+1, the output control signal Vctrl may change from the valid level to the invalid level before the shift signal Vnext outputted from the first shift register G is changed to the valid level to control the output control module 139 to be turned off. In such way, the invalid level of the output control signal VCTRL may be transmitted to the third node n3 of the first shift register G; and when the shift signal Vnext of the first shift register G is changed to the valid level, the signal of the third node N3 may continue to maintain the invalid level. Therefore, the first shift register G may continue and stably output the invalid level of the gate drive signal GOUT; and furthermore, the display sub-region, where the pixels electrically connected to the first shift registers G are located, may satisfy the display requirement of relatively low refresh frequency.

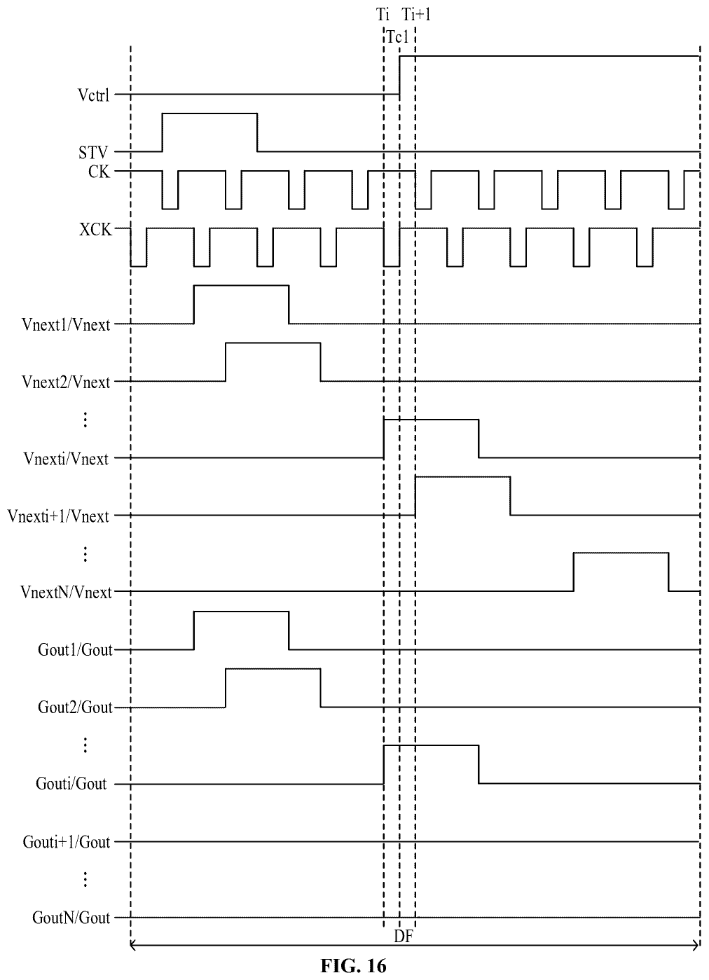

In another optional embodiment, FIG. 17 illustrates another driving time sequence diagram of a display panel according to various embodiments of the present disclosure. Referring to FIGS. 1, 9, 11 and 17, in the second shift register G, the time point when the output control signal Vctrl jumps from the invalid level to the valid level is the third time point Tc2; and the valid level starting time point of the shift signal Vnext is the fourth time point Ti; and the third time point Tc2 may be after the fourth time point Ti.

The frequency of the gate drive signal Gout of the second shift register G may be equal to the frequency of corresponding shift signal Vnext. Therefore, in the first mode, when the second shift register G outputs the valid level of the shift signal Vnext, corresponding gate drive signal Gout may also be at the valid level. By controlling the third time point Tc2 to be after the fourth time point Ti, the output control signal Vctrl may be ensured to be the valid level before the shift signal Vnext outputted by the second shift register G is changed to the valid level to control corresponding output control module 130 to be turned off. In such way, the valid level of the output control signal Vctrl may be transmitted to the third node N3 of the second shift register G; and when the shift signal Vnext of the second shift register G is changed to the valid level, the signal of the third node N3 may continue to maintain the valid level. Therefore, when the second shift register G outputs the valid level of the shift signal Vnext, the second shift register G may continuously and stably output the valid level of the gate drive signal Gout; and furthermore, the display sub-region, where the pixels electrically connected to the second shift registers G are located, may satisfy the display requirement of relatively high refresh frequency.

In an exemplary embodiment, referring to FIGS. 1, 9, 11 and 16, when the driver circuit includes both the first shift registers and the second shift registers, if the i-th-level shift register Gi is the second shift register and the (i+1)-th-level shift register Gi+1 is the first shift register, in the display time DF of one frame, the first time point Tc1 that the output control signal Vctrl jumps from the valid level to the invalid level may be between the valid level starting time point Ti of the shift signal Vnexti of the i-th-level shift register Gi and the valid level starting time point of the shift signal Vnexti+1 of the (i+1)-th-level shift register Gi+1. In such way, it may ensure that during the time period when the shift signal Vnexti of the i-th-level shift register Gi is at the valid level, the signal of the third node N3 of the i-th-level shift register Gi may be at the valid level, thereby ensuring that the i-th-level shift register Gi may accurately output the valid level of the gate drive signal Gout. Furthermore, before the shift signal Vnexti+1 of the (i+1)-th-level shift register Gi+1 is changed to the valid level, the output control signal Vctrl may be controlled to be changed to the invalid level. In such way, when the shift signal Vnexti+1 of the (i+1)-th-level shift register Gi+1 is changed to the valid level, the signal of the third node N3 of the (i+1)-th-level shift register Gi+1 may be the invalid level; and the (i+1)-level shift register Gi+1 may stably output the invalid level of the gate drive signal Gout.

In another exemplary embodiment, referring to FIGS. 1, 9, 11 and 17, if the i-th-level shift register Gi is the first shift register and the (i+1)-th-level shift register Gi+1 is the second shift register, in the display time DF of one frame, the third time point Tc2 that the output control signal Vctrl jumps from the invalid level to the valid level may be between the valid level starting time point Ti of the shift signal Vnexti of the i-th-level shift register Gi and the valid level starting time point of the shift signal Vnexti+1 of the (i+1)-th-level shift register Gi+1. In such way, it may ensure that during the time period when the shift signal Vnexti of the i-th-level shift register Gi is at the valid level, the signal of the third node N3 of the i-th-level shift register Gi may be at the invalid level, thereby ensuring that the i-th-level shift register Gi may continuously output the invalid level of the gate drive signal Gout. In addition, before the shift signal Vnexti+1 of the (i+1)-th-level shift register Gi+1 is changed to the valid level, the output control signal Vctrl may be controlled to be changed to the valid level. In such way, when the shift signal Vnexti+1 of the (i+1)-th-level shift register Gi+1 is changed to the valid level, the signal of the third node N3 of the (i+1)-th-level shift register Gi+1 may be at the valid level; and the (i+1)-th-level shift register Gi+1 may accurately output the valid level of the gate drive signal Gout.

It should be noted that as disclosed above, the output control signal may jump between the valid level and the invalid level once in the display time of one frame, which may be taken as an example for illustration. In other embodiments of the present disclosure, the number of jumps of the output control signal in the display time of one frame may be two or more; and specific jump scenarios may be designed according to actual needs, which may not be limited in embodiments of the present disclosure.

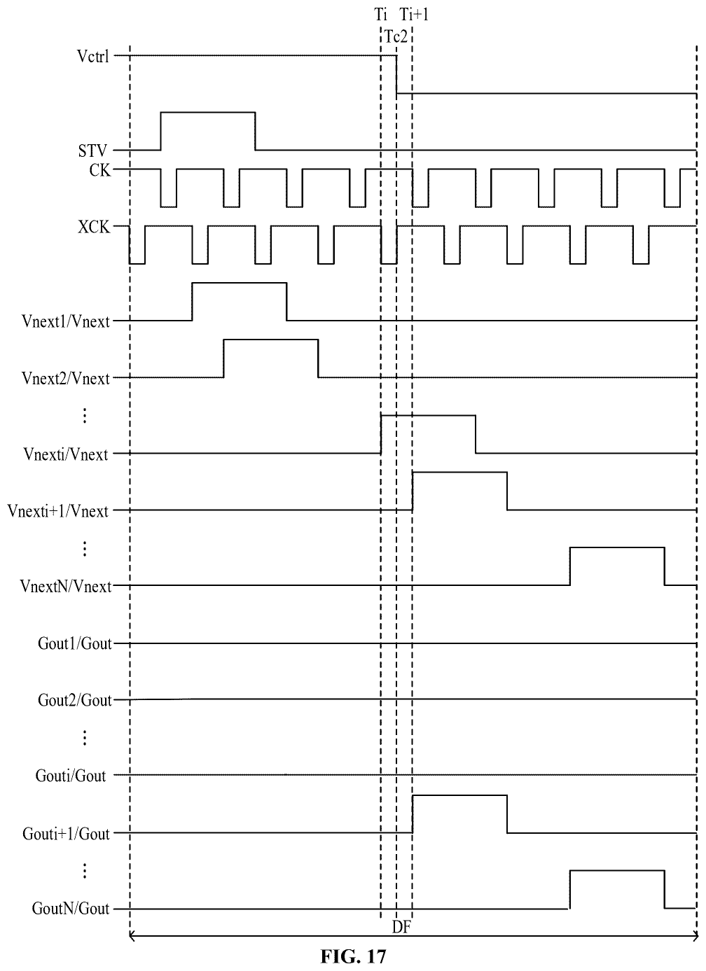

Exemplarily, FIG. 18 illustrates another driving time sequence diagram of a display panel according to various embodiments of the present disclosure. Referring to FIGS. 1, 9, 11 and 18, the shift registers G at all levels from the first-level shift register G1 to the i-th-level shift register Gi and from the (j+1)-th-level shift register Gj+1 to the N-th-level shift register GN may be all first shift registers; and the shift registers from the (i+1)-th-level shift register Gi+1 to the j-th-level shift register Gj may be all second shift registers, which may be taken as an example for illustration. In such way, in the display time DF of one frame, the third time point Tc3 that the output control signal Vctrl jumps from the invalid level to the valid level may be between the valid level starting time point Ti of the shift signal Vnexti of the i-th-level shift register Gi and the valid level starting time point of the shift signal Vnexti+1 of the (i+1)-th-level shift register Gi+1; and the first time point Tc1 that the output control signal Vctrl jumps from the valid level to the invalid level may be between the valid level starting time point Tj of the shift signal Vnextj of the j-th-level shift register Gj and the valid level starting time point of the shift signal Vnextj+1 of the (j+1)-th-level shift register Gj+1. In such way, it may ensure that during the time period when the shift signals Vnext (Vnexti+1, . . . , Vnextj) outputted by all-level shift registers G from the (i+1)-th-level shift register Gi+1 to the j-th shift register Gj are at the valid level, the signals of the third nodes N3 of all-level shift registers G from the (i+1)-th-level shift register Gi+1 to the j-th shift register Gj may be at the valid level, thereby ensuring that all-level shift registers G from the (i+1)-th-level shift register Gi+1 to the j-th shift register Gj may sequentially output the valid levels of the gate drive signals Gout (Gouti+1, . . . , Goutj). In addition, when the shift signals Vnext (Vnext1, Vnext2, . . . , Vnexti, Vnextj+1, . . . , VnextN) of all-level shift registers G from the first-level shift register G1 to the i-level shift register Gi and from the (j+1)-th-level shift register Gj+1 to the N-level shift register GN are at the valid level, all-level shift registers G from the first-level shift register G1 to the i-th-level shift register Gi and from the (j+1)-th-level shift register Gj+1 to the N-th-level shift register GN may still maintain the invalid levels of the output gate drive signals Gout (Gout1, Gout2, . . . , Gouti, Goutj+1, . . . , GoutN).

It should be noted that the above only exemplarily illustrates the changes in the output control signal of the display panel in the first mode and the gate drive signal outputted by the shift register at each level. In one embodiment of the present disclosure, the display panel may include multiple display modes, and the changes in the output control signal in each display mode and the gate drive signal outputted by each shift register may be designed according to actual needs, which may not be limited in embodiments of the present disclosure.

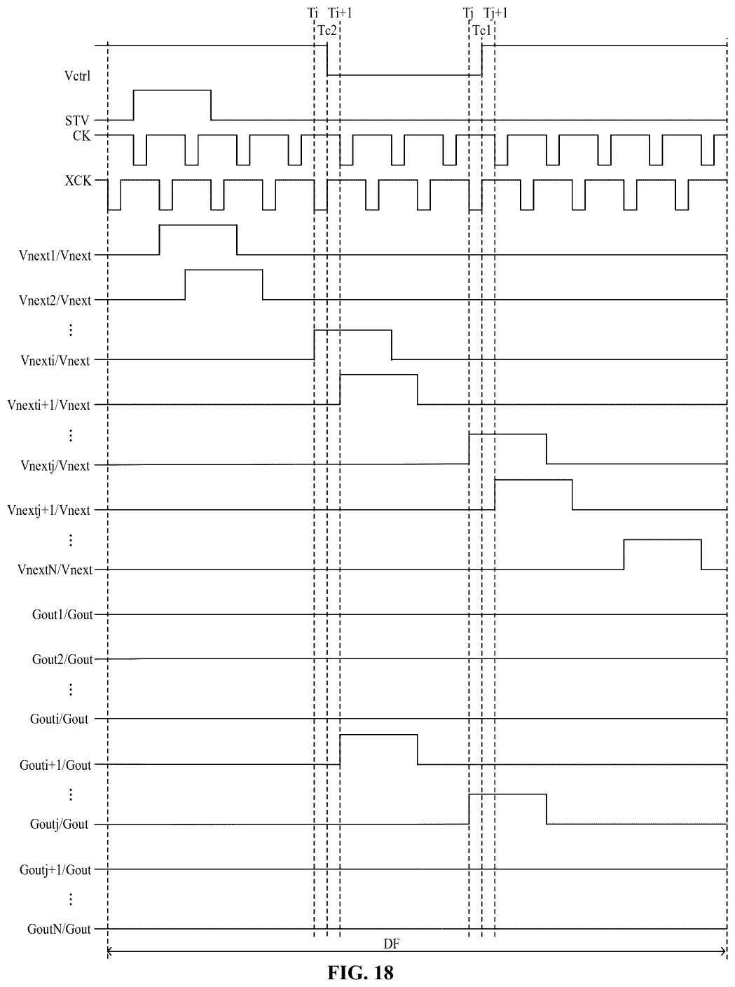

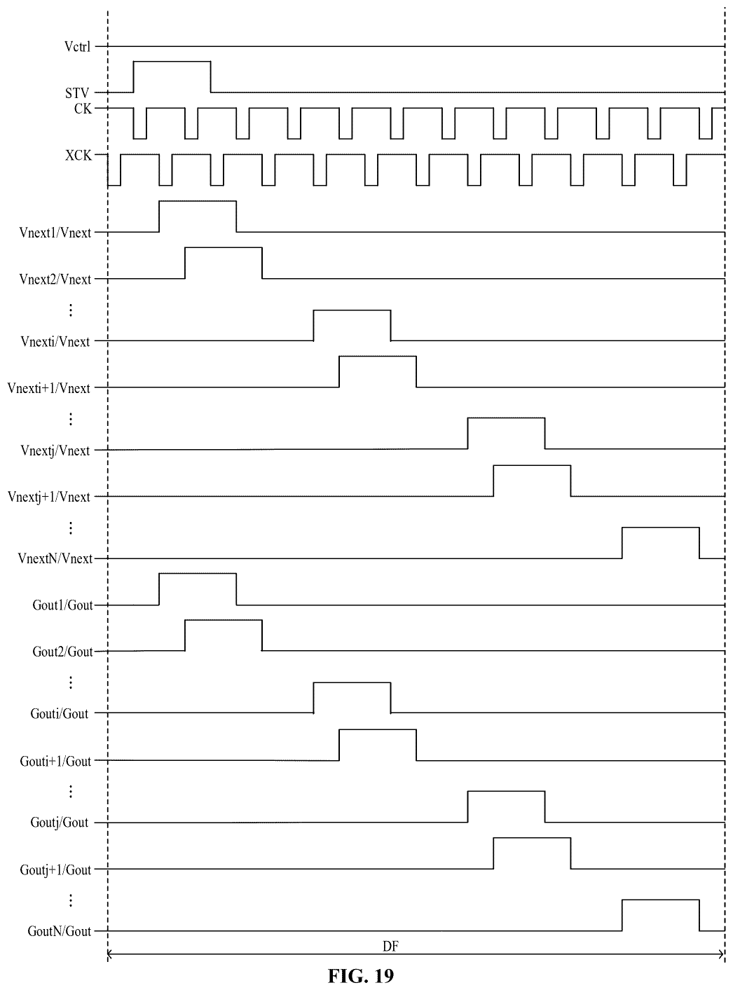

Optionally, FIG. 19 illustrates another driving time sequence diagram of a display panel according to various embodiments of the present disclosure. Referring to FIGS. 1, 9, 11 and 19, the working mode of the display panel 100 may further include the second mode; and in the second mode, the output control signal Vctrl may be at the valid level, and the frequency of the shift signal Vnext may be equal to the frequency of the gate drive signal Gout.

In the second mode, when the output control signal Vctrl is continuously at the valid level, the signal of the third node N3 of the shift register G at each level may be continuously maintained at the valid level during the display time DT of one frame. In such way, the shift registers G at all levels may output the valid levels of the gate drive signals Gout, and the valid level starting time points of the gate drive signals Gout outputted by the shift registers G at all levels may be shifted sequentially, such that all pixels 20 in the display panel 100 may be refreshed.

It may be understood that when the display mode of the display panel 100 is the second mode, in the display time DT of each frame of the display panel 100, each shift register G may output the gate drive signal Gout that the valid level starting time point is shifted sequentially, such that each pixel 20 in the display panel 100 may perform signal refresh at a fixed frequency, thereby preventing the pixel 20 from having a low display light-emitting brightness due to certain pixel 20 that has not been refreshed for a long time. In such way, when the display mode of the display panel 100 is the second mode, the output control signal Vctrl may be continuously maintained as the enable level, which may be beneficial for improving the display uniformity of the display panel 100 and ensuring the display panel 100 to have relatively high display brightness.

It should be noted that the above only exemplarily illustrates the structure of the shift register at each level and the working principle of outputting the gate drive signal; and under the premise that the shift register at each level can accurately output the gate drive signal, specific structure and working principle of the shift register at each level may not be limited in embodiments of the present disclosure. The structure of the shift register in embodiments of the present disclosure is exemplarily illustrated hereinafter.

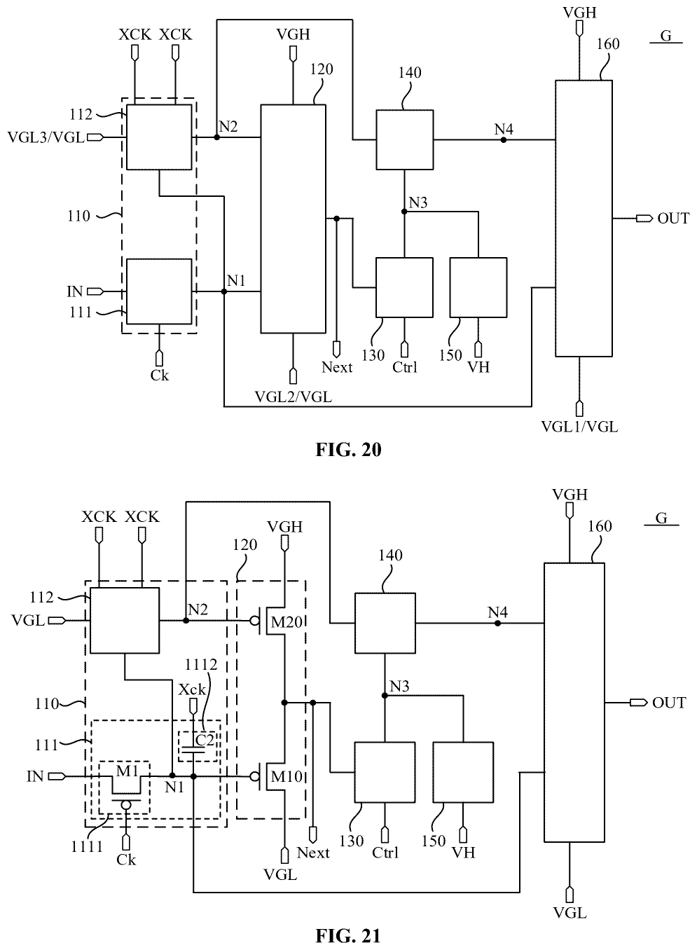

Optionally, FIG. 20 illustrates another structural schematic of a shift register according to various embodiments of the present disclosure. As shown in FIG. 20, the shift control module may include the first shift control submodule 111 and the second shift control submodule 112; the first shift control submodule 111 may be configured to at least receive the input signal Vin and the first clock signal CK, and control the signal of the first node N1; and the second shift control submodule 112 may be configured to at least receive the first clock signal CK, the second clock signal XCK, the first level signal Vg1 and the signal of the first node N1, and control the signal of the second node N2.

The first clock signal CK and the second clock signal XCK may be periodically changing signals, and both the first clock signal CK and the second clock signal XCK may include the valid level and the invalid level. The valid level time of the first clock signal CK may be not overlapped with the valid level time of the second clock signal XCK. That is, the valid level time of the first clock signal CK may be overlapped with the invalid level time of the second clock signal XCK, and the valid level time of the second clock signal XCK may be overlapped with the invalid level time of the first clock signal CK. The first level signal Vg1 received by the second shift control submodule 112 may be provided by the first level terminal VGL3. The first level terminal VGL3 may be a same signal terminal as or a different signal terminal from the first level terminal VGL2 providing the first level signal Vg1 to the shift output module 120 and/or the first level terminal VGL1 providing the first level signal Vg1 to the drive output module 160; and the first level terminals VGL3, VGL2 and VGL1 may be electrically connected to a same first signal transmission line or different first signal transmission lines, which may be designed according to actual needs and may not be limited in embodiments of the present disclosure.

For example, the first shift control submodule 111 may control the signal of the first node N1 according to the input signal Vin, the first clock signal CK and the second clock signal XCK which are received by the first shift control submodule 111, such that the signal of the first node N1 may control the time that the shift output module 120 outputs the first level signal Vg1. That is, when the signal of the first node N1 is the valid level for controlling the conduction of the shift output module 120, the shift output module 120 may transmit the first level signal Vg1 to the shift signal terminal Next, such that the first level signal Vg1 may be configured as the shift signal Vnext. The second shift control submodule 112 may control the signal of the second node N2 according to the first clock signal CK, the second clock signal XCK, the first level signal Vg1 and the signal of the first node N1 which are received by the second shift control submodule 112, such that the signal of the second node N2 may control the time that the shift output module 120 outputs the second level signal Vgh. That is, when the signal of the second node N2 is the valid level for controlling the conduction of the shift output module 120, the shift output module 120 may transmit the second level signal Vgh to the shift signal terminal Next, such that the second level signal Vgh may be configured as the shift signal Vnext. Therefore, by controlling one of the signals of the first node N1 and the second node N2 to be at the valid level, the shift output module Vnext may correspondingly output the valid level or invalid level of the shift signal Vnext, such that the valid level starting time point of the shift signal Vnext may be shifted sequentially.

Optionally, FIG. 21 illustrates another structural schematic of a shift register according to various embodiments of the present disclosure. As shown in FIG. 21, the first shift control submodule 111 may include the first input unit 1111 and the second charge pump unit 1112; the first input unit 1111 may be configured to at least receive the input signal Vin and the first clock signal CK to control the signal of the first node N1; and the second charge pump unit 1112 may be configured to at least receive the second clock signal XCK to control the signal amount of the second clock signal XCK coupled to the first node N1.

The first input unit 1111 may be electrically connected to the signal input terminal IN, the first clock terminal Ck and the first node N1 respectively. The first clock signal CK of the first clock terminal Ck may control the time that the first input unit 1111 transmits the input signal Vin received by the signal input terminal IN to the first node N1, thereby realizing the control of the signal of the first node N1. Meanwhile, since the valid level time of the first clock signal CK is not overlapped with the valid level time of the second clock signal XCK, the second clock signal XCK may jump from the invalid level to the valid level during the time period that the first clock signal CK is the invalid level. Therefore, the jump amount from the invalid level to the valid level may be coupled to the first node N1 through the second charge pump unit 1112, and the signal of the first node N1 may be compensated to ensure the stability of the signal of the first node N1.

Optionally, referring to FIG. 21, the first input unit 1111 may include the first input transistor M11; and the gate electrode of the first input transistor M11 may receive the first clock signal CK, and the first electrode of the first input transistor M11 may receive the input signal Vin and be electrically connected to the first node N1. In such way, the first clock signal CK may control the first input transistor M11 to be turned on or off; and when the first clock signal CK controls the first input transistor M11 to be turned on for conduction, the input signal Vin may be transmitted to the first node N1 through the first input transistor M11, such that the signal of the first node N1 may be consistent with the input signal Vin.

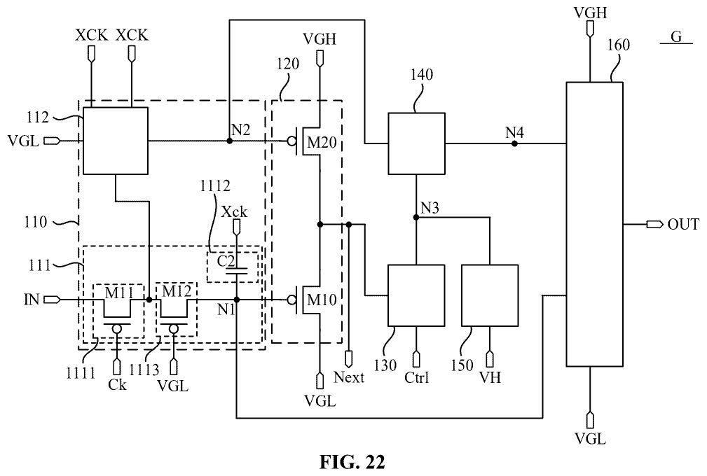

In another optional embodiment, FIG. 22 illustrates another structural schematic of a shift register according to various embodiments of the present disclosure. As shown in FIG. 22, the first shift control submodule 111 may further include the second voltage-stabilizing unit 1113. At this point, the second electrode of the first input transistor M11 may be electrically connected to the first node N1 through the second voltage-stabilizing unit 1113. The second voltage-stabilizing unit 1113 may stabilize the signal of the first node N1 and the signal of the second electrode of the first input transistor M11. In such way, when the signal of the first node N1 has an instantaneous spike, the second electrode signal of the first input transistor M11 may not be affected; or when the input signal Vin has an instantaneous spike, the signal of the first node N1 may not be affected. Therefore, the second voltage-stabilizing unit 1113 may be configured to isolate the first input transistor M11 from the first node N1, which may stabilize the signal of the first node N1 and the second electrode signal of the first input transistor M11, which may ensure the accuracy of the signal of the first node N1 and the second electrode signal of the first input transistor M11 and improve the accuracy of the shift signal Vnext outputted by the shift register G, thereby being beneficial for accurate signal level transmission of the shift register G.

Optionally, referring to FIG. 22, the second voltage-stabilizing unit 1113 may include the second voltage-stabilizing transistor M12; and the gate electrode of the second voltage-stabilizing transistor M12 may receive the first level signal Vg1, the first electrode of the second voltage-stabilizing transistor M12 may be electrically connected to the second electrode of the first input transistor M11, and the second electrode of the second voltage-stabilizing transistor M12 may be electrically connected to the first node N1.

When the difference between the second electrode signal of the second voltage-stabilizing transistor M12 and the signal of the first node N1 is within a preset range, the first level signal Vg1 may control the second voltage-stabilizing transistor M12 to be in a turn-on state, which may avoid that instantaneous increase or decrease of the second electrode signal of the second voltage-stabilizing transistor M12 and/or the signal of the first node N1 affects the stability of the signal of the second electrode of the second voltage-stabilizing transistor M12 or the signal of the first node N1, thereby being beneficial for improving the working stability of the shift register G.

It may be understood that when the first shift control submodule 111 includes the second voltage-stabilizing unit 1113, the second shift control submodule 112 may be directly electrically connected to the first node N1, or electrically connected to the first node N1 through the second voltage-stabilizing unit 113, which may not be limited in embodiments of the present of the present disclosure under the premise that the second shift control submodule 112 receives the signal of the first node N1.

Optionally, referring to FIG. 21 or FIG. 22, the second charge pump unit 1113 may include the second capacitor C2; and the first plate of the second capacitor C2 may receive the second clock signal XCK, and the second plate of the second capacitor C2 may be coupled to the first node N1. In such way, due to the charge conservation principle of the capacitor, when the second clock signal XCK received by the first plate of the second capacitor C2 changes between the valid level and the invalid level, the signal of the first node N1 electrically connected to the second plate of the second capacitor C2 may change accordingly, such that the signal of the second plate of the second capacitor C2 may have same change amount as the signal of the first plate. Therefore, when the first clock signal CK controls the first input unit 111 to be turned off and stops transmitting the input signal Vin to the first node N1, the second capacitor C2 may compensate the signal for the first node N1 to ensure the stability of the signal of the first node N1.

The second plate of the second capacitor C2 is coupled to the first node N1, which may be understood as the second plate of the second capacitor C2 may be directly and electrically connected to the first node N1, or the second plate of the second capacitor C2 may be electrically connected to the first node N1 through other conductive structures or devices, which may be designed based on actual needs and may not be limited in embodiments of the present disclosure.

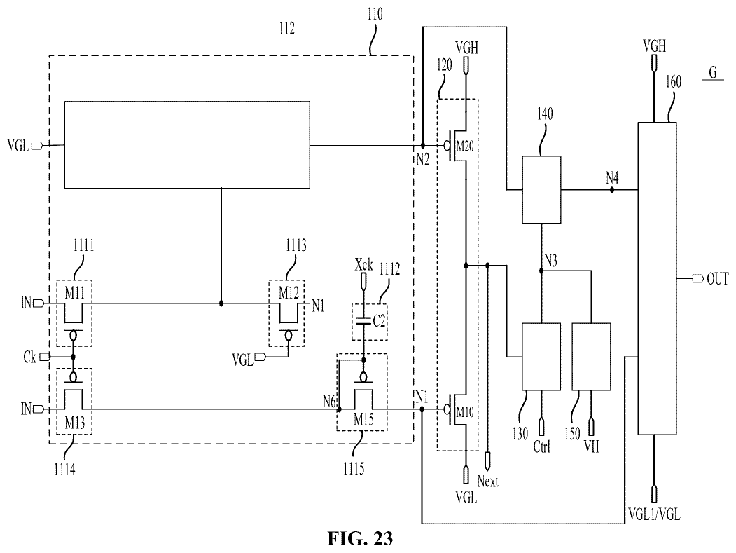

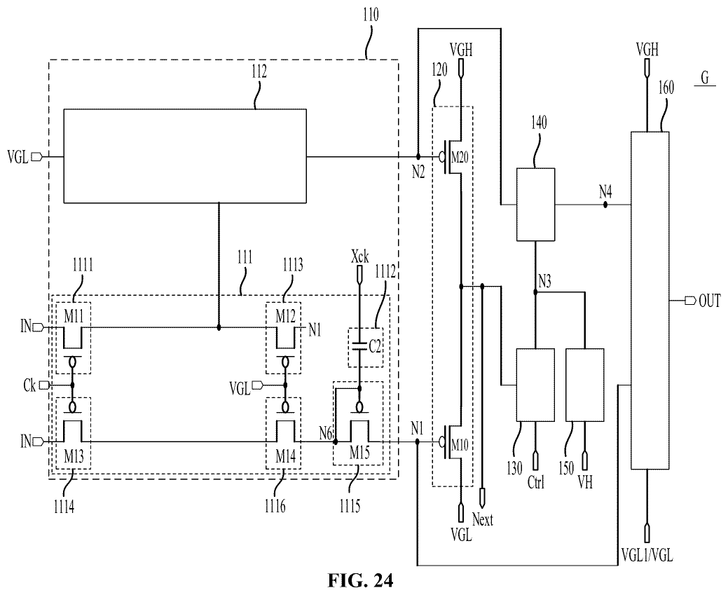

On the basis of above-mentioned embodiments, optionally, FIG. 23 illustrates another structural schematic of a shift register according to various embodiments of the present disclosure; and FIG. 24 illustrates another structural schematic of a shift register according to various embodiments of the present disclosure. As shown in FIG. 23 or FIG. 24, the first shift control submodule 111 may further include a second input unit 1114 and a filter unit 1115; the second charge pump unit 1112 may be electrically connected to the first node N2 through the filter unit 1115; the second charge pump unit 1112 and the filter unit 1115 may be coupled to the sixth node N6; the second input unit 1114 may be configured to at least receive the input signal Vin and the first clock signal Ck to control the signal of the sixth node N6; and the filter unit 1115 may be configured to at least receive the coupled signal of the second charge pump unit 1112 and the signal of the sixth node N6 to control the signal of the first node N1.

The first clock signal CK may control the time that the second input unit 1114 transmits the input signal Vin to the sixth node N6, thereby controlling the signal of the sixth node N6. The second charge pump unit 1112 may couple the jump value of the second clock signal XCK to the sixth node N6 to control the signal of the sixth node N6; and then the signal of the first node N1 may be controlled according to the voltage difference between the signal of the sixth node N6 and the signal of the first node N1 through the filter unit 1115. For example, when the voltage difference between the signal of the first node N1 and the signal of the sixth node N6 is within a preset voltage range, the filter unit 1115 may control the signal of the sixth node N6 to be transmitted to the first node N1, such that the signal of the sixth node N6 may be consistent with the signal of the first node N1; and when the voltage difference between the signal of the first node N1 and the signal of the sixth node N6 is not within the preset voltage range, the filter unit 1115 may stop transmitting the signal of the sixth node N6 to the first node N1. In such way, when the voltage of the signal of the sixth node N6 is relatively high or low, the signal of the sixth node N6 may be prevented from being transmitted to the first node N1, and the signal of the first node N1 may be prevented from changing greatly, thereby being beneficial for maintaining the stability of the signal of the first node N1.

Optionally, referring to FIG. 23, the second input unit 1114 may include the second input transistor M13; the gate electrode of the second input transistor M13 may receive the first clock signal CK, and the first electrode of the second input transistor M13 may receive the input signal Vin and be electrically connected to the sixth node N6. In such way, the first clock signal CK may control the second input transistor M13 to be turned on or off; and when the first clock signal CK controls the second input transistor M13 to be turned on for conduction, the input signal Vin may be transmitted to the sixth node N6 through the second input transistor M13, such that the signal of the sixth node N6 may be consistent with the input signal Vin.

Optionally, referring to FIG. 24, the first shift control submodule 111 may further include the third voltage-stabilizing unit 1116. At this point, the second electrode of the second input transistor M13 may be electrically connected to the sixth node N6 through the third voltage-stabilizing unit 1116.

The third voltage-stabilizing unit 1116 may stabilize the signal of the sixth node N6 and the signal of the second electrode of the second input transistor M13, such that when the signal of the sixth node N6 has an instantaneous spike, the second electrode signal of the second input transistor M13 may not be affected; or when the input signal Vin has an instantaneous spike, the signal of the sixth node N6 may not be affected. In such way, the third voltage-stabilizing unit 1116 may be configured to isolate the second input transistor M13 from the sixth node N6, which may stabilize the signal of the sixth node N6 and the second electrode signal of the second input transistor M13, ensure the accuracy of the signal of the sixth node N6 and the second electrode signal of the second input transistor M13, and improve the accuracy of the shift signal Vnext outputted by the shift register G, thereby being beneficial for accurate signal level transmission of the shift register G.

Optionally, referring to FIG. 24, the third voltage-stabilizing unit 1116 may include the third voltage-stabilizing transistor M14.

The gate electrode of the third voltage-stabilizing transistor M14 may receive the first level signal Vg1, the first electrode of the third voltage-stabilizing transistor M14 may be electrically connected to the second electrode of the second input transistor M13, and the second electrode of the third voltage-stabilizing transistor M13 may be electrically connected to the sixth node N6.

The first level signal Vg1 may control the third voltage-stabilizing transistor M13 to be in a turn-on state when the difference between the second electrode signal of the third voltage-stabilizing transistor M13 and the signal of the sixth node N6 is within a preset range, which may avoid the second electrode signal of the third voltage-stabilizing transistor M13 and/or the signal of the sixth node N6 from increasing or decreasing instantaneously to affect the stability of the signal of the second electrode of the third voltage-stabilizing transistor M13 or the signal of the sixth node N6, thereby being beneficial for improving the working stability of the shift register G.

Optionally, referring to FIG. 23 or FIG. 24, the filter unit 1115 may include a filter transistor M15; the gate electrode and the first electrode of the filter transistor M15 may be both electrically connected to the sixth node N6, and the second electrode of the filter transistor M15 may be electrically connected to the first node N1, where the second charge pump unit 1112 may be electrically connected to the gate electrode of the filter transistor M15.

The gate electrode of the filter transistor M15 may be electrically connected to the first electrode of the filter transistor M15, such that the filter transistor M15 may be equivalent to a diode. In such way, when the voltage difference between the signal of the sixth node N6 and the signal of the first node N1 satisfies the conduction condition of the filter transistor M15, the filter transistor M15 may be in a turn-on state, such that the signal of the sixth node N6 may be transmitted to the first node N1.

For example, taking the filter transistor M15 being the PMOS transistor as an example, when the signal of the sixth node N6 is lower than the signal of the first node N1, and when the voltage difference between the signal of the sixth node N6 and the signal of the first node N1 reaches a turn-on voltage of the filter transistor M15, the filter transistor M15 may be turned on for conduction. Therefore, when the second clock signal XCK jumps from the high level Vmax to the low level Vmin, the signal of the sixth node N6 may have a relatively low voltage after the second charge pump unit 1112 couples the jump amount (Vmin-Vmax) to the sixth node N6 which may make the filter transistor M15 to be turned on for conduction, such that the signal of the first node N1 may be pulled down, and the signal of the first node N1 may have a lower voltage. Furthermore, when the second clock signal XCK jumps from the low level Vmin to the high level Vmax, after the second charge pump unit 1112 couples the jump amount (Vmax-Vmin) to the sixth node N6, the signal of the sixth node N6 may have a relatively high voltage. The voltage difference between the signal of the sixth node N6 and the signal of the first node N1 may not reach the turn-on voltage of the filter transistor M15, and the filter transistor M15 may be in a turn-off state and cannot pull down the signal of the first node N1, such that the first node N1 may remain stable.

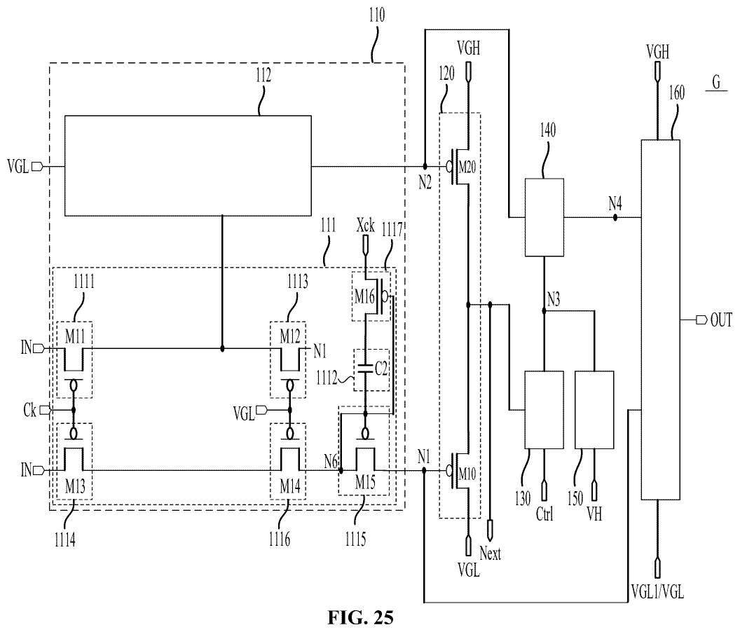

Optionally, FIG. 25 illustrates another structural schematic of a shift register according to various embodiments of the present disclosure. As shown in FIG. 25, the first shift control submodule 111 may further include the first coupling control unit 1117; the first coupling control unit 1117 may be electrically connected between the second charge pump unit 1112 and the second clock terminal Xck; the first coupling control unit 1117 may be also electrically connected to the sixth node N6; and the first coupling control unit 1117 may be configured to control the transmission path of the second clock signal XCK of the second clock terminal Xck to the second charge pump unit 1112 according to the signal of the sixth node N6.

The first coupling control unit 1117 may be turned on or off under the control of the sixth node N6. In addition, when the signal of the sixth node N6 controls the first coupling control unit 1117 to be turned on for conduction, the second clock signal Xck may be transmitted to the second charge pump unit 1112 through the first coupling control unit 1117, such that the second charge pump unit 1112 may control the signal of the sixth node N6 according to the jump amount of the second clock signal Xck. In such way, the second charge pump unit 1112 and the first coupling control unit 1117 may interact with each other, thereby improving the stability and accuracy of the signal of the sixth node N6.

Optionally, referring to FIG. 25, the first coupling control unit 1117 may include the first coupling control transistor M16; the gate electrode of the first coupling control transistor M16 may be electrically connected to the sixth node N6, the first electrode of the first coupling control transistor M16 may receive the second clock signal Xck, and the second electrode of the first coupling control transistor M16 may be electrically connected to the second charge pump unit 1112. In such way, the first coupling control transistor M16 may be turned on or off under the control of the signal of the sixth node N6. In addition, when the signal of the sixth node N6 controls the first coupling control transistor M16 to be turned on for conduction, the second clock signal XCK may be transmitted to the second charge pump unit 1112, such that the second charge pump unit 1112 may control the signal of the sixth node N6 based on the second clock signal XCK transmitted by the first coupling control transistor M16.

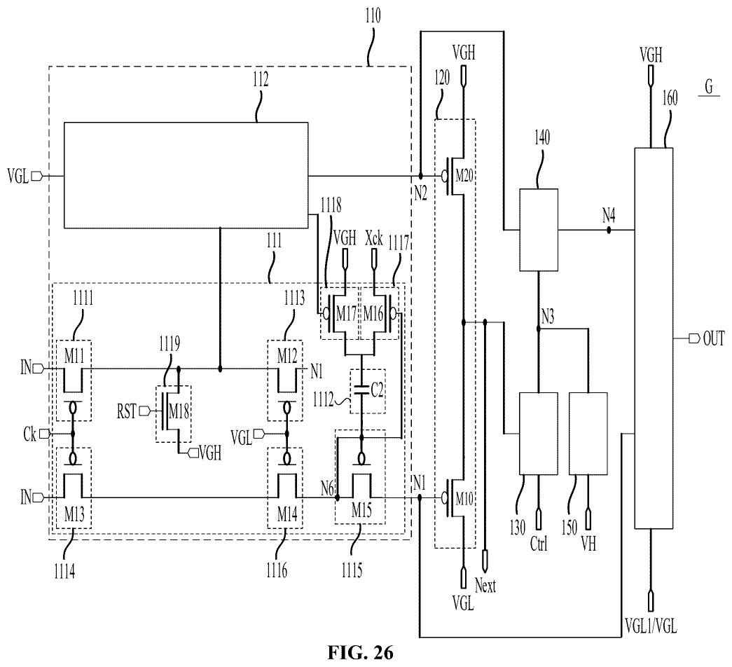

Optionally, FIG. 26 illustrates another structural schematic of a shift register according to various embodiments of the present disclosure. As shown in FIG. 26, the first shift control submodule 111 may further include the second coupling control unit 1118; the second coupling control unit 1118 may be electrically connected between the second charge pump unit 1112 and the second level terminal VGH; the second coupling control unit 1118 may be also electrically connected to the second shift control submodule 112; the second coupling control unit 1118 may be configured to control the transmission path of the second level signal Vgh of the second level terminal VGH to the second charge pump unit 1112 under the control of the second shift control submodule 112.

The second coupling control unit 1118 may be turned on or off under the control of the second shift control submodule 112. In addition, when the second shift control submodule 112 controls the second coupling control unit 1118 to be turned on for conduction, the second level signal Vgh may be provided to the second charge pump unit 1112. The signal received by the second charge pump unit 1112 may change between the second level signal Vgh and the second clock signal XCK transmitted by the first coupling control unit 1117, such that the signal received by the second charge pump unit 1112 may have a relatively large signal change amount. Therefore, when the change amount is coupled to the sixth node N6, the signal of the sixth node N6 may have a relatively low voltage, such that the signal of the first node N1 may be pulled down to a sufficiently low voltage, which may ensure that the signal of the first node N1 may accurately control the shift output module 120 to output the shift signal Vnext, improve the working stability and accuracy of the shift register G, and ensure that the signal level transmission may be accurately performed between the shift registers G at all levels.

Optionally, referring to FIG. 26, the second coupling control unit 1118 may include the second coupling control transistor M17; and the gate electrode of the second coupling control transistor M17 may be electrically connected to the second shift control submodule 112, the first electrode of the second coupling control transistor M17 may receive the second level signal Vgh, and the second electrode of the second coupling control transistor M17 may be electrically connected to the second charge pump unit 1112. In such way, the second coupling control transistor M17 may be turned on or off under the control of the second shift control submodule 112. In addition, when the signal of the sixth node N6 controls the second coupling control transistor M17 to be turned on for conduction, the second level signal Vgh may be transmitted to the second charge pump unit 1112, such that the second charge pump unit 1112 may control the signal of the sixth node N6 based on the second level signal Vgh transmitted by the second coupling control transistor M17.

Optionally, referring to FIG. 26, the first shift control submodule 111 may further include a reset unit 1119. The reset unit 1119 may at least receive the reset signal Vrst and the second level signal Vgh to control the signal of the first node N1. At this point, the reset unit 1119 may be electrically connected to the reset signal terminal RST for providing the reset signal Vrst, the second level terminal VGH for providing the second level signal Vgh, and the first node N1, such that the reset unit 1119 may reset the first node N1 under the control of the reset signal Vrst and the second level signal Vgh.

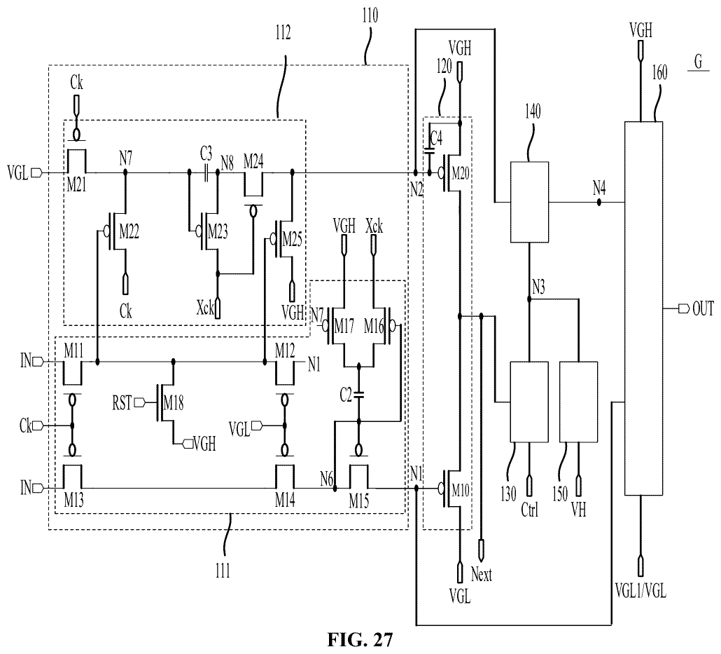

Based above-mentioned embodiments, optionally, FIG. 27 illustrates another structural schematic of a shift register according to various embodiments of the present disclosure. As shown in FIG. 27, the second shift control submodule 112 may include the first control transistor M21, the second control transistor M22, the third control transistor M23, the fourth control transistor M24 and a control capacitor C3; the gate electrode of the first control transistor M21 may receive the first clock signal CK, the first electrode of the first control transistor M21 may receive the first level signal Vg1, and the second electrode of the first control transistor M21 may be electrically connected to the seventh node N7; the gate electrode of the second control transistor M22 may be coupled to the first node N1, the first electrode of the second control transistor M22 may receive the first clock signal CK, and the second The second electrode of the control transistor M22 may be electrically connected to the seventh node N7; the gate electrode of the third control transistor M23 may be coupled to the seventh node N7, the first electrode of the third control transistor M23 may receive the second clock signal XCK, and the second electrode of the third control transistor M23 may be electrically connected to the eighth node N8; the gate electrode of the fourth control transistor M24 may receive the second clock signal XCK, the first electrode of the fourth control transistor M24 may be electrically connected to the eighth node N8, and the second electrode of the fourth control transistor M24 may be electrically connected to the second node N2; and the control capacitor C3 may be electrically connected between the seventh node N7 and the eighth node N8.

In such way, the first clock signal CK may control the first control transistor M21 to be turned on or off, the signal of the first node N1 may control the second control transistor M22 to be turned on or off, the signal of the seventh node N7 may control the third control transistor M23 to be turned on or off, the second clock signal XCK may control the fourth control transistor M24 to be turned on or off, and the control capacitor C3 may balance the signals of the seventh node N7 and the eighth node N8.

Optionally, referring to FIG. 27, the second shift control submodule 112 may further include the fifth control transistor M25; and the gate electrode of the fifth control transistor M25 may be electrically connected to the first node N1, the first electrode of the fifth control transistor M25 may receive the second level signal Vgh, and the second electrode of the fifth control transistor M25 may be electrically connected to the second node N2. In such way, the fifth control transistor M25 may be turned on or off under the control of the signal of the first node N1, such that when the signal of the first node N1 is at the valid level, the second level signal Vgh may be transmitted to the second node N2, and the signal of the second node N2 may be at the invalid level, which may ensure that one of the signals of the first node N1 and the second node N2 is at the valid level and another one of the signals of the first node N1 and the second node N2 is at the invalid level in the same time period. Therefore, the shift output module 120 may accurately output the shift signal Vnext under the control of the signal of the first node N1 and the signal of the second node N2.

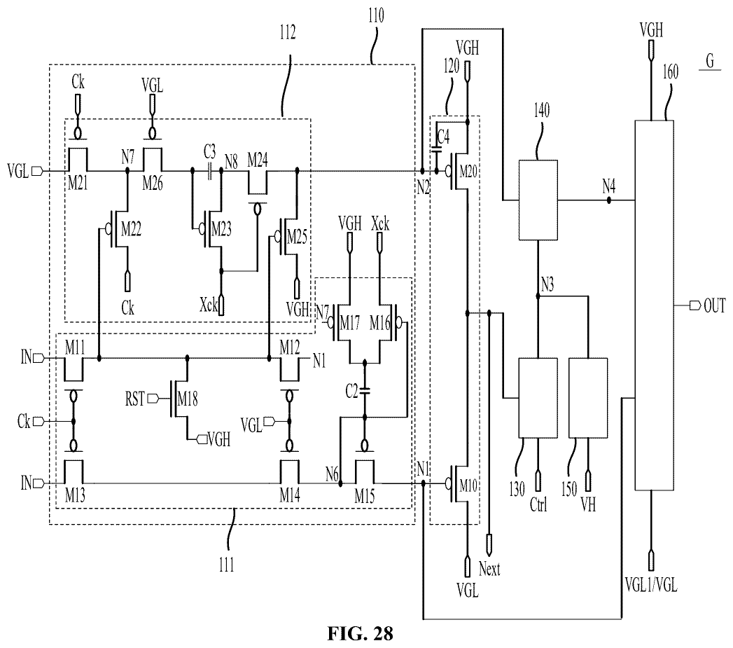

Optionally, FIG. 28 illustrates another structural schematic of a shift register according to various embodiments of the present disclosure. As shown in FIG. 28, the second shift control submodule 112 may further include the fourth voltage-stabilizing transistor M26. At this point, the gate electrode of the third control transistor M23 may be electrically connected to the seventh node N7 through the fourth voltage-stabilizing transistor M26, such that the fourth voltage-stabilizing transistor M26 may stabilize the seventh node N7 and the gate signal of the third control transistor M23.

Optionally, referring to FIG. 28, the shift output module 120 may include the first shift output transistor M10 and the second shift output transistor M20; the gate electrode of the first shift output transistor M10 may be coupled to the first node N1, the first electrode of the first shift output transistor M10 may receive the first level signal Vg1, and the second electrode of the first shift output transistor M10 may be configured to output the shift signal Vnext; and the gate electrode of the second shift output transistor M20 may be electrically connected to the second node N2, the first electrode of the second shift output transistor M20 may receive the second level signal Vgh, and the second electrode of the second shift output transistor M20 may be configured to output the shift signal Vnext.

The signal of the first node N1 may control the first shift output transistor M10 to be turned on or off, such that when the signal of the first node N1 controls the first shift output transistor M10 to be turned on for conduction, the first level signal Vg1 may be transmitted to the shift signal terminal Next as the shift signal Vnext, and the shift signal Vnext may be consistent with the first level signal Vg1. The signal of the second node N2 may control the second shift output transistor M20 to be turned on or off, such that when the signal of the second node N2 controls the second shift output transistor M20 to be turned on for conduction, the second level signal Vgh may be transmitted to the shift signal terminal Next as the shift signal Vnext, and the shift signal Vnext may be consistent with the second level signal Vgh. In such way, by controlling the signal of the first node N1 and the signal of the second node N2, the shift signal Vnext may be changed between the first level signal Vg1 and the second level signal Vgh, therefore the shift signal Vnext may include the valid level and the invalid level.

In addition, the shift output module 120 may further include the fourth capacitor C4. The fourth capacitor C4 may be electrically connected between the second level terminal VGH and the second node N2, such that the fourth capacitor C4 may store and maintain the signal of the second node N2, thereby ensuring that the signal of the second node N2 may accurately control the second shift output transistor M20 to be turned on or off.

It may be understood that the above only exemplarily illustrates the structures of the shift control module and the shift output module, which may not be limited in embodiments of the present disclosure under the premise that the valid level starting time of the shift signal outputted by the shift register at each level may be ensured to shift sequentially. For the convenience of description, without special limitation, the shift control module 110 and the shift output module 120 shown in FIG. 28 may be taken as an example to illustrate the technical solution of embodiments of the present disclosure.

Exemplarily, all transistors in the shift control module and the shift output module may be PMOS transistors, which may be taken as an example for illustration. FIG. 29 illustrates a driving time sequence diagram of a shift register according to various embodiments of the present disclosure. The working principle and working process of the shift register are described exemplarily with reference to FIGS. 28-29.

Before the Ta1 stage, the input signal Vin may be at the low level. When the first clock signal Ck is at the low level and the second clock signal XCK is at the high level, the first input transistor M11 and the second input transistor M13 may be controlled to be turned on for conduction, and the low level of the input signal Vin may be transmitted to the first node N1 and the sixth node N6. The signal of the first node N1 and the signal of the sixth node N6 may be both at the low level. In such way, the signal of the sixth node N6 may control the first coupling control transistor M16 to be turned on for conduction. The high level of the second clock signal XCK may be transmitted to the second plate of the second capacitor C2, such that the second plate of the second capacitor C2 may be at the high level. The signal of the first node N1 may control the first shift output transistor M10 to be turned on for conduction, and the first level signal Vg1 may be transmitted to the shift signal terminal Next, such that the shift signal Vnext may be consistent with the first level signal Vg1. When the first clock signal Ck is at the high level and the second clock signal XCK is at the low level, the first input transistor M11 and the second input transistor M13 may be turned off for disconnection, and the signal of the sixth node N6 may remain as the low-level signal written in previous stage. In such way, the first coupling control transistor M16 may still be in the turn-on state. The low-level signal of the second clock signal XCK may be transmitted to the first plate of the second capacitor C2, such that the signal of the first plate of the second capacitor C2 may change from the high level to the low level. The jump amount may be coupled to the sixth node N6 through the second capacitor C2, such that the sixth node N6 may have a lower potential. The filter transistor M15 may be controlled to be turned on for conduction to further pull down the signal of the first node N1. Therefore, the signal of the first node N1 may accurately control the first shift output transistor M10 to be stably turned on for conduction, and the shift signal terminal Next may stably and accurately output the low level of the shift signal Vnext. Meanwhile, since the signal of the first node N1 is at the low level, the fifth control transistor M25 may be turned on for conduction under the control of the signal of the first node N1, such that the second level signal Vgh may be transmitted to the second node N2, the second node N2 may continue to maintain the high level, and the second shift output transistor M20 may be in a turn-off state.

In the Ta1 stage, the input signal Vin may be changed to the high level, the first clock signal CK may be at the low level, and the second clock signal XCK may be at the high level. At this point, the first input transistor M11, the second input transistor M14 and the first control transistor M21 may be turned on for conduction, and the input signal Vin may be transmitted to the first node N1 and the sixth node N6 respectively through the first input transistor M11 and the second input transistor M13. In such way, the first node N1 and the sixth node N6 may be both at the high level, and the second control transistor M22 and the fifth control transistor M25 may remain to be turned off for disconnection. Meanwhile, the first-level signal Vg1 at the low level may be transmitted to the seventh node N7 through the first control transistor M21, the seventh node N7 may be at the low level, the third control transistor M23 may be turned on for conduction, and the second clock signal XCK at the high level may be transmitted to the eighth node N8. In such way, the eighth node N8 may be at the high level. In addition, the fourth control transistor M24 and the fifth control transistor M25 may be both in the turn-off state; and the signal of the second node N2 may maintain the high level, and the second shift output transistor M20 may be turned off for disconnection, such that the shift signal Vnext may maintain the low level.

In the Ta2 stage, the input signal Vin may continue to maintain the high level, the first clock signal CK may be changed to the high level, and the second clock signal XCK may be changed to the low level. At this point, the first input transistor M11, the second input transistor M13 and the first control transistor M21 may be turned off for disconnection; the second control transistor M22 and the fifth control transistor M25 may be turned off for disconnection; the seventh node N7 may be at the low level; and the third control transistor M23 may be turned on for conduction. The low level second clock signal XCK may be transmitted to the eighth node N8 through the third control transistor M23. In such way, the eighth node N8 may be at the low level, the fourth control transistor M24 may be turned on for conduction. The signal of the eighth node N8 may be transmitted to the second node N2, such that the second node N2 may be at the low level. The second shift output transistor M20 may be turned on for conduction, and the second level signal Vgh may be transmitted to the shift signal terminal Next, such that the output of the shift signal Vnext may be changed to the high level.

In the Ta3 stage, the input signal Vin may continue to maintain the high level, the first clock signal CK may be at the low level, and the second clock signal XCK may be at the high level. At this point, the second input transistor M13, the first input transistor M11 and the first control transistor M21 may be turned on for conduction; and the input signal Vin may be transmitted to the first node N1 and the sixth node N6 respectively through the second input transistor M13 and the first input transistor M11. In such way, the first node N1 and the sixth node N6 may be both at the high level; and the second control transistor M22 and the fifth control transistor M25 may be turned off for disconnection. Meanwhile, the first level signal Vg1 may be transmitted to the seventh node N7 through the first control transistor M21, the seventh node N7 may be at the low level, the third control transistor M23 may be turned on for conduction, the second clock signal XCK may be at the high level, the eighth node N8 may maintain the high level, the fourth control transistor M24 may be turned off for disconnection, the second node N2 may maintain the low level, and the second shift output transistor M20 may be turned on for conduction, such that the shift signal Vnext may continue to maintain the high level.

In the Ta4 stage, the input signal Vin may be changed to the low level, the first clock signal CK may be at the high level, the second clock signal XCK may be at the low level, the second input transistor M13, the first input transistor M11 and the first control transistor M21 may be all turned off for disconnection, the first node N1 and the sixth node N6 may both maintain the high level, and the second control transistor M22 and the fifth control transistor M25 may be both turned off for disconnection. The seventh node N7 may maintain the low level, the third control transistor M23 may be turned on for disconnection, and the low level of the second clock signal XCK may be transmitted to the eighth node N8 through the third control transistor M23, such that the eighth node N8 may be at the low level. The fourth control transistor M24 may be turned on for conduction, the signal of the eighth node N8 may be transmitted to the second node N2, the signal of the second node N2 may be at the low level, the second shift output transistor M20 may be turned on for conduction, and the second level signal Vgh may be transmitted to the shift signal terminal Next, such that the shift signal Vnext may continue to maintain the high level.

In the Ta5 stage, the input signal Vin may be at the low level, the first clock signal CK may be at the low level, the second clock signal XCK may be at the high level, and the second input transistor M13, the first input transistor M11 and the first control transistor M21 may be turned on for conduction. The input signal Vin may be transmitted to the first node N1 and the sixth node N6 respectively through the second input transistor M13 and the first input transistor M11, such that the first node N1 and the sixth node N6 may be both at the low level, and the second control transistor M22 and the fifth control transistor M25 may be turned on for conduction. Meanwhile, the first control transistor M21 may be turned on for conduction, the first level signal Vg1 may be transmitted to the seventh node N7 through the first control transistor M21, the seventh node N7 may be at the low level, the third control transistor M23 may be turned on for conduction, the second clock signal XCK may be at the high level, the eighth node N8 may remain the high level, and the fourth control transistor M24 may be turned off for disconnection. The second level signal Vgh may be transmitted to the second node N2 through the fifth control transistor M25, such that the second node N2 may be at the high level, and the second shift output transistor M20 may be turned off for disconnection. Meanwhile, the first node N1 may be at the low level, the first shift output transistor M10 may be turned on for conduction, and the first level signal Vg1 may be transmitted to the shift signal terminal Next, such that the shift signal Vnext may be changed to the low level.

After the Ta5 stage, the input signal Vin may continue to maintain the low level, such that no matter how the first clock signal CK and the second clock signal XCK change, the signal of the first node N1 may maintain the low level, and the signal of the second node N2 may maintain the high level. In such way, the first shift output transistor M10 may be continuously turned on, and the second shift output transistor M20 may be continuously turned off; and the shift signal Vnext may be always at the low level until next driving cycle is entered, and the signal of the first node N1, the signal of the second node N2, and the shift signal Vnext may undergo above changes again.

As disclosed above, through the structure and corresponding time sequence of above-mentioned shift control module 110, the shift control module 110 may control the starting time point of the enable level of the shift signal Vnext outputted by the shift output module 120 to be after the starting time point of the enable level of the input signal Vin received by the shift control module 110; and the shift control module 110 may control the ending time point of the enable level of the shift signal Vnext outputted by the shift output module 120 to be after the ending time point of the enable level of the input signal Vin received by the shift control module 110, thereby satisfying signal level transmission requirement of the shift register G at each level.

It should be noted that the working principle of the shift register that each transistor in the shift control module 110 and the shift output module 120 is the PMOS transistor is exemplarily described above. Furthermore, each transistor in the shift control module 110 and the shift output module 120 in embodiments of the present disclosure may further include the NMOS transistor, which may be designed according to actual needs. For the PMOS transistor, the gate may be turned on for conduction when receiving a high-level signal and may be turned off for disconnection when receiving a low-level signal. For the NMOS transistor, the gate may be turned on for conduction when receiving a low-level signal and may be turned off for disconnection when receiving a high-level signal. Therefore, when the transistor type changes, similar working principle may also be achieved by adjusting the signal provided to the gate of the transistor, which may refer to above description and may not be described in detail herein.

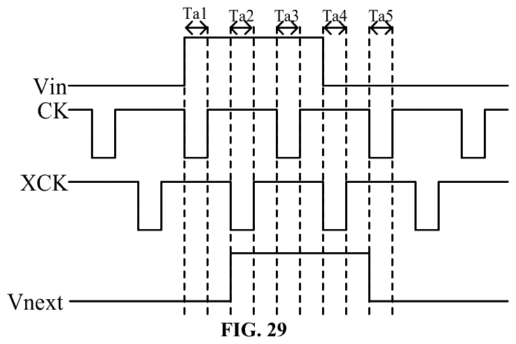

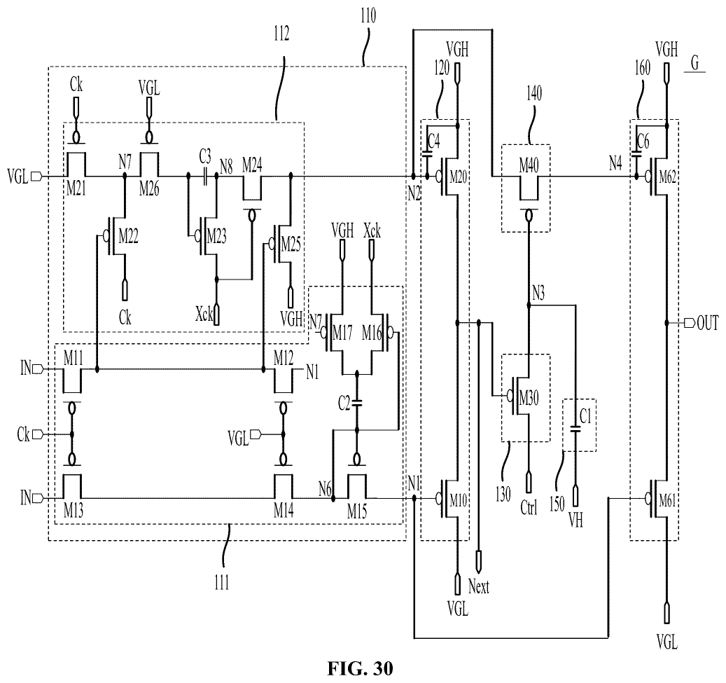

Optionally, FIG. 30 illustrates another structural schematic of a shift register according to various embodiments of the present disclosure. As shown in FIG. 30, the output control module 130 may include an output control transistor M30; and the gate electrode of the output control transistor M30 may receive the shift signal Vnext, the first electrode of the output control transistor M30 may receive the output control signal Vctrl, and the second electrode of the output control transistor M30 may be electrically connected to the third node N3. In such way, the output control transistor M30 may be turned on or off under the control of the shift signal Vnext. In addition, when the output control transistor M30 is turned on for conduction, the output control signal Vctrl may be transmitted to the third node N3, such that the signal of the third node N3 may be consistent with the output control signal Vctrl.

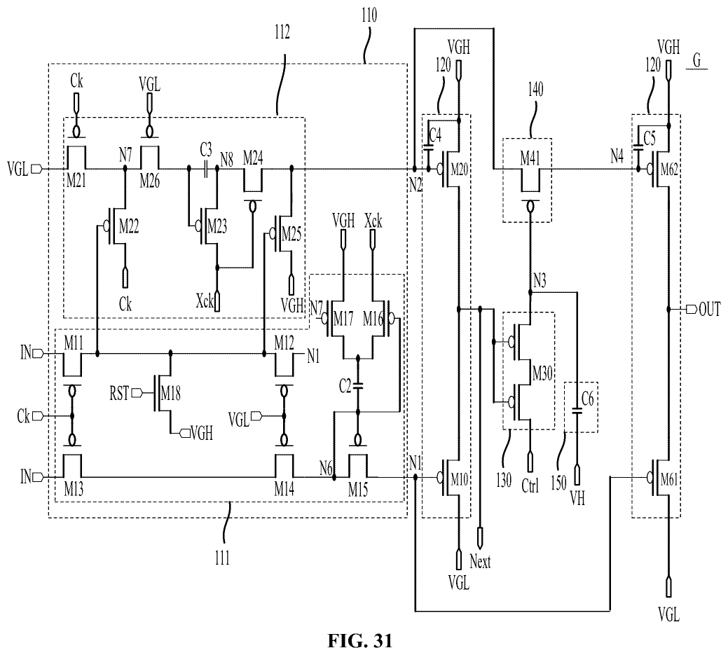

Optionally, FIG. 31 illustrates another structural schematic of a shift register according to various embodiments of the present disclosure. As shown in FIG. 31, the output control transistor M30 may be a dual-gate transistor.

The output control transistor M30 may be configured to transmit the output control signal Vctrl to the third node N3, and the signal of the third node N3 may control the transmission path of the signal of the second node N2 to the fourth node N4; and the signal of the fourth node N4 may control the drive output module 160 to output the gate drive signal Gout. Meanwhile, after the shift signal Vnext is changed to the valid level, the output control transistor M30 may be in the turn-off state. At this point, the signal of the third node N3 may need to be controlled to remain unchanged. Based on the characteristics of the transistor of the present disclosure, there may be a certain leakage current when the output control transistor M30 is in the turn-off state. When the leakage current is relatively large, the signal of the third node N3 may change greatly, such that the signal of the third node N3 cannot accurately control the time of forming the conduction path between the second node N2 and the fourth node N4, and the signal of the fourth node N4 may be inaccurate, which may affect the accuracy of the gate drive signal Gout outputted by the drive output module 160. Therefore, by setting the output control transistor M30 as the dual-gate transistor, the output control transistor M30 may have a relatively small leakage current when the output control transistor M30 is in the turn-off state, which may improve the stability and accuracy of the signal of the third node N3, thereby accurately controlling the conduction path between the second node N2 and the fourth node N4 by the signal of the third node N3, and further improving the accuracy and stability of the gate drive signal Gout outputted by the drive output module 160.

It should be noted that the above only exemplarily illustrates the case that the output control transistor M30 is the dual-gate transistor. For the transistors electrically connected to other nodes or signal terminals, when the signals of the nodes or signal terminals electrically connected thereto also require high accuracy and stability, the transistors may also be configured as dual-gate transistors, which may be designed according to actual needs and may not be limited in embodiments of the present disclosure.

Optionally, referring to FIG. 30 or FIG. 31, the transmission control module 140 may include a transmission control transistor M40; and the gate electrode of the transmission control transistor M40 may be electrically connected to the third node N3, the first electrode of the transmission control transistor M40 may be electrically connected to the second node N2, and the second electrode of the transmission control transistor M40 may be electrically connected to the fourth node N4. In such way, the transmission control transistor M40 may be turned on or off under the control of the signal of the third node N3. In addition, when the transmission control transistor M40 is turned on for conduction, the signal of the second node N2 may be transmitted to the fourth node N4, such that the signal of the fourth node N4 may be consistent with the signal of the second node N2.

Optionally, referring to FIG. 30 or FIG. 31, the potential maintaining module 150 may include a potential maintaining capacitor C6; and the first plate of the potential maintaining capacitor C6 may receive the fixed level signal Vh, and the second plate of the potential maintaining capacitor C6 may be electrically connected to the third node N3. In such way, the signal of the third node N3 may be stored in the potential maintaining capacitor C6. Therefore, when the output control module 130 does not transmit the output control signal Vctrl, the potential maintaining capacitor C6 may maintain the stability of the signal of the third node N3; and the signal of the third node N3 may stably control the transmission control module 140 to be turned on or off.

Optionally, referring to FIG. 30 or FIG. 31, the drive output module 160 may include the first drive output transistor M61 and the second drive output transistor M62. The gate electrode of the first drive output transistor M61 may be coupled to the first node N1, the first electrode of the first drive output transistor M61 may receive the first level signal Vg1, and the second electrode of the first drive output transistor M61 may be configured to output the gate drive signal Gout. The gate electrode of the second drive output transistor M62 may be electrically connected to the fourth node N4, the first electrode of the second drive output transistor M62 may receive the second level signal Vgh, and the second electrode of the second drive output transistor M62 may be configured to output the gate drive signal Gout.

The signal of the first node N1 may control the first drive output transistor M61 to be turned on or off, such that when the signal of the first node N1 controls the first drive output transistor M61 to be turned on for conduction, the first level signal Vg1 may be transmitted to the drive signal terminal OUT as the gate drive signal Gout; and the gate drive signal Gout may be consistent with the first level signal Vg1. The signal of the fourth node N4 may control the second drive output transistor M62 to be turned on or off, such that when the signal of the fourth node N4 controls the second drive output transistor M62 to be turned on for conduction, the second level signal Vgh may be transmitted to the drive signal terminal OUT as the gate drive signal Gout; and the gate drive signal Gout may be consistent with the second level signal Vgh. Therefore, by controlling the signal of the first node N1 and the signal of the fourth node N4, the gate drive signal Gout may be changed between the first level signal Vg1 and the second level signal Vgh, such that the gate drive signal Gout may include the valid level and the invalid level to satisfy diversified display requirement of the display panel.

In addition, the drive output module 160 may further include the fifth capacitor C5. The fifth capacitor C5 may be electrically connected between the second level terminal VGH and the fourth node N4, such that the fifth capacitor C5 may store and maintain the signal of the fourth node N4, thereby ensuring that the signal of the fourth node N4 may accurately control the second drive output transistor M62 to be turned on or off.

It may be understood that the above only exemplarily illustrates the structures of the output control module, the transmission control module and the drive output module, which may not be limited in embodiments of the present disclosure under the premise that the valid level or invalid level of the gate drive signal outputted as required by the shift register at each level may be ensured.

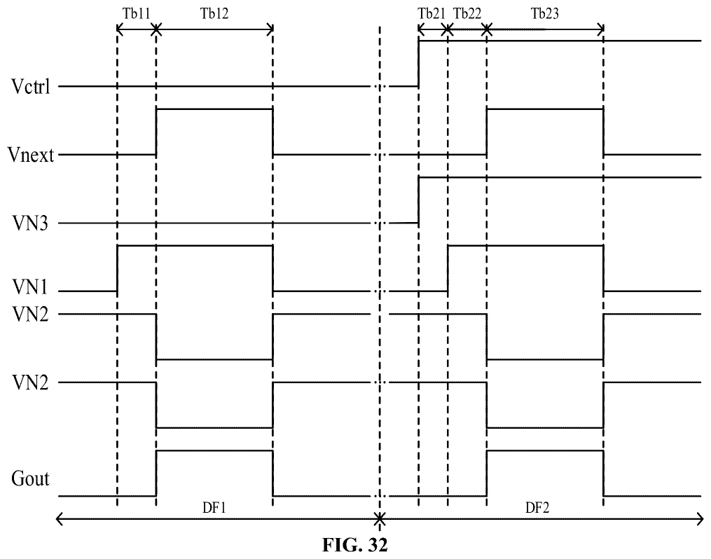

Exemplarily, each transistor in the output control module, the transmission control module and the drive output module is the PMOS transistor, which may be taken as an example. FIG. 32 illustrates another driving time sequence diagram of a shift register according to various embodiments of the present disclosure. Referring to FIGS. 30 and 32, the working principle and working process of the shift register as the first shift register is exemplarily described hereinafter.

The first shift register may continuously output the invalid level of the gate drive signal at a partial time period in the first mode, and the gate drive signal outputted at the partial time period may include the valid level. In order to satisfy the output requirement of the gate drive signal, the valid level time of the output control signal may be set accordingly. For example, as shown in FIG. 32, during the display time DF1 of one frame, the output control signal Vctrl may continue to be at the low level; and during the display time DF2 of another frame, the output control signal Vctrl may jump to the high level before the shift signal Vnext is changed to the high level.

Before the Tb11 stage of the frame display time DF1, the signal of the first node N1 may be at the low level, the signal of the second node N2 may be at the high level, the shift signal Vnext may be at the low level, the output control transistor M30 may be turned on for conduction, and the low level of the output control signal Vctrl may be transmitted to the third node N3. In such way, the signal of the third node N3 may be consistent with the output control signal Vctrl; that is, the signal of the third node N3 may be at the low level. The signal of the third node N3 may control the transmission control transistor M40 to be turned on for conduction, and the signal of the second node N2 may be transmitted to the fourth node N4. The signal of the second node N2 may be consistent with the signal of the fourth node N4; that is, the signal of the fourth node N4 may be at the high level. The second drive output transistor M62 may be in the turn-off state. Meanwhile, the signal of the first node N1 may be at the low level, such that the first drive output transistor M61 may be turned on for conduction, and the first level signal Vg1 may be configured as the gate drive signal Gout, that is, the gate drive signal Gout may be at the low level.

In the Tb11 level, the signal of the first node N1 may be changed to the high level, the signal of the second node N2 may remain the high level, the shift signal Vnext may remain the low level, the output control transistor M30 may continue to remain the turn-on state, the signal of the third node N3 may remain to be consistent with the low level of the output control signal Vctrl, and the transmission control transistor M40 may be turned on for conduction. The high level of the second node N2 may be transmitted to the fourth node N4, such that the fourth node N4 may remain the high level, and the second drive output transistor M62 may remain the turn-off state. Meanwhile, the signal of the first node N1 may be changed to the high level, the first drive output transistor M61 may also be changed to the turned-off state, and the gate drive signal Gout may remain the low level of previous stage.

In the Tb12 stage, the signal of the first node N1 may remain the high level, the signal of the second node N2 may be changed to the low level, the shift signal Vnext may be changed to the high level, and the output control transistor M30 may be turned off for disconnection. The signal of the third node N3 may remain the low level written in previous stage, such that the transmission control transistor M40 may continue to remain the turn-on state. The high level signal of the second node N2 may be transmitted to the fourth node N4, such that the signal of the fourth node N4 may control the second drive output transistor M62 to be turned on for conduction. The second level signal Vgh may be transmitted to the drive signal terminal OUT, and the gate drive signal Gout may be changed to consistent with the second level signal Vgh; that is, the gate drive signal Gout may be changed to the high level. Meanwhile, the signal of the first node N1 is at the high level, such that the first drive output transistor M61 may continue to remain the turn-off state.

After the Tb12 stage of the frame display time DF1, the signal of the first node N1 may be changed to the low level again, the signal of the second node N2 may be changed to the high level again, and the shift signal Vnext may be changed to the low level again. In such way, the first drive output transistor M61 may be turned on for conduction, the second drive output transistor M62 may be turned off for disconnection, and the gate drive signal Gout may be changed to the low level again.

After entering the Tb21 stage of the frame display time DF2, the output control signal Vctrl may be changed to the high level, the shift signal Vnext may be at the low level, the output control transistor M30 may be turned on for conduction, the output control signal Vctrl may be transmitted to the third node N3, the signal of the third node N3 may be changed to the high level, the transmission control transistor M40 may be turned off for disconnection, the signal of the second node N2 cannot be transmitted to the fourth node N4, the signal of the fourth node N4 may remain the high level of previous stage, and the second drive output transistor M62 may be turned off for disconnection. The signal of the first node N1 may be at the low level, such that the first drive output transistor M61 may be turned on for conduction, the gate drive signal Gout may be consistent with the first level signal Vg1, and the gate drive signal Gout may be at the low level.

In the Tb22 stage, the signal of the first node N1 may be changed to the high level, the signal of the second node N2 may be also at the high level, the shift signal Vnext may continue to maintain the low level, the output control transistor M30 may continue to be turned on for conduction and continue to provide the high-level output control signal Vctrl to the third node N3, the signal of the third node N3 may control the transmission control transistor M40 to continue to remain the turn-off state, the signal of the fourth node N4 may continue to maintain the high level, and the second drive output transistor M61 may be turned off for disconnection. Meanwhile, the signal of the first node N1 may control the first drive output transistor M62 to be turned off, and the gate drive signal Gout may remain the low level of previous stage.

In the Tb23 stage, the signal of the first node N1 may continue to maintain the high level, the signal of the second node N2 may be at the low level, the shift signal Vnext may be changed to the high level, and the output control transistor M30 may be turned off for disconnection, such that the third node N3 may remain the high level written in previous stage. The transmission control transistor M40 may continue to be in the turn-off state, the signal of the fourth node N4 may continue to maintain the high level, and the second drive output transistor M62 may be still in the turn-off state. Meanwhile, the signal of the first node N1 may continue to control the first drive output transistor M61 to be in the turn-off state, such that the gate drive signal Gout may continue to maintain the low level of previous stage.

After the Tb23 stage of the frame display time DF2, if the output control signal Vctrl continues to maintain the high level, the signal of the third node N3 and the signal of the fourth node N4 may continue to maintain the high level, and the second drive output transistor M62 may remain the turn-off state. Or if the output control signal Vctrl is changed to the low level, the signal of the third node N3 may be at the low level, and the transmission control transistor M40 may be turned on for conduction. However, the signal of the second node N2 may be at the high level at this point. After the high-level signal of the second node N2 is transmitted to the fourth node N4, the fourth node N4 may remain the high level, and the second drive output transistor M62 may also remain the turn-off state. Meanwhile, the signal of the first node N1 may be changed to the low level, such that the low-level signal may control the first drive output transistor M61 to be turned on for conduction again, and the gate drive signal Gout may continue to maintain the low level until next driving cycle.

As disclosed above, by controlling the jump time of the valid level and invalid level of the output control signal Vctrl, the gate drive signal Gout outputted by the shift register G may be controlled to be consistent with the shift signal Vnext, or the gate drive signal Gout outputted by the shift register G may be controlled to be continuously maintained at the low level, thereby satisfying diversified display requirement of the display panel.

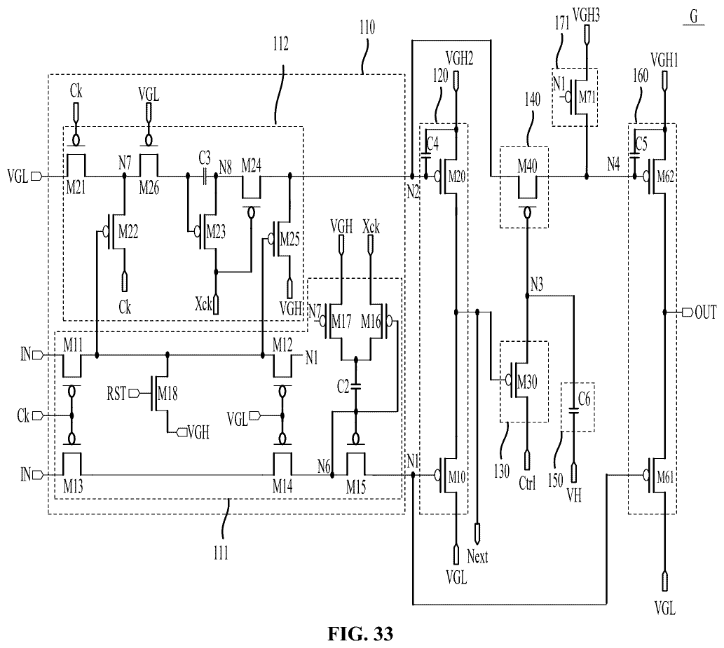

Optionally, FIG. 33 illustrates another structural schematic of a shift register according to various embodiments of the present disclosure. As shown in FIG. 33, the shift register G may further include a node control module 171 for receiving the signal of the first node N1 and the second level signal Vgh and controlling the signal of the fourth node N4.

The node control module 171 may transmit the second level signal Vgh to the fourth node N4 under the control of the signal of the first node N1. In such way, when the signal of the third node N3 remains the high level for a long time and the transmission control module 140 cannot transmit the signal of the second node N2 to the fourth node N4, the node control module 171 may be turned on for conduction by the signal of the first node N1. Therefore, the node control module 171 may transmit the second level signal Vgh to the fourth node N4 to compensate the signal of the fourth node N4; and the signal of the fourth node N4 may control the second drive output transistor M62 to remain the turn-off state, thereby preventing the situation that the second drive output transistor M62 cannot be turned off due to insufficient signal of the fourth node N4 which may affect the output accuracy of the gate drive signal Gout.

It may be understood that the node control module 171 may be electrically connected to the first node N1 directly or indirectly. For example, when the first shift control submodule 111 includes the second voltage-stabilizing transistor M12, the node control module 171 may be electrically connected to the first node N1 through the second voltage-stabilizing transistor M12. Or when the first shift control submodule 111 includes the filter transistor M15, the node control module 171 may be electrically connected to the first node N1 through the filter transistor M15; that is, the node control module 171 may be electrically connected to the sixth node N6 first, and then electrically connected to the first node N1 through the filter transistor M15. Or when the first shift control submodule 111 includes the filter transistor M15 and the third voltage-stabilizing transistor M14, the node control module 171 may also be electrically connected to the first node N1 through the third voltage-stabilizing transistor M14 and the filter transistor M15 sequentially. Specific connection manners may be designed according to actual needs, which may not be limited in embodiments of the present disclosure. For ease of description, without special limitation, the node control module 171 may be electrically connected to the first node N1, which may be taken as an example for description in embodiments of the present disclosure.

Optionally, referring to FIG. 33, the node control module 171 may include a node control transistor M71. The gate electrode of the node control transistor M71 may be electrically connected to the first node N1, the first electrode of the node control transistor M71 may receive the second level signal Vgh, and the second electrode of the node control transistor M71 may be electrically connected to the fourth node N4. In such way, the node control transistor M71 may be turned on or off under the control of the signal of the first node N1. In addition, when the signal of the first node N1 controls the node control transistor M71 to be turned on for conduction, the second level signal Vgh may be transmitted to the fourth node N4, such that the signal of the fourth node N4 may be consistent with the second level signal Vgh.

The node control transistor M71, the first shift output transistor M10 and the first drive output transistor M61 may have a same channel type. That is, the signal of the first node N1 may control the node control transistor M71, the first shift output transistor M10 and the first drive output transistor M61 to be turned on or off simultaneously, such that when the signal of the first node N1 is at the valid level, the signal of the fourth node N4 may be at the invalid level, thereby ensuring the output accuracy of the gate drive signal Gout.

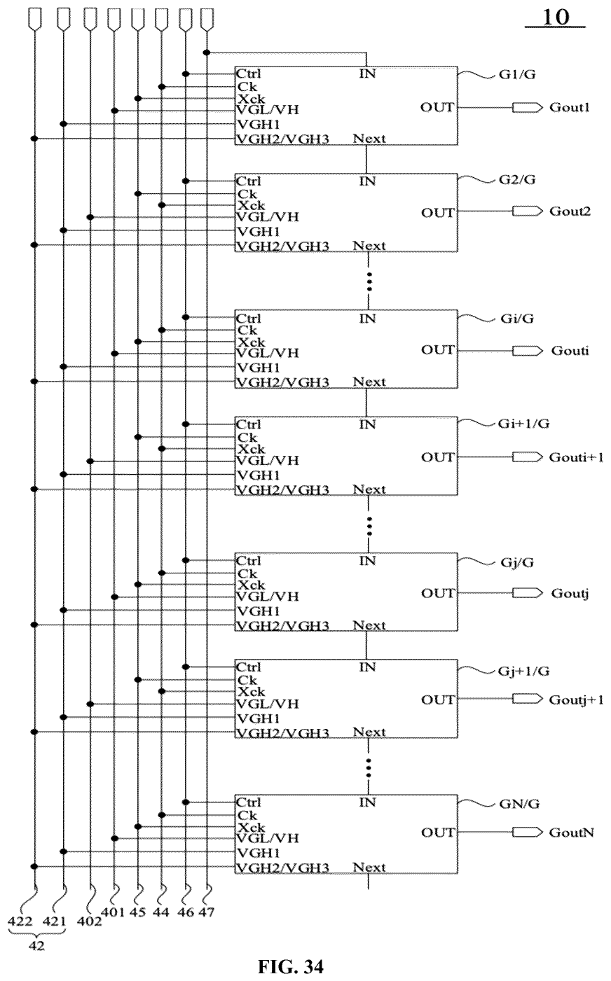

Optionally, FIG. 34 illustrates another structural schematic of a driver circuit according to various embodiments of the present disclosure. Referring to FIGS. 33-34, the display panel may further include at least one second signal transmission line 42; the second signal transmission line 42 may be configured to transmit the second level signal Vgh; and in the same shift register G, the shift output module 120 and the node control module 171 may be electrically connected to same second signal transmission line 42.

As disclosed above, the shift output module 120 and the node control module 171 of same shift register G may share one second signal transmission line 42, which may be beneficial for reducing the number of second signal transmission lines 42 electrically connected to same shift register G, thereby being beneficial for simplifying the structure of the display panel 100. Meanwhile, the second signal transmission line 42 may be disposed in the non-display region of the display panel 100, which may be beneficial for reducing the dimension of the non-display region of the display panel 100, thereby being beneficial for narrow frame of the display panel 100.

Optionally, referring to FIG. 34, in the same shift register G, the shift output module 120 and the drive output module 160 may be electrically connected to different second signal transmission lines 42, respectively.

The drive output module 160 may be electrically connected to the second signal transmission line 421 through the second level terminal VGH1, and the shift output module 120 may be electrically connected to the second signal transmission line 422 through the second level terminal VGH2, such that the second signal transmission line 421 may provide the second level signal Vgh to the drive output module 160, and the second signal transmission line 422 may provide the second level signal Vg2 to the shift output module 120. At this point, the second level signal Vgh transmitted by the second signal transmission line 421 may be same as or different from the second level signal Vgh transmitted by the second signal transmission line 421, which may be flexibly designed according to actual needs to satisfy different display requirements of the display panel 100 and broaden the application scenarios of the display panel 100. Meanwhile, when different second signal transmission lines 42 are configured to provide the second level signal Vgh to the shift output module 120 and the drive output module 160 respectively, each second signal transmission line 42 may have a relatively small load, such that each second signal transmission line 42 may have a relatively small voltage drop, which may be beneficial for the accuracy of the second level signal Vgh transmitted by each second signal transmission line 42.

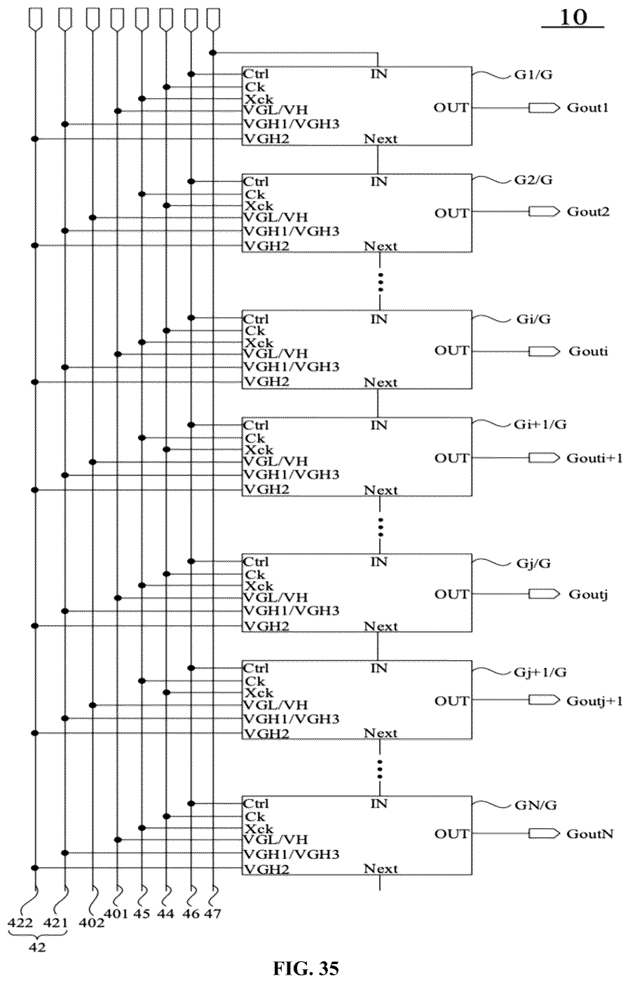

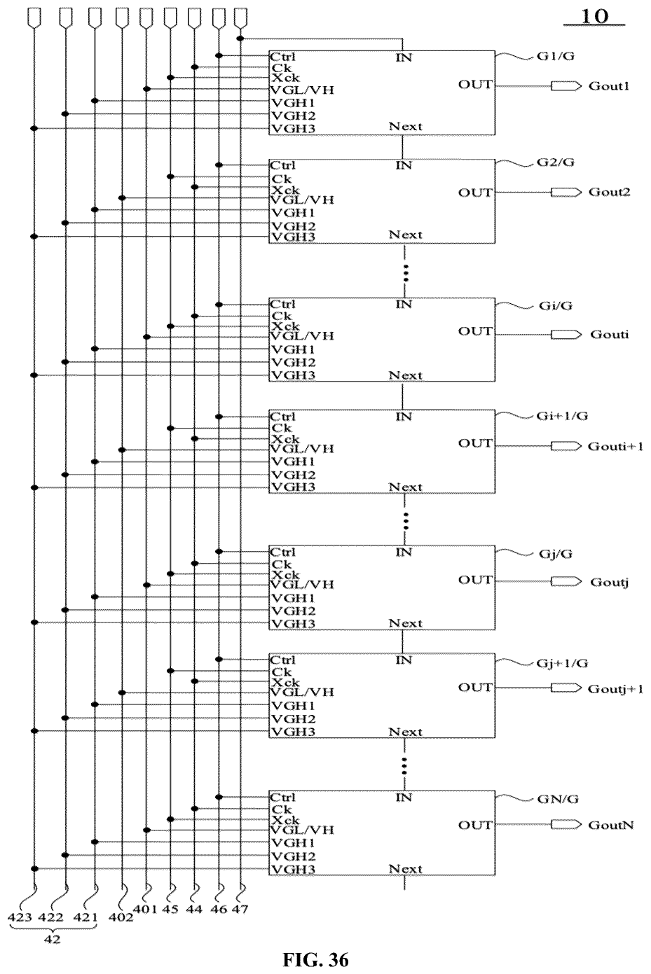

In other optional embodiments, as shown in FIG. 35, when the shift output module 120 and the drive output module 160 are electrically connected to different second signal transmission lines 42 respectively, the node control module 171 and the drive output module 160 may also be electrically connected to same second signal transmission line 421. Or as shown in FIG. 36, the node control module 171, the drive output module 160 and the shift output module 120 may also be electrically connected to different second signal transmission lines 42, respectively. For example, the drive output module 160 may be electrically connected to the second signal transmission line 421 through the second level terminal VGL1, the shift output module 120 may be electrically connected to the second signal transmission line 422 through the second level terminal VGL2, and the node control module 171 may be electrically connected to the second signal transmission line 423 through the second level terminal VGL3. It should be noted that specific connection manners between the node control module 171, the drive output module 160 and the shift output module 120 and the second signal transmission line 42 may be designed according to actual needs, which may not be limited in embodiments of the present disclosure. For the convenience of description, without special limitation, in the same shift register G, the shift output module 120 and the drive output module 160 may be respectively connected to different second signal transmission lines 42, and the shift output module 120 and the node control module 171 may be electrically connected to same second signal transmission line 422, which may be taken as an example to illustrate the technical solution of embodiments of the present disclosure.

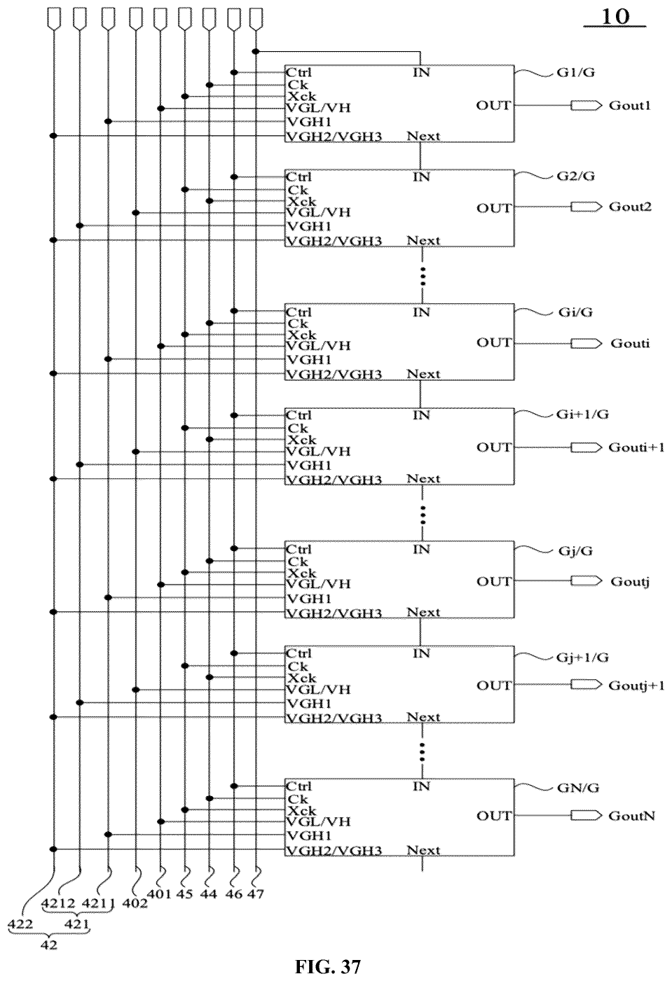

On the basis of above-mentioned embodiments, optionally, FIG. 37 illustrates another structural schematic of a driver circuit according to various embodiments of the present disclosure. Referring to FIGS. 33 and 37, the drive output modules 160 of the shift registers G of any two adjacent levels may be electrically connected to different second signal transmission lines 42.

In an exemplary embodiment, the drive output module 160 of the odd-numbered shift register G may be electrically connected to the second signal transmission line 4211, and the drive output module 160 of the even-numbered shift register G may be electrically connected to the second signal transmission line 4212, such that the shift registers G of any two adjacent levels may be electrically connected to different second signal transmission lines 42. At this point, each second signal transmission line 42 may be electrically connected to fewer shift registers G, such that the load on each second signal transmission line 42 may be reduced, which may be beneficial for reducing the voltage drop of the second level signal Vgh transmitted by the second signal transmission line 42 and accurately providing the second level signal Vgh to the shift register at each level G. Furthermore, the shift register G at each level may accurately output the gate drive signal Gout, and the display panel may accurately refresh the signal, thereby improving the display quality of the display panel.

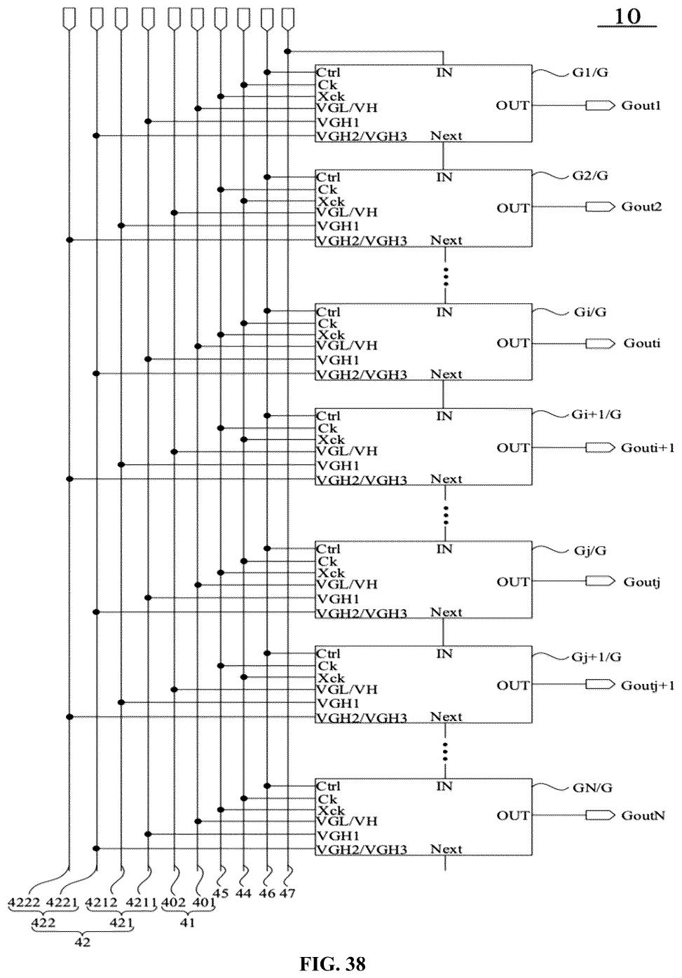

Optionally, referring to FIGS. 33 and 38, the shift output module 120 of the shift registers G of any two adjacent levels may also be electrically connected to different second signal transmission lines 422, respectively. For example, the shift output module 120 of the odd-numbered shift register G may be electrically connected to the second signal transmission line 4221 through the second level terminal VGL2, and the shift output module 120 of the even-numbered shift register G may be electrically connected to the second signal transmission line 4222 through the second level terminal VGL2. In such way, the load of the second signal transmission line 422 that provides the second level signal Vgh to the shift output module 120 may be reduced, which may be beneficial for the accuracy of the second level signal Vgh and improving the accuracy of the shift signal Vnext outputted by the shift output module 120.

In an optional embodiment, when the signal of the fourth node N4 in the same shift register G is at the valid level, the drive output module 160 may transmit the second level signal Vgh of the second level terminal VGL1 to the drive signal terminal OUT as the valid level of the gate drive signal Gout, such that the accuracy of the signal transmission of the second signal transmission line 421 electrically connected to the drive output module 160 may affect the accuracy of the valid level of the gate drive signal Gout. Therefore, by setting the line width of the second signal transmission line 421 electrically connected to the drive output module 160 to be greater than or equal to 12 μm, the second signal transmission line 421 may have a relatively large line width, which may be beneficial for reducing the voltage drop of the second level signal Vgh when the second signal transmission line 421 is transmitted, ensuring that the second signal transmission line 421 may accurately transmit the second level signal Vgh to the shift register G at each level and further improving the accuracy of the gate drive signal Gout outputted by the shift register G at each level.

Furthermore, the display panel may further include a start signal line 47, a control signal line 46, and at least two clock signal lines (44 and 45). The start signal line 47 may transmit the start control signal to the first-level shift register G1, the control signal line 46 may transmit the output control signal Vctrl to the shift register at each level, and two clock signal lines (44 and 45) may transmit the first clock signal CK and the second clock signal XCK to the shift register G at each level respectively. In addition, in order to ensure that the shift register G at each level may accurately output the shift signal Vnext, the first clock terminals Ck of two adjacent levels of shift register G may be electrically connected to different clock signal transmission lines, and the second clock terminals Xck of two adjacent levels of shift register G may be electrically connected to different clock signal lines. At this point, the first clock terminal Ck of the odd-numbered shift register G may be connected to same clock signal line 44 as the second clock terminal Xck of the even-numbered shift register G; and the second clock terminal Xck of the odd-numbered shift register G may be connected to same clock signal line 45 as the first clock terminal Ck of the even-numbered shift register G. In such way, the first clock signal CK of the odd-numbered shift register G may be multiplexed as the second clock signal XCK of the even-numbered shift register G; and the second clock signal XCK of the odd-numbered shift register G may be multiplexed as the first clock signal CK of the even-numbered shift register G.

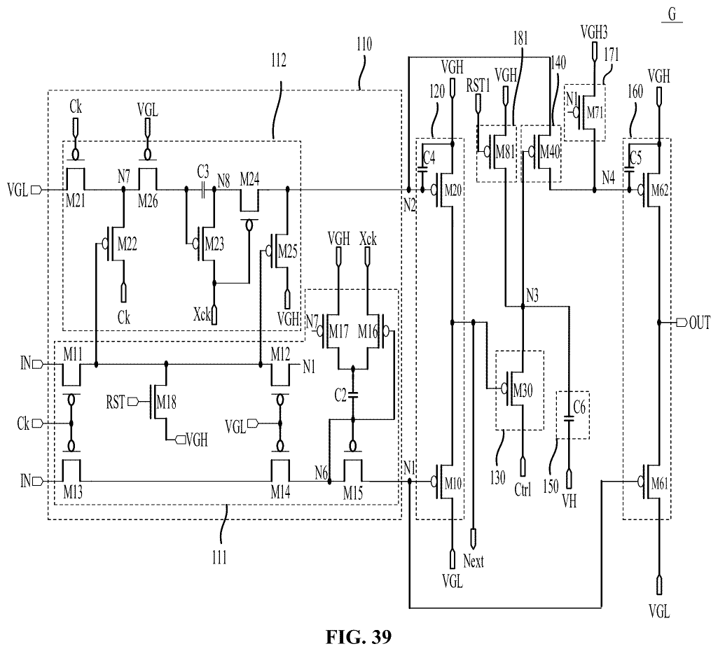

On the basis of above-mentioned embodiments, optionally, FIG. 39 illustrates another structural schematic of a shift register according to various embodiments of the present disclosure. As shown in FIG. 39, the shift register G may further include the first reset module 181. The first reset module 181 may be configured to at least receive the first reset signal Vrst1 and the second level signal Vgh to control the signal of the third node N3. In such way, the first reset module 181 may reset the third node N3 according to the first reset signal Vrst1 and the second level signal Vgh.

Optionally, referring to FIG. 39, the first reset module 181 may include the first reset transistor M81; and the gate electrode of the first reset transistor M81 may receive the first reset signal Vrst1, the first electrode of the first reset transistor M81 may receive the second level signal Vgh, and the second electrode of the first reset transistor M81 may be electrically connected to the third node N3. In such way, the first reset transistor M81 may be turned on or off under the control of the first reset signal Vrst1. In addition, when the first reset signal Vrst1 is controlled to be turned on for conduction, the second level signal Vgh may be transmitted to the third node N3 to reset the third node N3.

In an exemplary embodiment, before the shift registers G at all levels start to output the valid levels of the shift signals Vnext, the first reset transistors M81 of the shift registers G at all levels may receive same or different first reset signals Vrst1. In such way, the first reset transistors M81 of the shift registers G at all levels may be controlled to be turned on simultaneously or in time-sharing manner, such that the third nodes N3 of the shift registers G at all levels may be reset simultaneously or in time-sharing manner, thereby ensuring that the signals of the third nodes N3 of the shift registers G at all levels may prepare for accurate output of the gate drive signals Gout by the shift registers G at all levels.

It may be understood that in the shift register G, the signal of the first node N1 and the signal of the second node N2 may control the output of corresponding shift signal Vnext; when the signal of the first node N1 is at the valid level, the shift register G may be controlled to output the invalid level of the shift signal Vnext; and when the second node N2 is at the valid level, the shift register G may be controlled to output the valid level of the shift signal Vnext. Therefore, before the shift register G outputs the valid level of the shift signal Vnext, the signal of corresponding first node N1 may include the valid level. At this point, the signal of the first node N1 may be multiplexed as the first reset signal Vrest1, such that the first reset transistor M81 in the shift register G may be turned on under the control of the signal of the first node N1, and the turn-on time may be at least in the time period before the shift signal Vnext is at the valid level, thereby resetting the third node N3 before the shift signal Vnext is changed to the valid level. Meanwhile, when the signal of the first node N1 is multiplexed as the first reset signal Vrst1, the number of signals provided to the shift register G may be reduced, which may be beneficial for simplifying the structure of the shift register G and reducing the driving cost of the shift register G.

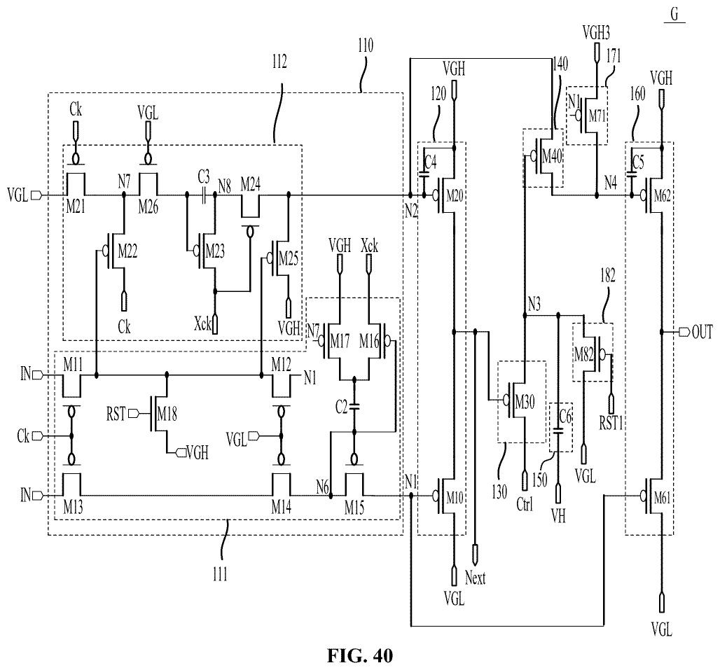

Optionally, FIG. 40 illustrates another structural schematic of a shift register according to various embodiments of the present disclosure. As shown in FIG. 40, the shift register G may further include the second reset module 182. The second reset module 182 may be configured to at least receive the second reset signal Vrst2 and the first level signal Vg1 to control the signal of the third node N3. In such way, the second reset module 182 may reset the third node N3 according to the second reset signal Vrst2 and the first level signal Vg1.

Optionally, referring to FIG. 40, the second reset module may include the second reset transistor M82; and the gate electrode of the second reset transistor M82 may receive the second reset signal Vrst2, the first electrode of the second reset transistor M82 may receive the first level signal Vg1, and the second electrode of the second reset transistor M82 may be electrically connected to the third node N3. In such way, the second reset transistor M82 may be turned on or off under the control of the second reset signal Vrst2. In addition, when the second reset signal Vrst2 is controlled to be turned on for conduction, the first level signal Vg1 may be transmitted to the third node N3 to reset the third node N3.

The time for the second reset transistor M82 to transmit the first level signal Vg1 to the third node N3 may be same as or different from the transmission time of the first reset transistor M81, which may not be limited in embodiments of the present disclosure. In an exemplary embodiment, after the shift registers G at all levels end outputting the valid levels of the shift signals Vnext, the second reset transistors M82 of the shift registers G at all levels may receive same or different second reset signals Vrst2, such that the second reset transistors M82 of the shift registers G at all levels may be controlled to be turned on simultaneously or in time-sharing manner, and the third nodes N3 of the shift registers G at all levels may be reset simultaneously or in time-sharing manner, thereby ensuring that the signals of the third nodes N3 of the shift registers G at all levels may prepare for accurate output of the gate drive signals Gout by the shift registers G at all levels.

It may be understood that before and after the shift register G outputs the valid level of the shift signal Vnext, the signal of the first node N1 may include the valid level. At this point, the signal of the first node N1 may be multiplexed as the second reset signal Vrst2, such that the second reset transistor M82 may accurately reset the third node N3, which may be beneficial for reducing the number of signals provided to the shift register G, simplifying the structure of the shift register G, and reducing the driving cost of the shift register G.

It should be noted that FIGS. 39-40 only exemplarily illustrate the situation that only the first reset module 181 or the second reset module 182 is included in the shift register G. In embodiments of the present disclosure, both the first reset module 181 and the second reset module 182 may also be included. At this point, the first reset module 181 and the second reset module 182 may be turned on in time-sharing manner, which may not be limited in embodiments of the present disclosure on the premise of capable of implementing the core concept (solution) of embodiments of the present disclosure. For the convenience of description, without special limitation, the shift register G may only include the first reset module 181, which may be taken as an example to exemplarily illustrate the technical solution of embodiments of the present disclosure.

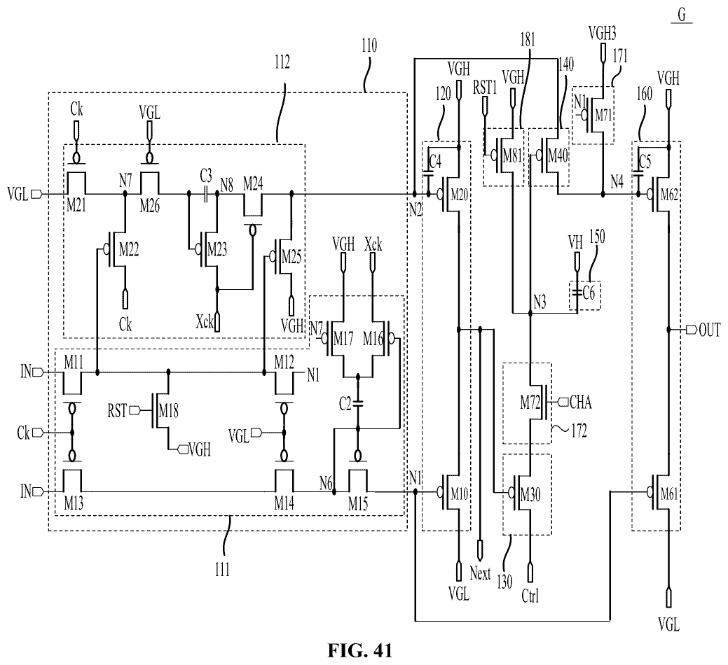

Optionally, FIG. 41 illustrates another structural schematic of a shift register according to various embodiments of the present disclosure. As shown in FIG. 41, the shift register G may further include a charging control module 172; the charging control module 172 may be electrically connected between the output control module 130 and the third node N3; and the charging control module 172 may at least receive the charging control signal Vcha and control the transmission path of the output control signal Vctrl transmitted by the output control module 130 to the third node N3.

The charging control signal Vcha may be provided by a charging signal terminal CHA, such that when the charging control signal Vcha controls the charging control module 172 to be turned on for conduction, a conduction path may be formed between the third node N3 and the output control module 130. Furthermore, when the charging control signal Vcha controls the charging control module 172 to be turned off for disconnection, no path may be formed between the third node N3 and the output control module 130, such that the output control signal Vctrl transmitted by the output control module 130 cannot be transmitted to the third node N3. Therefore, when the charging control module 172 and the output control module 130 are turned on simultaneously, the output control signal Vctrl may be transmitted to the third node N3. When the time that the charging control module 172 and the output control module 130 are turned on simultaneously is the output control time, the output control time of the shift register G at each level may be controlled to shift sequentially and be not overlapped with each other. In such way, the time for the shift register G at each level to transmit the output control signal Vctrl to the third node N3 may not affect each other, which may be beneficial for improving the accuracy of the output control signal Vctrl transmitted to the third node N3 and further improving the accuracy of the gate drive signal Gout outputted by the shift register G.

Optionally, referring to FIG. 41, the charging control module 172 may include a charging control transistor M72; and the gate electrode of the charging control transistor M72 may receive the charging control signal Vcha, the first electrode of the charging control transistor M72 may be electrically connected to the output control module 130, and the second electrode of the charging control transistor M72 may be electrically connected to the third node N3. In such way, the charging control transistor M72 may be turned on or off under the control of the charging control signal Vcha. In addition, when the charging control signal Vcha controls the charging control transistor M72 to be turned on for conduction, a conduction path may be formed between the output control module 130 and the third node N2. At this point, if the output control module 130 is also in the turn-on state, the output control signal Vctrl may be transmitted to the third node N3 through the output control module 130 and the charging control transistor M72 sequentially, such that the signal of the third node N3 may be consistent with the output control signal Vctrl.

In an exemplary embodiment, when the output control module 130 includes the output control transistor M30 and when the output control transistor M30 is turned on under the control of the shift signal Vnext being the invalid level, since the valid level starting time point of the shift signal Vnext outputted by the shift register G at each level is shifted sequentially, the valid level starting time point of the shift signal Vnext outputted by current level shift register G may have a certain shift time compared to the valid level starting time point of the shift signal Vnext outputted by the shift register G at previous level; and the shift time of the valid level starting time point of the shift signal Vnext outputted by the shift register G at each level may not be overlapped with the shift time of the valid level starting time point of the shift signal Vnext outputted by the shift register G at previous level. For example, when the shift time of the valid level starting time point of the shift signal outputted by the second-level shift register may be the first shift time compared to the valid level starting time point of the shift signal outputted by the first-level shift register, and when the shift time of the valid level starting time point of the shift signal outputted by the third-level shift register may be the second shift time compared with the valid level starting time point of the shift signal outputted by the second-level shift register, the first shift time may be not overlapped with the second shift time. Therefore, in the same shift register G, the time that the output control module 130 and the charging control module 172 are turned on simultaneously may be configured to the shift time of the valid level starting time point of the shift signal Vnext outputted by the shift register G, such that the time that the shift registers G at all levels transmit the output control signals Vctrl to the third nodes N3 may be not overlapped with each other. That is, the output control signals Vctrl transmitted by the shift registers G at all levels to the third nodes N3 may not affect each other.

In an optional embodiment, the input signal Vin may be multiplexed as the charging control signal Vcha, such that the charging control transistor M72 may be turned on or off under the control of the input signal Vin.

When the shift output module 120 includes the first shift output transistor M10 and the second shift output transistor M20, the channel types of the first shift output transistor M10 and the second shift output transistor M20 may be different from the channel type of the charging control transistor M72. Meanwhile, the first shift output transistor M10 may be turned on or off under the control of the signal of the first node N1, and the signal of the first node N1 may be controlled by the first shift control submodule 111. Therefore, when the first shift control submodule 111 includes the first input unit (the first input transistor M11), the first input unit (the first input transistor M11) may be turned on or off under the control of the first clock signal CK. When the first clock signal CK controls the first input unit (the first input transistor M11) to be turned on for conduction, the input signal Vin may be transmitted to the first node N1, such that the signal of the first node N1 may be consistent with the input signal Vin. That is, when the input signal Vin is at the low level, the signal of the first node N1 may be also at the low level; and when the input signal Vin is at the high level, the signal of the first node N1 may be also at the high level. In such way, the time that the signal of the first node N1 controls the first shift output transistor M10 to be turned on may be overlapped with the time that the input signal Vin controls the charging control transistor M72 to be turned off. Similarly, the time that the signal of the first node N1 controls the first shift output transistor M10 to be turned off may be overlapped with the time that the input signal Vin controls the charging control transistor M72 to be turned on.

For example, the charging control transistor M72 may be an NMOS transistor, the output control transistor M30 and the first shift output transistor M10 may be PMOS transistors, which may be taken as an example for description. The charging control transistor M72 may be turned on for conduction when the input signal Vin is at the high level, and the first shift output transistor M10 may be turned on for conduction when the signal of the first node N1 is at the low level. The signal of the first node N1 may also be changed to the high level after the input signal Vin is changed to the high level. At this point, the first level signal Vg1 cannot be transmitted to the shift signal terminal Next. Meanwhile, the signal change of the second node N2 may have a certain hysteresis. Therefore, the signal of the second node N2 may also maintain the high level for a period of time when the first node N1 is changed to the high level, and the shift signal Vnext may maintain the low level, such that the shift signal Vnext may control the output control transistor M30 to be in the conduction state. That is, during such time period, the output control transistor M30 and the charging control transistor M72 may be turned on simultaneously, such that the output control signal Vctrl may be transmitted to the third node N3. Therefore, by multiplexing the input signal Vin as the charging control signal Vcha, while reducing the number of signals provided to the shift register G, it may ensure that the time for providing the output control signal Vctrl to the third node N3 of the shift register G at each level may be not overlapped with each other, which may be beneficial for improving the accuracy of the gate drive signal Gout outputted by the shift register G at each level.

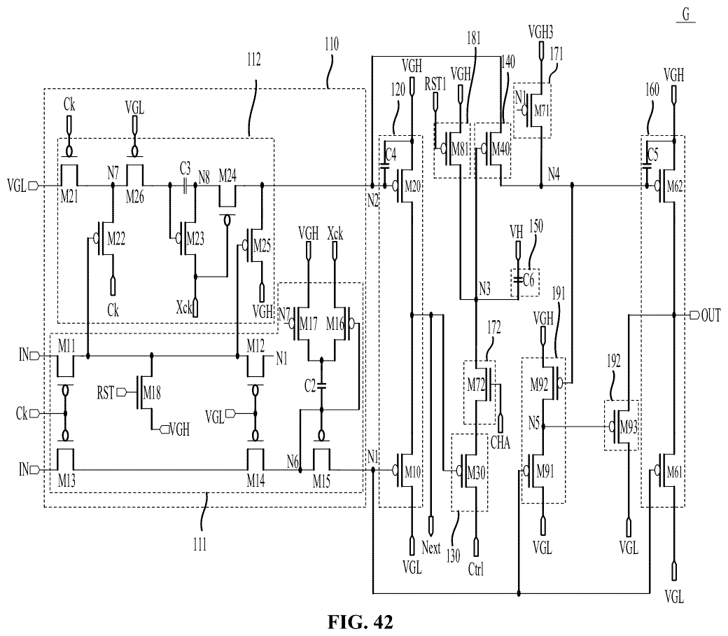

Optionally, FIG. 42 illustrates another structural schematic of a shift register according to various embodiments of the present disclosure. As shown in FIG. 42, the shift register G may further include a compensation control module 191 and an output compensation module 192. The compensation control module 191 may be configured to at least receive the signal of the first node N1, the signal of the fourth node N4, the first level signal Vg1 and the second level signal Vgh and control the signal of the fifth node N5; and the output compensation module 192 may be configured to at least receive the signal of the fifth node N5 and the first level signal Vg1 and compensate the gate drive signal Gout.

The compensation control module 191 may control the signal of the fifth node N5 according to the first node N1, the fourth node N4, the first level signal Vg1 and the second level signal Vgh. For example, when the signal of the first node N1 is at the valid level, the compensation control module 191 may be controlled to transmit the first level signal Vg1 to the fifth node N5, such that the signal of the fifth node N5 may be consistent with the first level signal Vg1. Furthermore, when the signal of the fourth node N4 is at the valid level, the compensation control module 191 may be controlled to transmit the second level signal Vgh to the fifth node N5, such that the signal of the fifth node N5 may be consistent with the second level signal Vgh. Therefore, the signal of the fifth node N5 may change between the first level signal Vg1 and the second level signal Vgh. When the first level signal Vg1 is the valid level for controlling the output compensation module 192 to be turned on for conduction and when the second level signal Vgh is the invalid level for controlling the output compensation module 192 to be turned off for disconnection, the output compensation module 192 may be controlled to be turned on or off by controlling the signal of the fifth node N5. In addition, when the signal of the fifth node N5 controls the output compensation module 192 to be turned on for conduction, the output compensation module 192 may transmit the first level signal Vg1 to the drive signal terminal OUT, such that the signal of the first node N1 cannot control the drive output module 160 to transmit the first level signal Vg1 to the drive signal terminal OUT. However, during the time period that the shift register G needs to output the low-level gate drive signal Gout, the first level signal Vg1 transmitted by the output compensation module 192 may be configured to control the gate drive signal Gout to maintain the low level, thereby being beneficial for improving the output accuracy of the gate drive signal.

Optionally, referring to FIG. 42, the compensation control module 191 may include the first compensation control transistor M91 and the second compensation control transistor M92; and the gate electrode of the first compensation control transistor M91 may be electrically connected to the first node N1, the first electrode of the first compensation control transistor M91 may receive the first level signal Vg1, and the second electrode of the first compensation control transistor M91 may be electrically connected to the fifth node N5. In such way, the first compensation control transistor M91 may be turned on or off under the control of the signal of the first node N1. In addition, when the signal of the first node N1 controls the first compensation control transistor M91 to be turned on for conduction, the first compensation control transistor M91 may transmit the first level signal Vg1 to the fifth node N5, such that the signal of the fifth node N5 may be consistent with the first level signal Vg1.

The gate electrode of the second compensation control transistor M92 may be electrically connected to the fourth node N4, the first electrode of the second compensation control transistor M92 may receive the second level signal Vgh, and the second electrode of the second compensation control transistor M92 may be electrically connected to the fifth node N5. In such way, the second compensation control transistor M92 may be turned on or off under the control of the signal of the fourth node N4. In addition, when the signal of the fourth node N4 controls the second compensation control transistor M92 to be turned on, the second compensation control transistor M92 may transmit the second level signal Vgh to the fifth node N5, such that the signal of the fifth node N5 may be consistent with the second level signal Vgh.

Therefore, the conduction-time of the first compensation control transistor M91 may be at least consistent with the conduction-time of the first drive output transistor M61; and the conduction-time of the second compensation control transistor M92 may be at least consistent with the conduction-time of the second drive output transistor M62, such that the signal of the fifth node N5 may be consistent with the signal of the gate drive signal Gout. When the output compensation module 192 is controlled by the signal of the fifth node N5 to compensate the gate drive signal Gout, the gate drive signal Gout compensated by the output compensation module 192 may be consistent with the gate drive signal Gout outputted by the drive output module 160, thereby being beneficial for improving the accuracy of the gate drive signal Gout.

Optionally, referring to FIG. 42, the output compensation module 192 may include an output compensation transistor M93; and the first electrode of the output compensation transistor M92 may receive the first level signal Vg1, the second electrode of the output compensation transistor M93 may be configured to output the compensation signal of the gate drive signal Gout, and the gate electrode of the output compensation transistor M93 may be electrically connected to the fifth node N5. In such way, the output compensation transistor M93 may be turned on or off under the control of the signal of the fifth node N5. In addition, when the signal of the fifth node N5 controls the output compensation transistor M93 to be turned on for conduction, the first level signal Vg1 may be transmitted to the drive signal terminal OUT to compensate the gate drive signal Gout outputted by the drive signal terminal OUT.

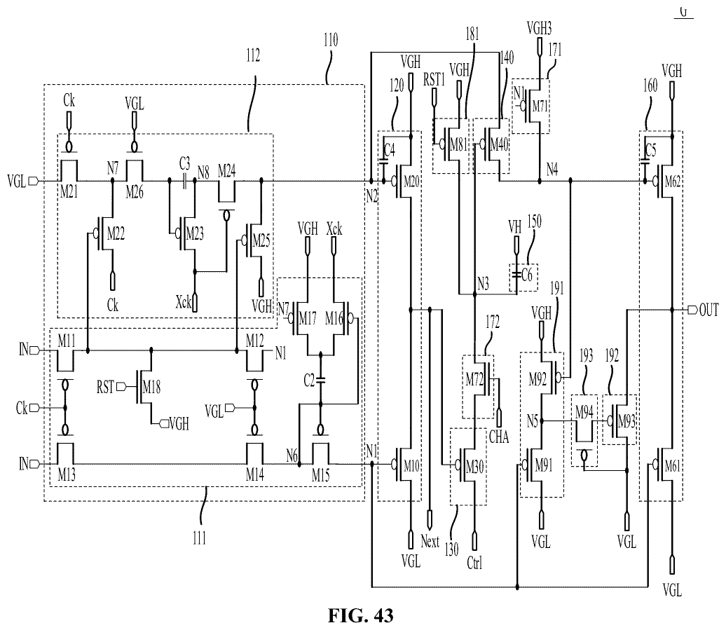

In another optional embodiment, FIG. 43 illustrates another structural schematic of a shift register according to various embodiments of the present disclosure. As shown in FIG. 43, the shift register G may further include the first voltage-stabilizing unit 193. At this point, the gate electrode of the output compensation transistor M93 may be electrically connected to the fifth node N5 through the first voltage-stabilizing unit 193. In such way, the first voltage-stabilizing unit 193 may be configured to isolate the compensation control module 191 from the output compensation transistor M93, which may stabilize the signal of the compensation control module 191 and the signal of the output compensation transistor M93, ensure the accuracy of the signal of the compensation control module 191 and the signal of the output compensation transistor M93, and improve the accuracy of the gate drive signal Gout outputted by the shift register G.

Optionally, referring to FIG. 43, the first voltage-stabilizing unit 193 may include the first voltage-stabilizing transistor M94; and the first electrode of the first voltage-stabilizing transistor M94 may be electrically connected to the fifth node, the second electrode of the first voltage-stabilizing transistor M94 may be electrically connected to the gate electrode of the output compensation transistor M93, and the gate electrode of the first voltage-stabilizing transistor M94 may receive the first level signal Vg1.

The first level signal Vg1 may control the first voltage-stabilizing transistor M94 to be in the turn-on state when the difference between the second electrode signal and the first electrode signal of the first voltage-stabilizing transistor M94 is within a preset range, which may avoid the second electrode signal and/or the first electrode signal of the first voltage-stabilizing transistor M94 from increasing or decreasing instantaneously to affect the stability of the signal of the second electrode or the signal of the first electrode of the first voltage-stabilizing transistor M94, thereby being beneficial for improving the working stability of the shift register G.

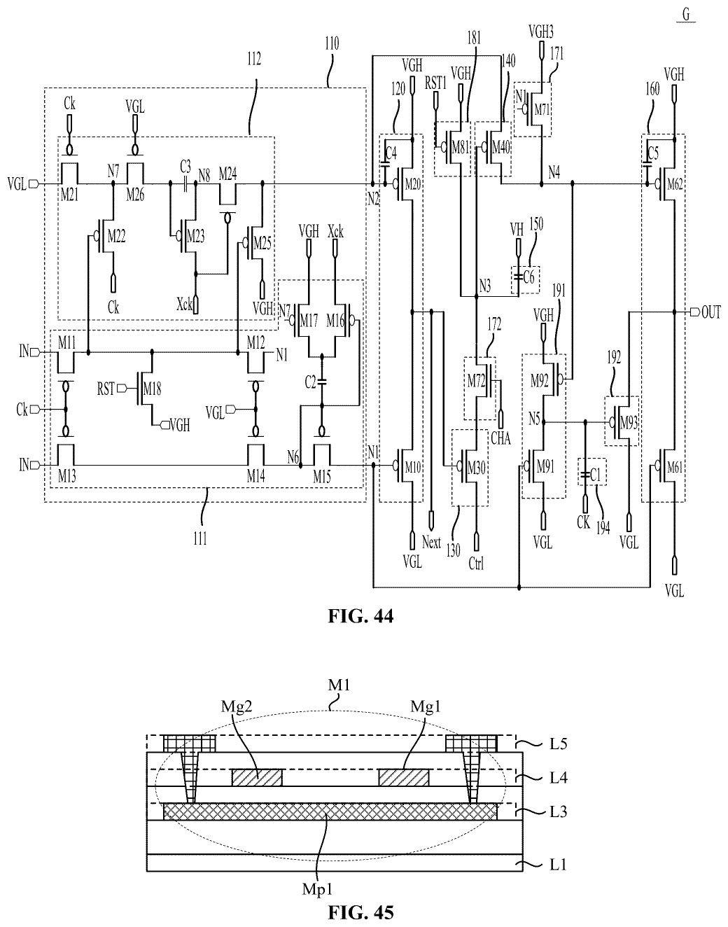

Optionally, FIG. 44 illustrates another structural schematic of a shift register according to various embodiments of the present disclosure. As shown in FIG. 44, the shift register G may further include the first charge pump module 194 which may be configured to at least receive the first clock signal CK and control the signal amount of the first clock signal CK coupled to the fifth node N5.

The first clock signal CK may change between the valid level and the invalid level. When the first clock signal CK jumps and the compensation control module 191 stops transmitting the first level signal Vg1 or the second level signal Vgh to the fifth node N5, the first charge pump module 194 may couple the jump amount of the first clock signal CK to the fifth node N5, such that the signal of the fifth node N5 may change accordingly to satisfy the conduction requirement of the output compensation module 192.

Optionally, referring to FIG. 44, the first charge pump module 194 may include the first capacitor C1; and the first plate of the first capacitor C1 may receive the first clock signal CK, and the second plate of the first capacitor C1 may be electrically connected to the fifth node N5. In such way, due to the charge conservation principle of the capacitor, when the first clock signal CK received by the first plate of the first capacitor C1 changes between the valid level and the invalid level, the signal of the fifth node N5 electrically connected to the second plate of the first capacitor C1 may change accordingly, such that the signal of the second plate of the first capacitor C1 may have same change amount as the signal of the first plate. Therefore, when the first node N1 signal and the second node N4 signal both control the compensation control module 191 to be turned off and stop transmitting the first level signal Vg1 or the second level signal Vgh to the fifth node N5, the first capacitor C1 may be configured to compensate the signal for the fifth node N5, thereby ensuring the stability of the signal of the fifth node N5.

It should be noted that the above only exemplarily describes specific structure of the shift register. On the premise of capable of implementing the core concept (solution) of embodiments of the present disclosure, the shift registers in above-mentioned embodiments may be simply modified to obtain resulting shift registers, which may also belong to the protection scope of embodiments of the present disclosure and may not be described in detail herein. For the convenience of description, the structure of one of the shift registers in above-mentioned embodiments may be taken as an example to exemplarily describe the technical solution of embodiments of the present disclosure.

On the basis of above-mentioned embodiments, optionally, FIG. 45 illustrates a partial cross-sectional structural schematic of a display panel according to various embodiments of the present disclosure. As shown in FIG. 45, the shift register G may include at least one first transistor M1; the first transistor M1 may include the first gate electrode Mg1 and the second gate electrode Mg2; and the first gate electrode Mg1 may be electrically connected to the second gate electrode Mg2.

The first gate electrode Mg1 and the second gate electrode Mg2 of same first transistor M1 may be electrically connected to each other, such that the first gate electrode Mg1 and the second gate electrode Mg2 of the first transistor M1 may receive same signal. Therefore, when the signals received by the first gate electrode Mg1 and the second gate electrode Mg2 control the first transistor M1 to be turned on for conduction, the first transistor M1 may be turned on quickly, thereby improving the response speed of the first transistor M1. When the signals received by the first gate electrode Mg1 and the second gate electrode Mg2 control the first transistor M1 to be turned off for disconnection, the first transistor M1 may have a relatively small leakage current, thereby improving the stability of the signal of the node to which the first transistor M1 is electrically connected.

It may be understood that, as shown in FIG. 45, the first gate electrode Mg1 and the second gate electrode Mg2 of the first transistor M1 may be arranged in the same layer; or in other embodiments, the first gate electrode Mg1 and the second gate electrode Mg2 of the first transistor M1 may also be arranged in different film layers, which may be designed according to actual needs and may not be limited in embodiments of the present disclosure.

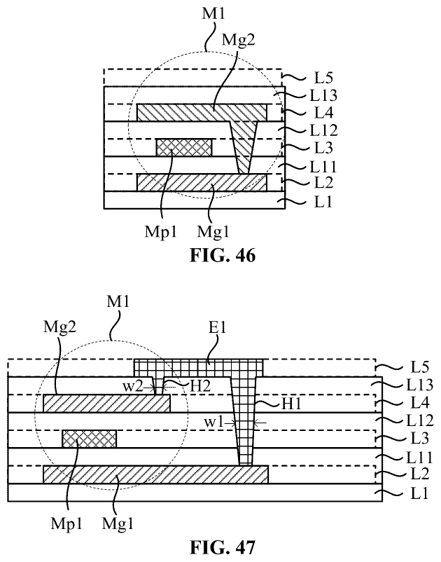

Optionally, FIG. 46 illustrates another partial cross-sectional structural schematic of a display panel according to various embodiments of the present disclosure. As shown in FIG. 46, the display panel 100 may further include a base substrate L1; a first metal layer L2, which is on the side of the base substrate L1 and includes a first gate electrode Mg1; and a semiconductor layer L3, on the side of the first metal layer L2 away from the base substrate L1. The first transistor M1 may further include a first active layer Mp1; and the semiconductor layer L3 may include the first active layer Mp1. The display panel may further include a second metal layer LA, on the side of the semiconductor layer L3 away from the base substrate L1, where the second metal layer L4 may include a second gate electrode Mg2.

The first metal layer L2 and the second metal layer LA may located on two opposite sides of the semiconductor layer L3; and the first metal layer L2, the semiconductor layer L3, and the second metal layer LA may be arranged with insulation intervals, such that a corresponding insulating layer L11 may be arranged between the first metal layer L2 and the semiconductor layer L3, and a corresponding insulating layer L12 may be also arranged between the semiconductor layer L3 and the second metal layer LA. Meanwhile, the first metal layer L1 may include the first gate electrode Mg1, the second metal layer L4 may include the second gate electrode Mg2, and the semiconductor layer L3 may include the first active layer Mp1. Therefore, in the same first transistor M1, the first gate electrode Mg1 and the second gate electrode Mg2 may be respectively in two layers opposite to the first active layer Mp1. At this point, the first gate electrode Mg1 may be the bottom gate electrode of the first transistor M1, and the second gate electrode Mg2 may be the top gate electrode of the first transistor M1, such that the first transistor M1 may be a top-bottom double-gate structure.

It may be understood that the first active layer Mp1 of the first transistor M1 may include a source region, a drain region and a channel region. The channel region may connect the source region and the drain region. Both the first gate electrode Mg1 and the second gate electrode Mg2 may be overlapped with the channel region to control the number of carriers moving along the fixed direction between the source region and the drain region in the channel region through the signals received by the first gate electrode Mg1 and the second gate electrode Mg2, thereby controlling the turn-on or off of the first transistor M1. Meanwhile, the first gate electrode Mg1 and the second gate electrode Mg2 may be the bottom gate and the top gate electrode of the first transistor M1 respectively; and the first gate electrode Mg1 may be electrically connected to the second gate electrode Mg2. Therefore, when the signal received by the first gate electrode Mg1 and the second gate electrode Mg2 controls the first transistor M1 to be turned on for conduction, it is beneficial for increasing the electric field applied to the first active layer Mp1 and increasing the number of carriers moving along the fixed direction between the source region and the drain region. That is, it is equivalent to reducing the threshold voltage of the first transistor M1, such that the first transistor M1 may be turned on quickly and accurately transmit signals. In the case that the first transistor M1 is the PMOS transistor, the threshold voltage of the first transistor M1 may be a negative value. At this point, reducing the threshold voltage of the first transistor M1 may be understood as making the threshold voltage of the first transistor M1 to be positively biased, that is, reducing the absolute value of the threshold voltage of the first transistor M1.

It should be noted that when the first gate electrode Mg1 and the second gate electrode Mg2 are located in different film layers, corresponding vias may be directly configured between the first gate electrode Mg1 and the second and third gates Mg2, such that the first gate electrode Mg1 and the second gate electrode Mg2 may be electrically connected to each other through the vias; or the first gate electrode Mg1 and the second gate electrode Mg2 may also be electrically connected to each other through other connection structures.

Optionally, FIG. 47 illustrates another partial cross-sectional structural schematic of a display panel according to various embodiments of the present disclosure. As shown in FIG. 47, the display panel 100 may further include a third metal layer L5, on the side of the second metal layer LA away from the base substrate L1; the third metal layer L5 may include at least one gate connection structure E1; and in the same first transistor, the first gate electrode Mg1 may be electrically connected to the gate connection structure E1 through the first via H1, and the gate connection structure E1 may be electrically connected to the second gate electrode Mg2 through the second via H2.

A corresponding insulating layer L13 may also be disposed between the third metal layer L5 and the second metal layer LA, such that the third metal layer L5 and the second metal layer L4 may be insulated from each other. Meanwhile, the first gate electrode Mg1 and the second gate electrode Mg2 may be electrically connected to each other through the gate connection structure E1 of the third metal layer L5; that is, the gate connection structure E1 may be not in the same layer as the first gate electrode Mg1 and the second gate electrode Mg2. In such way, the disposing position and dimension of the gate connection structure E1 may not be limited by the sizes and positions of the first gate electrode Mg1 and the second gate electrode Mg2 of the first transistor M1, thereby being beneficial for flexible configuration of the gate connection structure E1 and the compact structure of the shift register G, and reducing the dimension of the shift register G.

Optionally, referring to FIG. 47, the size w1 of the first via H1 may be greater than the size w2 of the second via H2.

The third metal layer L5 disposed with the gate connection structure E1 may be on the side of the second metal layer LA away from the base substrate L1, such that the distance between the third metal layer L5 and the second metal layer L4 may be less than the distance between the third metal layer L5 and the first metal layer L2. That is, the depth of the first via H1 connecting the gate connection structure E1 to the first gate electrode Mg1 may be greater than the depth of the second via H2 connecting the gate connection structure E1 to the second gate electrode Mg2. By setting the size w1 of the first via H1 to be greater than the size w2 of the second via H2, the first via H1 with a relatively large depth may have a relatively large size, such that the first via H1 may be conveniently configured. Meanwhile, when the first via H1 has a relatively large size, the gate connection structure E1 and the first gate electrode Mg1 may have a relatively large contact region, thereby being beneficial for reducing the contact impedance between the gate connection structure E1 and the first gate electrode Mg1, balancing the problem of large impedance difference caused by the connection distance, improving the consistency of the signals received by the first gate electrode Mg1 and the second gate electrode Mg2, and accurately controlling the first transistor M1 to be turned on or off.

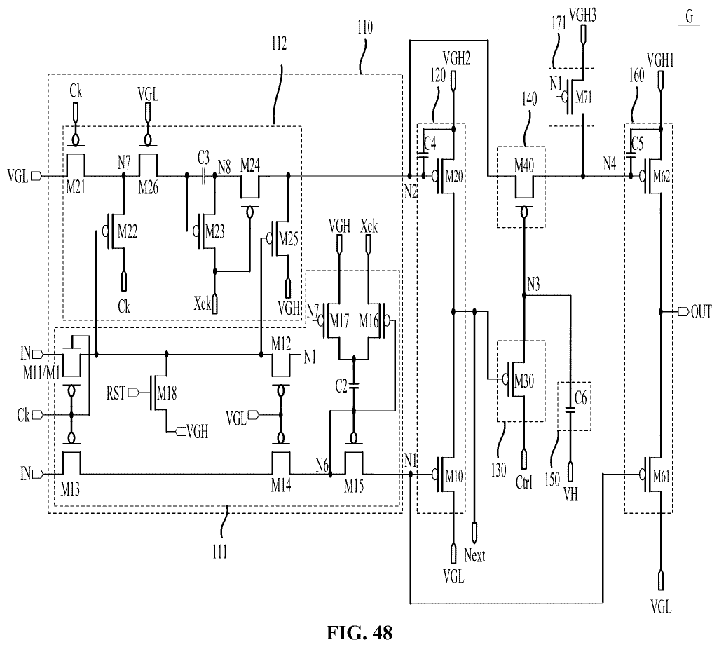

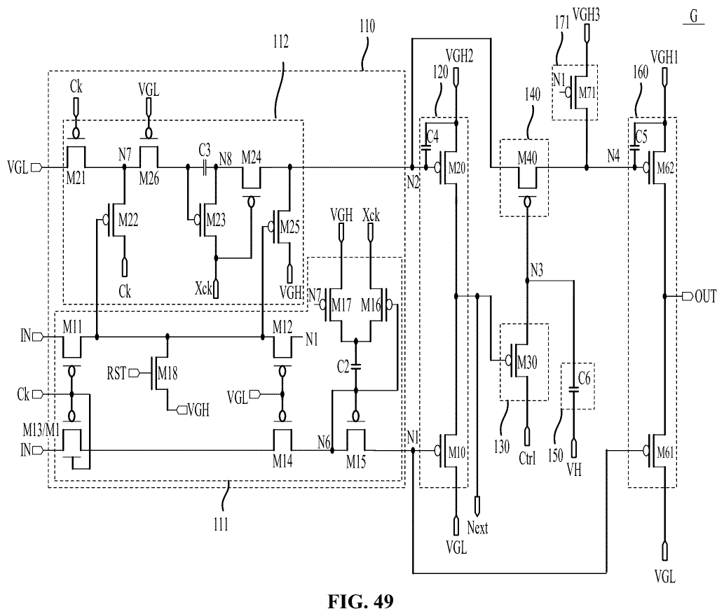

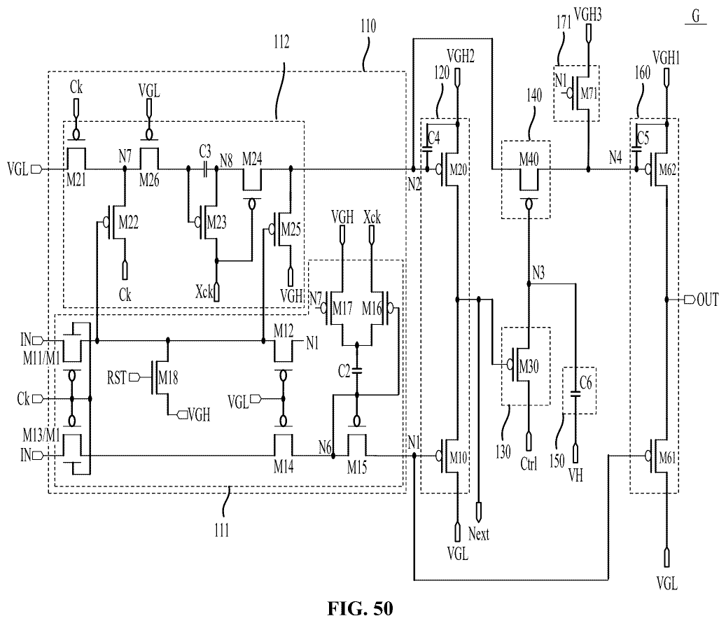

Optionally, FIG. 48 illustrates another structural schematic of a shift register according to various embodiments of the present disclosure; FIG. 49 illustrates another structural schematic of a shift register according to various embodiments of the present disclosure; and FIG. 50 illustrates another structural schematic of a shift register according to various embodiments of the present disclosure. Referring to FIGS. 48-50, the first input transistor M11 and/or the second input transistor M13 may be the first transistors M1 when the first input unit includes the first input transistor M11, the gate electrode of the first input transistor M11 receives the first clock signal CK, the first electrode of the first input transistor M11 receives the input signal Vin, the first electrode of the first input transistor M11 is coupled to the first node N1, the second input unit includes the second input transistor M13, the gate electrode of the second input transistor M13 receives the first clock signal CK, the first electrode of the second input transistor M13 receives the input signal Vin, and the first electrode of the second input transistor M13 is coupled to the sixth node N6.

As shown in FIG. 48, when only the first input transistor M11 is the first transistor M1, the first input transistor M11 may include the first gate electrode Mg1 and the second gate electrode Mg2. In such way, when the first clock signal CK controls the first input transistor M11 to be turned on for conduction, the first input transistor M11 may have a relatively small threshold voltage, such that the input signal Vin may be accurately transmitted to the first node N1, and the accuracy of the signal of the first node N1 may be improved. As shown in FIG. 49, when only the second input transistor M13 is the first transistor M1, the second input transistor M13 may include the first gate electrode Mg1 and the second gate electrode Mg2. In such way, when the first clock signal CK controls the second input transistor M13 to be turned on for conduction, the second input transistor M13 may have a relatively small threshold voltage, such that the input signal Vin may be accurately transmitted to the sixth node N6, and the accuracy of the signal of the sixth node N6 may be improved. Or as shown in FIG. 50, when the first input transistor M11 and the second input transistor M13 are both first transistors M1, the accuracy of the signal of the first node N1 and the signal of the sixth node N6 may be improved simultaneously.

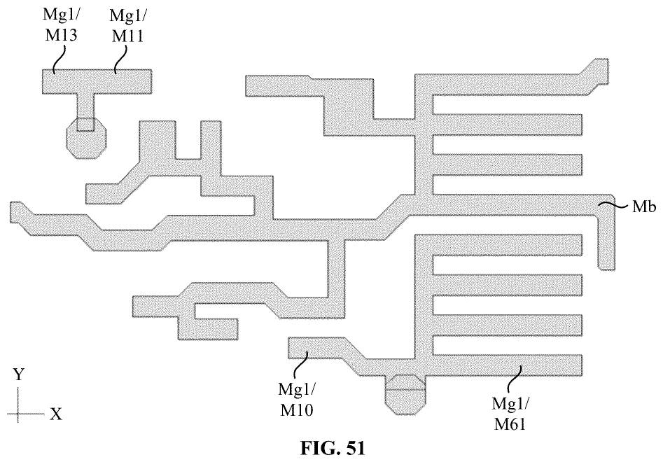

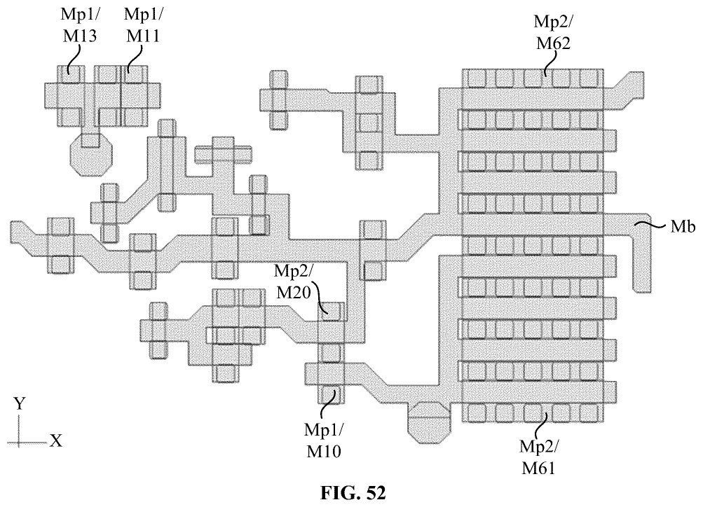

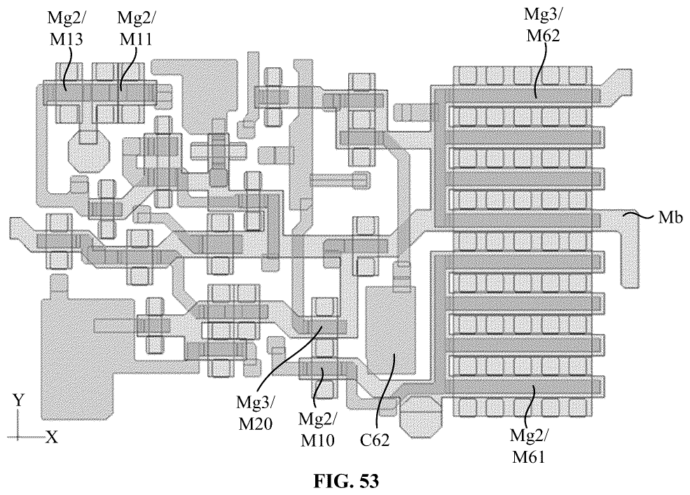

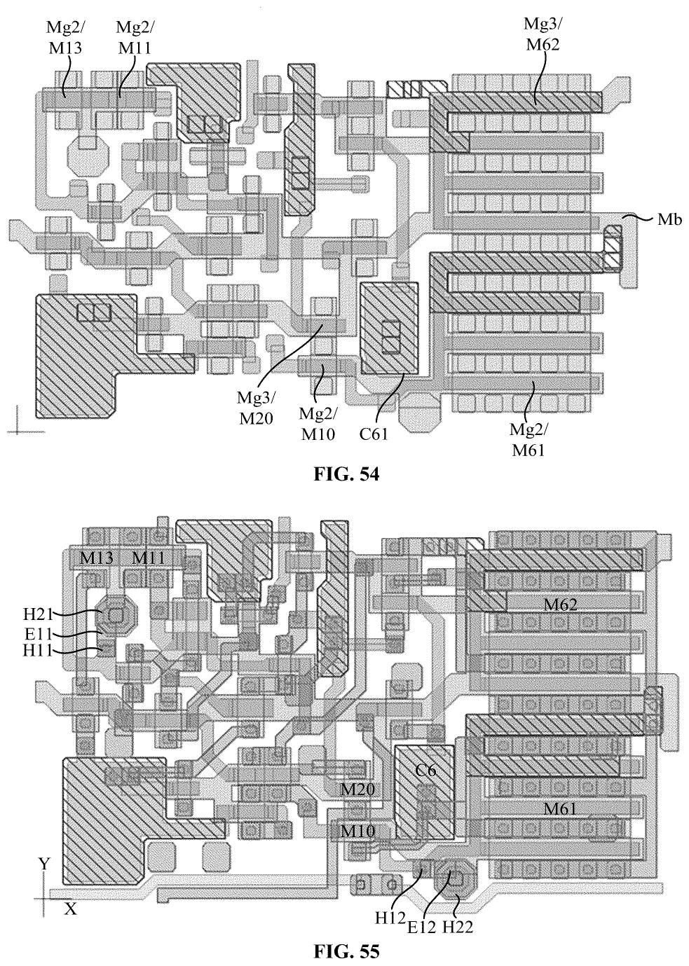

Optionally, FIGS. 51-55 illustrate top-view structural schematics of each film layer of a shift register according to various embodiments of the present disclosure. Referring to FIGS. 50-55, when the first input transistor M11 and the second input transistor M13 are both first transistors M1, the first gate electrode Mg1 of the first input transistor M11 and the first gate electrode Mg1 of the second input transistor M13 may be electrically connected to each other and form a single piece structure; the second gate electrode Mg2 of the first input transistor M11 and the second gate electrode Mg2 of the second input transistor M13 may be electrically connected to each other and form a single piece structure; the first gate electrode Mg1 of the first input transistor M11 and the first gate electrode Mg1 of the second input transistor M13 may be electrically connected to the gate connection structure E11 through same first first-via H11; and the gate connection structure E11 may be electrically connected to the second gate electrode Mg2 of the first input transistor M11 and the second gate electrode Mg2 of the second input transistor M13 through same first second-via H21.

The gates of the first input transistor M11 and the second input transistor M13 may both receive the first clock signal. That is, the first gate electrode Mg1 of the first input transistor M11, the second gate electrode Mg2 of the first input transistor M11, the first gate electrode Mg1 of the second input transistor M13, and the second gate electrode Mg2 of the second input transistor M13 may all receive the first clock signal. At this point, the first gate electrode Mg1 of the first input transistor M11 and the first gate electrode Mg1 of the second input transistor M13 may be configured as a single piece structure, which may be beneficial for reducing the sizes of the first gate electrode Mg1 of the first input transistor M11 and the second input transistor M13 in the first metal layer L2. Meanwhile, configuring the second gate electrode Mg2 of the first input transistor M11 and the second gate electrode Mg2 of the second input transistor M13 as a single piece structure may be beneficial for reducing the sizes of the second gate electrode Mg2 of the first input transistor M11 and the second input transistor M13 in the second metal layer LA, thereby being beneficial for the compact design of the first input transistor M11 and the second input transistor M13. Furthermore, when the first gate electrode Mg1 of the first input transistor M11 and the first gate electrode Mg1 of the second input transistor M13 are configured as the single piece structure, and when the second gate electrode Mg2 of the first input transistor M11 and the second gate electrode Mg2 of the second input transistor M13 are configured as the single piece structure, the first gate electrode Mg1 of the first input transistor M11 and the first gate electrode Mg1 of the second input transistor M13 may be electrically connected to the gate connection structure E11 through same first via H11; and the second gate electrode Mg2 of the first input transistor M11 and the second gate electrode Mg2 of the second input transistor M13 may be electrically connected to the gate connection structure E11 through same first and second vias H21. In such way, the number of the first vias, the second vias, and the gate connection structures may be reduced, thereby being beneficial for simplifying the structure of the shift register G, simplifying the formation process of the display panel, and reducing the formation cost of the display panel.

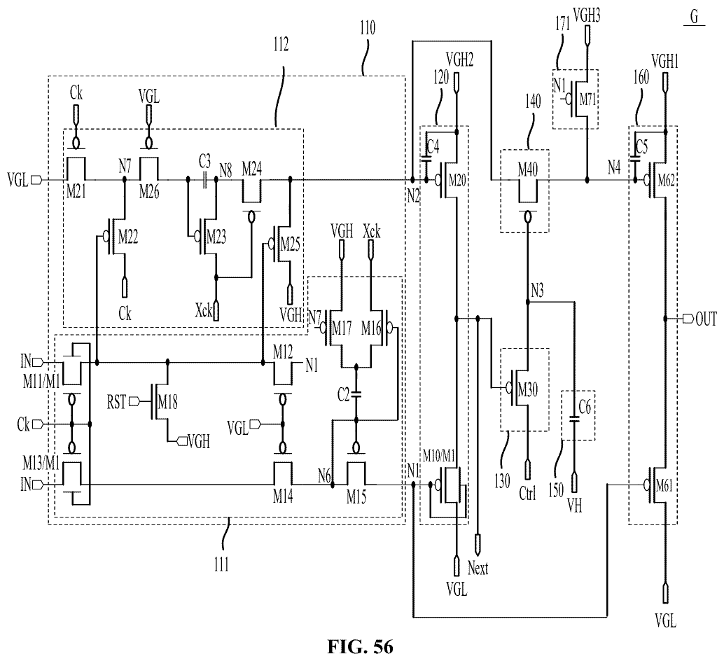

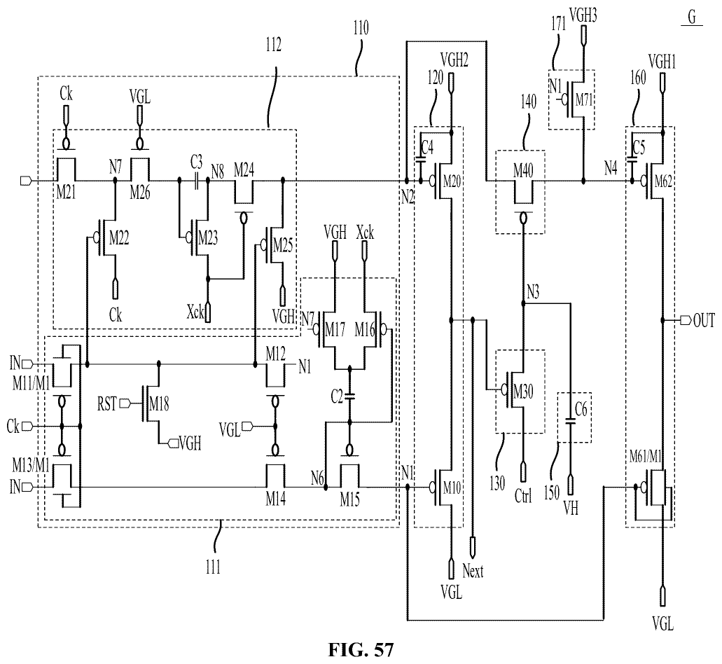

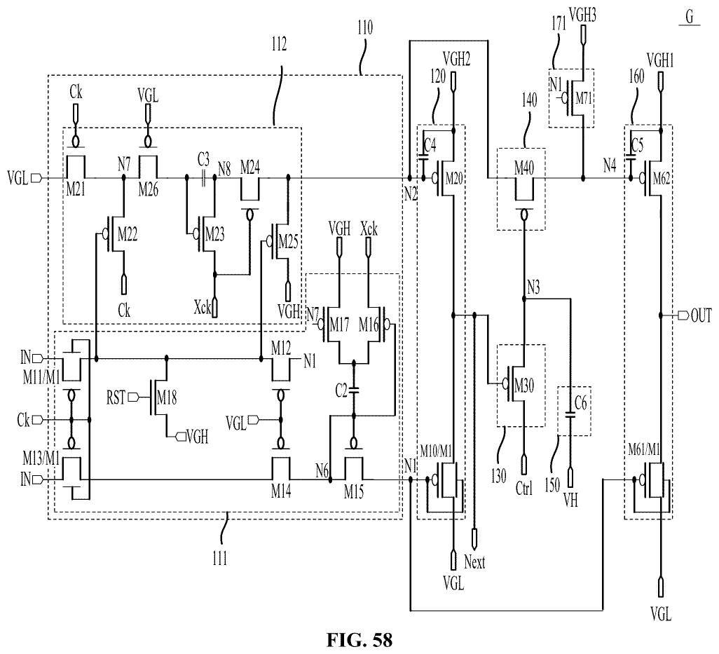

On the basis of above-mentioned embodiments, optionally, FIG. 56 illustrates another structural schematic of a shift register according to various embodiments of the present disclosure; FIG. 57 illustrates another structural schematic of a shift register according to various embodiments of the present disclosure; and FIG. 58 illustrates another structural schematic of a shift register according to various embodiments of the present disclosure. Referring to FIGS. 56-58, when the shift output module 120 includes the first shift output transistor M10 and the second shift output transistor M20 and when the drive output module 160 includes the first drive output transistor M61 and the second drive output transistor M62, the gate electrode of the first shift output transistor M10 may be coupled to the first node N1, the first electrode of the first shift output transistor M10 may receive the first level signal Vg1, and the second electrode of the first shift output transistor M10 may be configured to output the shift signal Vnext; the gate electrode of the second shift output transistor M20 may be electrically connected to the second node N2, the first electrode of the second shift output transistor M20 may receive the second level signal Vgh, and the second electrode of the second shift output transistor M20 may be configured to output the shift signal Vnext; the gate electrode of the first drive output transistor M61 may be coupled to the first node N1, the first electrode of the first drive output transistor M61 may receive the first level signal Vg1, and the second electrode of the first drive output transistor M61 may be configured to output the gate drive signal Gout; the gate electrode of the second drive output transistor M62 may be electrically connected to the fourth node N4, the first electrode of the second drive output transistor M62 may receive the second level signal Vgh, and the second electrode of the second drive output transistor M62 may be configured to output the gate drive signal Gout; and the first shift output transistor M10 and/or the first drive output transistor M61 may be the first transistors M1.

As shown in FIG. 56, when only the first shift output transistor M10 is the first transistor M1, the first shift output transistor M10 may include the first gate electrode Mg1 and the second gate electrode Mg2. In such way, when the signal of the first node N1 controls the first shift output transistor M10 to be turned on for conduction, the first shift output transistor M10 may have a relatively small threshold voltage, such that the first level signal Vg1 may be accurately transmitted to the shift signal terminal Next, and the accuracy of the shift signal Vnext outputted by the shift signal terminal Next may be improved. As shown in FIG. 57, when only the first drive output transistor M61 is the first transistor M1, the first drive output transistor M61 may include the first gate electrode Mg1 and the second gate electrode Mg2. In such way, when the signal of the first node N1 controls the first drive output transistor M61 to be turned on for conduction, the first drive output transistor M61 may have a relatively small threshold voltage, such that the first level signal Vg1 may be accurately transmitted to the drive signal terminal OUT, and the accuracy of the gate drive signal Gout outputted by the drive signal terminal OUT may be improved. Or as shown in FIG. 58, when the first shift output transistor M10 and the first drive output transistor M61 are both first transistors M1, the accuracy of the shift signal Vnext and the gate drive signal Gout may be improved simultaneously.

Optionally, referring to FIGS. 51-55 and 58, when the first shift output transistor M10 and the first drive output transistor M61 are both first transistors M1, the first gate electrode Mg1 of the first shift output transistor M10 and the first gate electrode Mg1 of the first drive output transistor M61 may be electrically connected to each other and form a single piece structure; the second gate electrode Mg2 of the first shift output transistor M10 and the second gate electrode Mg2 of the first drive output transistor M61 may be electrically connected to each other and form a single piece structure; the first gate electrode Mg1 of the first shift output transistor M10 and the first gate electrode Mg1 of the first drive output transistor M61 may be electrically connected to the gate connection structure E12 through same second first-via H12; and the gate connection structure E12 may be electrically connected to the second gate electrode Mg2 of the first shift output transistor M10 and the second gate electrode Mg2 of the first drive output transistor M61 through same second second-via H22.

The gates of the first shift output transistor M10 and the first drive output transistor M61 may both receive the signal of the first node N1. That is, the first gate electrode Mg1 of the first shift output transistor M10, the second gate electrode Mg2 of the first shift output transistor M10, the first gate electrode Mg1 of the first drive output transistor M61, and the second gate electrode Mg2 of the first drive output transistor M61 may all receive same signal. At this point, the first gate electrode Mg1 of the first shift output transistor M10 and the first gate electrode Mg1 of the first drive output transistor M61 may be configured as a single piece structure, which may be beneficial for reducing the sizes of the first shift output transistor M10 and the first drive output transistor M61 in the first metal layer L2. Meanwhile, configuring the second gate electrode Mg2 of the first shift output transistor M10 and the second gate electrode Mg2 of the first drive output transistor M61 as a single piece structure may be beneficial for reducing the sizes of the second gate electrode Mg2 of the first shift output transistor M10 and the first drive output transistor M61 in the second metal layer LA, thereby being beneficial for the compact design of the first shift output transistor M10 and the first drive output transistor M61. Meanwhile, after the first gate electrode Mg1 of the first shift output transistor M10 and the first gate electrode Mg1 of the first drive output transistor M61 are configured as a single piece structure, and after the second gate electrode Mg2 of the first shift output transistor M10 and the second gate electrode Mg2 of the first drive output transistor M61 are configured as a single piece structure, the first gate electrode Mg1 of the first shift output transistor M10 and the first gate electrode Mg1 of the first drive output transistor M61 may be electrically connected to the gate connection structure E12 through same second first-via H12; and the second gate electrode Mg2 of the first shift output transistor M10 and the second gate electrode Mg2 of the first drive output transistor M61 may be electrically connected to the gate connection structure E12 through same second second-via H22, which may reduce the number of first vias, second vias, and gate connection structures, thereby simplifying the structure of the shift register G, simplifying the formation process of the display panel, and reducing the formation cost of the display panel.

Optionally, referring to FIGS. 51-55, when the potential maintaining module 150 includes the potential maintaining capacitor C6, the first plate C61 of the potential maintaining capacitor C6 may receive the fixed level signal Vh, the second plate C62 of the potential maintaining capacitor C6 may be electrically connected to the third node N3, and when the fixed level signal Vh is same as the first level signal Vg1, the first shift output transistor M10 and the second shift output transistor M20 may be arranged along the first direction Y; the first drive output transistor M61 and the second drive output transistor M62 may be arranged along the first direction Y; the first shift output transistor M10 and the first drive output transistor M61 may be arranged along the second direction X; the fourth capacitor C4 may be between the first shift output transistor M10 and the first drive output transistor M61; and the first direction Y may intersect the second direction X.

Therefore, the potential maintaining capacitor C6 may be located in the region enclosed by the first shift output transistor M10, the second shift output transistor M20, the first drive output transistor M61, and the second drive output transistor M62, such that the potential maintaining capacitor C6 may have a relatively large size to have sufficient capacity to maintain the signal of the third node N3, which may be beneficial for compact design of the shift register G and size reduction of the shift register G, thereby being beneficial for reducing the occupied region of the driver circuit as a whole and implementing the narrow frame of the display panel.

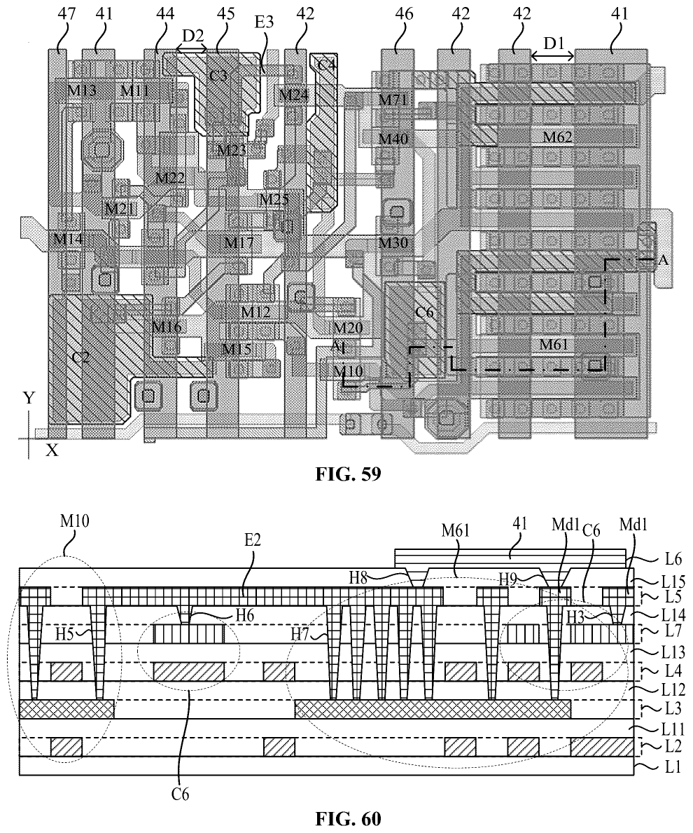

Optionally, FIG. 59 illustrates a top-view structural schematic of a shift register according to various embodiments of the present disclosure; and FIG. 60 illustrates a cross-sectional structural schematic along an A-A section in FIG. 59. Referring to FIGS. 59 and 60, the display panel may further include a fourth metal layer L6, which is on the side of the third metal layer L5 away from the base substrate L1 and includes at least one first signal transmission line 41; and include a fifth metal layer L7, which is on the side of the second metal layer LA away from the base substrate L1 and insulated from the third metal layer L5 and the fourth metal layer L6. The second metal layer L4 may include the second plate of the potential maintaining capacitor C6, and the fifth metal layer L7 may include the first plate of the potential maintaining capacitor C6. The third metal layer L5 may further include a first connection structure E2. The first connection structure E2 may be electrically connected to the first electrode of the first shift output transistor M10 through the fifth via H5. The first connection structure E2 may be electrically connected to the first electrode plate of the potential maintaining capacitor C6 through the sixth via H6. The first connection structure E2 may be electrically connected to the first electrode of the first drive output transistor M61 through the seventh via H7. The first connection structure E2 may be electrically connected to the first signal transmission line 41 through the eighth via H8.

In such configuration, the first drive output transistor M61, the potential maintaining capacitor C6 and the first shift output transistor M10 may be all electrically connected to same first connection structure E2, and may be electrically connected to same first signal transmission line 41 through same first connection structure E2, which may be beneficial for reducing the number of first connection structures in the display panel and reducing the number of vias, thereby being beneficial for simplifying the structure and formation process of the shift register and realizing the low level cost and high production yield of the display panel.

It may be understood that FIG. 60 exemplarily shows the relative position relationship between the fifth metal layer L7, the fourth metal layer L6 and the third metal layer L5. For example, the fifth metal layer L7 may be between the second metal layer LA and the third metal layer L5; and the third metal layer LA may be between the fifth metal layer L7 and the fourth metal layer L6. At this point, an insulating layer L14 should be disposed between the third metal layer L5 and the fifth metal layer L7, and an insulating layer L15 should also be disposed between the third metal layer L5 and the fourth metal layer L6, such that the structures in all metal layers may be insulated from each other, and the transmitted signals may not interfere with each other. In embodiments of the present disclosure, the relative position relationship of all film layers may be not limited to the configuration manner in FIG. 60, which may be designed according to actual needs and may not be described in detail herein.

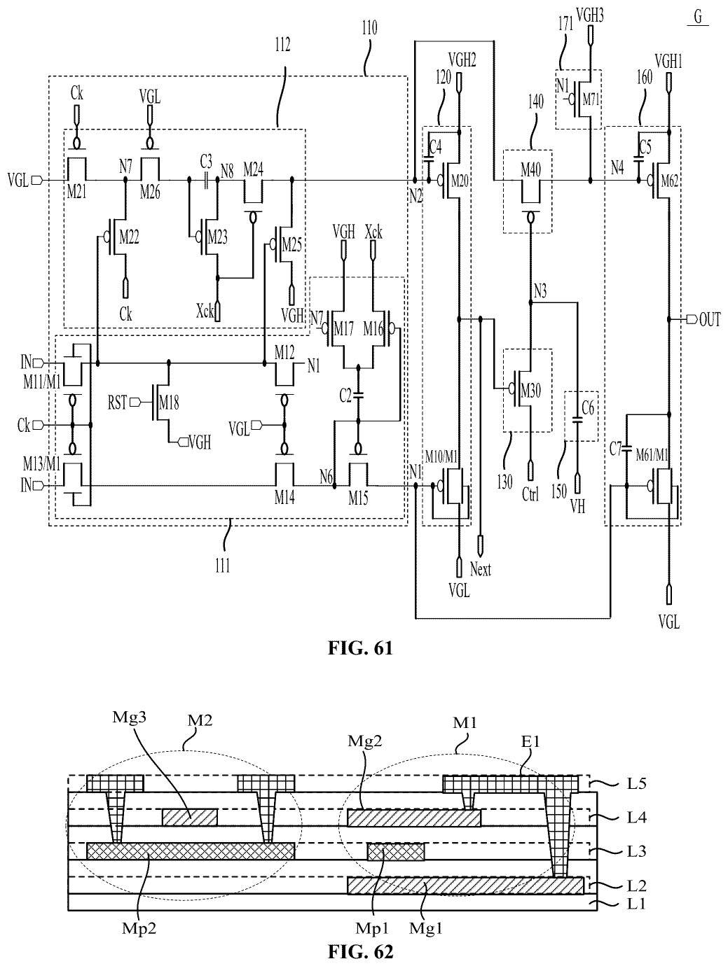

Optionally, FIG. 61 illustrates another structural schematic of a shift register according to various embodiments of the present disclosure. As shown in FIG. 61, the drive output module 160 may further include a bootstrap capacitor C7; and the first plate of the bootstrap capacitor may be electrically connected to the gate electrode of the first drive output transistor M61, and the second plate of the bootstrap capacitor may be electrically connected to the second electrode of the first drive output transistor M61. In such way, when the signal of the first node N1 changes from the invalid level to the valid level, the first drive output transistor M61 may start to be turned on for conduction, such that the first level signal Vg1 may be transmitted to corresponding second electrode. That is, the shift signal Vnext outputted by the second electrode of the first drive output transistor M61 may change from the valid level to the invalid level. At this point, due to the existence of the bootstrap capacitor C7, the jump amount of the shift signal Vnext may be coupled to the first node N1, such that the signal of the first node N1 may control the first drive output transistor M61 to be further turned on for conduction, thereby reducing the output impedance of the first drive output transistor M61, improving the output step of the shift signal Vnext, and improving the output accuracy of the shift signal Vnext.

Optionally, referring to FIGS. 59-61, at least a part of the gate electrode of the first drive output transistor M61 may be reused as the first plate of the bootstrap capacitor C7; the fifth metal layer L7 may include the second plate of the bootstrap capacitor C7; the third metal layer L5 may further include the first electrode lead Md1 of the first drive output transistor M61; the first electrode lead Md1 may be electrically connected to the second electrode in the first active layer through the ninth via H9; the second plate of the bootstrap capacitor C7 may be electrically connected to the first electrode lead Md1 of the first drive output transistor M61 through the third via H3.

The first plate of the bootstrap capacitor C7 may be electrically connected to the gate electrode of the first drive output transistor M61, such that at least a part of the gate electrode of the first drive output transistor M61 may be reused as the bootstrap capacitor C7, the structure of the shift register may be simplified, and the dimension of the shift register may be reduced under the premise of ensuring the accuracy of the signals transmitted by the bootstrap capacitor C7 and the first drive output transistor M61. Meanwhile, the second electrode plate of the bootstrap capacitor C7 may be electrically connected to the first electrode lead Md1 through the third via H3, such that the bootstrap capacitor C7 may be accurately and electrically connected to the second electrode of the first drive output transistor M61, thereby ensuring that the shift register accurately outputs the gate drive signal Gout.

Optionally, referring to FIGS. 59-61, the shortest distance between the seventh via H7 and the ninth via H9 may be greater than the minimum width of the bootstrap capacitor C7. In such way, a short circuit may be prevented between the seventh via H7 and each of the ninth via H9 and the bootstrap capacitor C7, thereby ensuring that the shift register accurately outputs the gate drive signal Gout and being beneficial for improving the production yield of the display panel.

Optionally, referring to FIGS. 48, and 59-61, when the display panel further includes the fourth metal layer L6 on the side of the third metal layer L5 away from the base substrate L1, the fourth metal layer L6 may include a plurality of signal transmission lines; the signal transmission lines may include at least one first signal transmission line 41, at least one second signal transmission line 42, the first clock signal line 44, the second clock signal line 45 and the control signal line 46; the first signal transmission line 41 may be configured to transmit the first level signal Vg1; the second signal transmission line 42 may be configured to transmit the second level signal Vgh; the first clock signal line 44 may be configured to transmit the first clock signal CK of the odd-numbered shift register and the second clock signal XCK of the even-numbered shift register; the second clock signal line 45 may be configured to transmit the second clock signal XCK of the odd-numbered shift register and the first clock signal CK of the even-numbered shift register; and the control signal line 46 may be configured to transmit the output control signal Vctrl of the shift register at each level. In such way, each signal line may be configured in the fourth metal layer L6, which may be beneficial for the electrical connection of each signal line with transistors, capacitors and other structures through corresponding connection structures.

Optionally, referring to FIG. 59, the distance between any two adjacent transmission lines including the first signal transmission lines 41 and second signal transmission lines 42 is the first distance D1; the distance between the first clock signal line 44 and the second clock signal line 45 is the second distance D2; and the first distance D1 may be greater than the second distance D2.

The first clock signal line 44 and the second clock signal line 45 may be configured to transmit clock signals (CK and XCK) that change between the valid level and the invalid level, such that the clock signals (CK and XCK) may continuously charge and discharge the first clock signal line 44 and the second clock signal line 45; and when the distance between the first clock signal line 44 and the second clock signal line 45 is relatively close, the accuracy of the clock signals transmitted by the first clock signal line 44 and the second clock signal line 45 may be ensured. Furthermore, the first level signal Vg1 transmitted by the first signal transmission line 41 and the second level signal Vgh transmitted by the second signal transmission line 42 may be fixed level signals, such that when those transmission lines are interfered by external signals, the transmission accuracy of the first level signal Vg1 and the second level signal Vgh may be affected. In addition, the first level signal Vg1 and the second level signal Vgh may be two signals with opposite polarities, such that a coupling capacitor may be formed between the first signal transmission line 41 and the second signal transmission line 42. At this point, the first distance D1 between the first signal transmission line 41 and the second signal transmission line 41 may be configured to be relatively large, which may be beneficial for reducing the capacitance of the coupling capacitor, thereby improving the influence of the first level signal Vg1 on the second level signal Vgh, and the influence of the second level signal Vgh on the first level signal Vg1 and further improving the accuracy of the shift signal Vnext and the gate drive signal Gout outputted by the shift register.

Optionally, the first clock signal line 44 and the second clock signal line 45 may be two adjacent signal transmission lines among a plurality of signal transmission lines. In such way, the first clock signal line 44 and the second clock signal line 45, which transmit alternating signals, may be configured as two adjacent signal lines, which may reduce the coupling amount to other signal lines due to jumping of the clock signals transmitted on the first clock signal line 44 and the second clock signal line 45, thereby improving the accuracy of the signal transmitted by the signal transmission line.

Optionally, referring to FIGS. 59 and 61, when the first shift control submodule 111 includes the first coupling control transistor M16, and when the second shift control submodule 112 at least includes the first control transistor M21, the second control transistor M22, the third control transistor M23, the fourth control transistor M24, and the control capacitor C3, the gate electrode of the first coupling control transistor M16 may be electrically connected to the sixth node N6, the first electrode of the first coupling control transistor M16 may receive the second clock signal XCK, and the second electrode of the first coupling control transistor M16 may be electrically connected to the second charge pump unit (C2); the gate electrode of the first control transistor M21 may receive the first clock signal CK, the first electrode of the first control transistor M21 may receive the first level signal Vg1, and the second electrode of the first control transistor M21 may be electrically connected to the seventh node N7; the gate electrode of the second control transistor M22 may be coupled to the first node N1, the first electrode of the second control transistor M22 may receive the first clock signal CK, and the second electrode of the second control transistor M22 may be electrically connected to the seventh node N7; the gate electrode of the third control transistor M23 may be coupled to the seventh node N7, the first electrode of the third control transistor M23 may receive the second clock signal XCK, and the second electrode of the third control transistor M23 may be electrically connected to the eighth node N8; the gate electrode of the fourth control transistor M24 may receive the second clock signal XCK, the first electrode of the fourth control transistor M24 may be electrically connected to the eighth node N8, and the second electrode of the fourth control transistor M24 may be electrically connected to the second node N2; and the control capacitor C3 may be electrically connected between the seventh node N7 and the eighth node N8.

Correspondingly, the third metal layer may further include the second connection structure E3; and the third control transistor M23 and the fourth control transistor M24 of the odd-numbered shift register, and the first coupling control transistor M21 of the even-numbered shift register may be electrically connected to the second clock signal line 45 through same second connection structure E3. In such way, in two adjacent shift registers, transistors that are close to each other and electrically connected to same signal transmission line may be electrically connected to same connection structure, thereby reducing the number of connection structures disposed in the shift registers and being beneficial for simplifying the structures of the shift registers and realizing small dimension of the shift registers.

It should be noted that the above only exemplarily describes the shift register structure including the first transistor M1. In embodiments of the present disclosure, the shift register may include at least one first transistor M1. That is, the number of the first transistors M1 may be one or more, which may be configured according to actual needs and may not be limited in embodiments of the present disclosure. When a part of the transistors in the shift register are the first transistors M1, and another part of the transistors may be the second transistors.

Optionally, FIG. 62 illustrates a partial film layer cross-sectional structural schematic of a display panel according to various embodiments of the present disclosure. As shown in FIG. 62, the shift register may further include a plurality of second transistors M2; the second transistor M2 may include the second active layer Mp2 and the third gate electrode Mg3; the semiconductor layer L3 may further include the second active layer Mp2; and the second metal layer LA may further include the third gate electrode Mg3. In such way, the second active layer Mp2 of the second transistor M2 may be arranged in a same layer as the first active layer Mp1 of the first transistor M1; and the third gate electrode Mg3 of the second transistor M2 may be arranged in a same layer as the second gate electrode Mg2 of the first transistor M1, such that there is no need to dispose a corresponding film layer for the second transistor M2, which may be beneficial for thinness of the display panel.

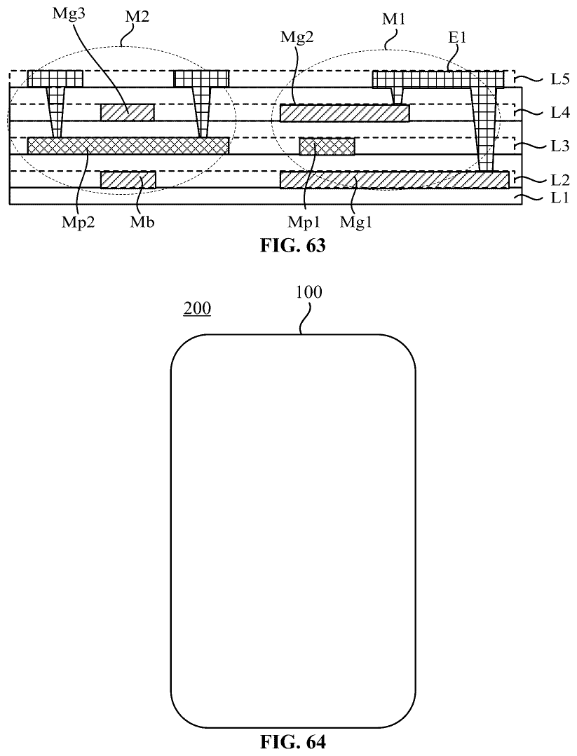

Optionally, FIG. 63 illustrates a partial cross-sectional structural schematic of a display panel according to various embodiments of the present disclosure. As shown in FIG. 63, the first metal layer L2 may further include the first light-blocking structure Mb; along the thickness direction Z of the display panel, the first light-blocking structure Mb may cover the channel region of each second active layer Mp2.

The active layer in the semiconductor layer may generate certain photogenerated carriers when the active layer is exposed to light. The photogenerated carriers may affect the characteristics of the transistor, for example, affect the leakage current of the transistor when the transistor is turned off, and affect the accuracy of the transistor transmission signal when the transistor is turned on.

The first metal layer L2 may be on the side of the semiconductor layer L3 away from the second metal layer LA, and the third gate electrode Mg3 of the second transistor M2 may be arranged in the second metal layer LA, such that the third gate electrode Mg3 may be the top gate electrode of the second transistor, and the third gate electrode Mg3 may block the light, incident from the side away from the second metal layer LA, from irradiating to the second active layer Mp2. Meanwhile, the first light-blocking structure Mb may be disposed in the first metal layer L1, such that the first light-blocking structure Mb may block the light incident from the side of the base substrate L1, thereby improving the accuracy of the signal transmitted by the second transistor M2.

Furthermore, during the transportation and assembly of the display panel, a certain amount of static electricity may be generated. The presence of such static electricity may affect the conduction characteristics of the transistor and even damage the transistor. At this point, the first light-blocking structure Mb may also release partial static electricity, such that static electricity may be released through the first light-blocking structure Mb, thereby preventing static electricity accumulation from damaging transistors and other devices.

Optionally, the first light-blocking structure Mb may receive a jamming signal. The jamming signal may shield the external signal from interfering with the signal transmitted by the second transistor M2, thereby improving the accuracy of the signal transmitted by the second transistor M2.

The jamming signal received by the first light-blocking structure Mb overlapped with the second active layer Mp2 of each second transistor M2 may be same or different, which may not be limited in embodiments of the present disclosure. In an optional embodiment, a corresponding jamming signal may be provided according to the channel type of each second transistor M2, and the threshold voltage of the second transistor M2 may be adjusted by the jamming signal, such that the threshold voltage of the second transistor M2 may be small enough to satisfy the conduction characteristics of the second transistor M2.

In another optional embodiment, the voltage of the jamming signal is V0, the voltage of the first level signal Vg1 is V1, and the voltage of the second level signal Vgh is V2, where |V0|<|V1|, and |V0|<|V2|. Such configuration may make the threshold voltage of the second transistor M2 to be positively biased, thereby being beneficial for improving the conduction characteristics of the second transistor.

Based on same inventive concept, embodiments of the present disclosure further provide a display apparatus which may include the display panel provided by embodiments of the present disclosure. Therefore, the display apparatus may have the technical features of the display panel and the driving method provided in embodiments of the present disclosure; and may achieve the beneficial effects of the display panel provided in embodiments of the present disclosure. Similarities may be referred to the description of the display panel provided in embodiments of the present disclosure and may not be described in detail herein.

Exemplarily, FIG. 64 illustrates a structural schematic of a display apparatus according to various embodiments of the present disclosure. As shown in FIG. 64, the display apparatus 200 may include the display panel 100 provided in embodiments of the present disclosure. The display apparatus 200 provided in embodiments of the present disclosure may be any electronic product with a display function, including but not limited to the following categories: mobile phones, televisions, laptops, desktop displays, tablet computers, digital cameras, smart bracelets, smart glasses, vehicle displays, medical equipment, industrial control equipment, touch interactive terminals and/or the like, which may not be limited in embodiments of the present disclosure.

It may be seen from above-mentioned embodiments that the present disclosure may at least achieve following beneficial effects.

For the technical solution provided in the present disclosure, the cascaded N-level shift registers may be configured in the driver circuit, the shift control module of the shift register at each level may control the shift output module to output the shift signal as the input signal of other level shift registers, and the shift signal may be configured to control the output control module to transmit the output control signal to the third node, such that the transmission control module may control the drive output module to output the gate drive signal according to the signal of the third node. In such way, in a same shift register, the shift output module for signal level transmission and the drive output module for outputting the gate drive signal may be two different modules to make the signal level transmission and the output of the gate drive signal to be independent of each other. Therefore, while ensuring the signal level transmission between the shift registers, the gate drive signals outputted by the shift registers at all levels may be flexibly controlled; and the display panel may satisfy diversified display requirement and broaden application scenarios of the display panel. Meanwhile, the shift register may be also configured with the potential maintaining module to receive the fixed level signal and maintain the signal of the third node. In addition, the fixed level signal may be at least different from the second level signal, which may prevent the second level signal from fluctuating due to the signal change of the third node and affecting the gate drive signal outputted by the drive output module, thereby being beneficial for improving the accuracy of the gate drive signal outputted by the drive output module and further improving the display quality of the display panel.

It should be noted that the above may be merely embodiments of the present disclosure and the technical principles applied. Those skilled in the art may understand that the present disclosure may be not limited to specific embodiments in the present disclosure; and various obvious changes, readjustments and substitutions may be made by those skilled in the art without departing from the protection scope of the present disclosure. Therefore, although the present disclosure has been described in detail through above-mentioned embodiments, the present disclosure may be not limited to above-mentioned embodiments and may include more other equivalent embodiments without departing from the protection scope of the present disclosure. The protection scope of the present disclosure may be determined by the scope of the appended claims.

What is claimed is:

1. A display panel, comprising:
a driver circuit including cascaded N-level shift registers, wherein a shift register of the cascaded N-level shift registers includes:
a shift control module, configured to at least receive an input signal, a first clock signal and a second clock signal, and control a signal of a first node and a signal of a second node;
a shift output module, configured to at least receive the signal of the first node, the signal of the second node, a first level signal and a second level signal, and control an output shift signal, wherein a shift signal outputted by an x-th-level shift register is an input signal received by a y-th-level shift register; 1≤x≤N; 1≤y≤N; x≠y; and x, y and N are all positive integers;
an output control module, configured to at least receive an output control signal and the shift signal, and control a transmission path of the output control signal to a third node under the control of the shift signal;
a transmission control module, configured to at least receive the signal of the second node and a signal of the third node, and control a signal of the fourth node;
a potential maintaining module, configured to receive a fixed level signal and maintain the signal of the third node; and
a drive output module, configured to at least receive the signal of the fourth node, the signal of the first node, the first level signal and the second level signal, and control an output of a gate drive signal, wherein the fixed level signal is at least different from the second level signal.

2. The display panel according to claim 1, wherein:
the fixed level signal is also different from the first level signal.

3. The display panel according to claim 1, wherein:
the fixed level signal is same as the first level signal.

4. The display panel according to claim 3, further including:
at least one first signal transmission line, wherein a first signal transmission line is configured to transmit the first level signal; and in a same shift register, the drive output module and the potential maintaining module are both electrically connected to a same first signal transmission line.

5. The display panel according to claim 4, wherein:
in the same shift register, the shift output module is electrically connected to the first signal transmission line through the potential maintaining module and/or the drive output module.

6. The display panel according to claim 4, wherein:
in the same shift register, the shift output module and the drive output module are electrically connected to different first signal transmission lines respectively.

7. The display panel according to claim 4, wherein:
drive output modules of shift registers of any two adjacent levels are electrically connected to different first signal transmission lines.

8. The display panel according to claim 4, wherein:
drive output modules of shift registers at all levels are electrically connected to a same first signal transmission line; and
a line width of the first signal transmission line electrically connected to the drive output module is greater than or equal to 12 μm.

9. The display panel according to claim 1, wherein the shift register further includes:
a node control module, configured to receive the signal of the first node and the second level signal and control the signal of the fourth node.

10. The display panel according to claim 9, further including:
at least one second signal transmission line, wherein a second signal transmission line is configured to transmit the second level signal; and in a same shift register, the shift output module and the node control module are electrically connected to a same second signal transmission line.

11. The display panel according to claim 10, wherein:
in the same shift register, the shift output module and the drive output module are electrically connected to different second signal transmission lines respectively.

12. The display panel according to claim 10, wherein:
drive output modules of shift registers of any two adjacent levels are electrically connected to different second signal transmission lines.

13. The display panel according to claim 10, wherein:
a line width of the second signal transmission line electrically connected to the drive output module is greater than or equal to 12 μm.

14. The display panel according to claim 9, wherein:
the node control module includes a node control transistor, wherein a gate electrode of the node control transistor is electrically connected to the first node, a first electrode of the node control transistor receives the second level signal, and a second electrode of the node control transistor is electrically connected to the fourth node.

15. The display panel according to claim 1, wherein:
the potential maintaining module includes a potential maintaining capacitor, wherein a first plate of the potential maintaining capacitor receives the fixed level signal, and a second plate of the potential maintaining capacitor is electrically connected to the third node.

16. The display panel according to claim 1, wherein:
the transmission control module includes a transmission control transistor, wherein a gate electrode of the transmission control transistor is electrically connected to the third node, a first electrode of the transmission control transistor is electrically connected to the second node, and a second electrode of the transmission control transistor is electrically connected to the fourth node.

17. The display panel according to claim 1, wherein:
the output control module includes an output control transistor, wherein a gate electrode of the output control transistor receives the shift signal, a first electrode of the output control transistor receives the output control signal, and a second electrode of the output control transistor is electrically connected to the third node.

18. The display panel according to claim 17, wherein:
the output control transistor is a dual-gate transistor.

19. The display panel according to claim 1, wherein:
the shift register further includes a charging control module, wherein the charging control module is electrically connected between the output control module and the third node; and the charging control module at least receives a charging control signal and controls a transmission path of the output control signal transmitted by the output control module to the third node.

20. The display panel according to claim 19, wherein:
the charging control module includes a charging control transistor, wherein a gate electrode of the charging control transistor receives the charging control signal, a first electrode of the charging control transistor is electrically connected to the output control module, and a second electrode of the charging control transistor is electrically connected to the third node.
